(19) United States
(12) Patent Application Publication
(10) Pub. No.: US 2026/0173918 A1
(43) Pub. Date: Jun. 18, 2026

(54) SEMICONDUCTOR DIE STACKS AND METHODS FOR FORMING THE SAME

(71) Applicant: Taiwan Semiconductor Manufacturing Company Limited, Hsinchu (TW)

(72) Inventors: Tzuan-Horng Liu, Longtan Township (TW); An-Jhih Su, Taoyuan City (TW)

(21) Appl. No.: 18/981,570

(22) Filed: Dec. 15, 2024

(51) Int. Cl. H01L 23/498

(52) U.S. Cl. CPC H10W 70/635; H10W 90/701

(57) ABSTRACT

A semiconductor assembly is provided, which includes a through-substrate-via-containing semiconductor die, an adhesive layer, and a semiconductor carrier substrate. The through-substrate-via-containing semiconductor die includes a first semiconductor substrate having through-substrate-via structures formed therein, first semiconductor devices, and front connection pads located on a front side of the first semiconductor substrate, and backside metal interconnect structures located on a backside of the first semiconductor substrate. The semiconductor assembly may be attached to a carrier wafer using a die attachment film. The semiconductor carrier substrate and the adhesive layer may be removed from the semiconductor assembly.

### BACKGROUND

In the semiconductor industry, as the demand for increased performance and functionality continues to grow, there has been a push toward the integration of multiple semiconductor dies in three-dimensional (3D) configurations. Related methods for stacking semiconductor dies, particularly for large dies exceeding 200 mm², face challenges related to yield, reliability, and manufacturing cost. Large semiconductor dies are prone to defects that reduce yield, especially as advanced technology nodes with smaller features are adopted. This results in increased production costs and reduced overall throughput. Additionally, related die stacking methods, such as face-to-back (F2B) or face-to-face (F2F) stacking, are constrained by limitations in achieving high-density interconnects with micro-bumps, particularly when fine-pitch interconnections are desired. The desire to implement complex through-silicon vias (TSVs) further exacerbates the manufacturing complexity, often leading to process inefficiencies and challenges in maintaining structural integrity across the stack. These issues are particularly pronounced in applications where large active dies must be integrated to meet performance and design criteria. As a result, there is a desire for new approaches to semiconductor die stacking that may address these challenges and provide a cost-effective, high-yield solution for integrating large active dies in 3D configurations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1N are sequential vertical cross-sectional views of a first embodiment structure during a sequence of processing steps according to an embodiment of the present disclosure.

FIG. 1O is a first flow chart including a subset of processing steps used during manufacture of the first embodiment structure.

FIGS. 2A-2N are sequential vertical cross-sectional views of a second embodiment structure during a sequence of processing steps according to an embodiment of the present disclosure.

FIG. 2O is a second flow chart including a subset of processing steps used during manufacture of the second embodiment structure.

FIGS. 3A-3N are sequential vertical cross-sectional views of a third embodiment structure during a sequence of processing steps according to an embodiment of the present disclosure.

FIG. 3O is a third flow chart including a subset of processing steps used during manufacture of the third embodiment structure.

FIGS. 4A-4M are sequential vertical cross-sectional views of a fourth embodiment structure during a sequence of processing steps according to an embodiment of the present disclosure.

FIG. 4N is a fourth flow chart including a subset of processing steps used during manufacture of the fourth embodiment structure.

FIGS. 5A-5L are sequential vertical cross-sectional views of a fifth embodiment structure during a sequence of processing steps according to an embodiment of the present disclosure.

FIG. 5M is a fifth flow chart including a subset of processing steps used during manufacture of the fifth embodiment structure.

FIGS. 6A-6L are sequential vertical cross-sectional views of a sixth embodiment structure during a sequence of processing steps according to an embodiment of the present disclosure.

FIG. 6M is a sixth flow chart including a subset of processing steps used during manufacture of the sixth embodiment structure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to a semiconductor structure and packaging schemes designed to address the challenges of integrating large through-substrate-via-containing (TSV-containing) semiconductor dies, such as TSV-containing semiconductor dies having an area exceeding 200 mm². Related approaches such as face-to-back (F2B) and face-to-face (F2F) stacking have faced limitations in yield and reliability due to defects and the complexity of fine-pitch interconnections. The various embodiments disclosed herein introduce methods that enhances yield by leveraging advanced bump structures, bonding dielectric layers, and a novel combination of molding compounds to provide structural stability and thermal management.

According to an aspect of the present disclosure, a first molding compound matrix may be formed around the TSV-containing semiconductor die, which offers lateral support and mitigates mechanical stress during subsequent processing steps. Various embodiments may further provide high-density interconnections by utilizing bonding dielectric layers and bump structures, facilitating efficient vertical and horizontal signal routing between stacked device semiconductor dies. Additionally, the use of underfill material portions around solder material arrays provides mechanical reinforcement and reduces the likelihood of failure due to thermal expansion mismatches. Embodiments of the present disclosure simplify the manufacturing process and reduce production costs while maintaining high interconnect density and minimizing defects. Embodiments of the present disclosure may be used to manufacture semiconductor packages for advanced technology nodes and high-performance applications. The various aspects of the methods and structures of embodiments of the present disclosure are now described with reference to the accompanying drawings.

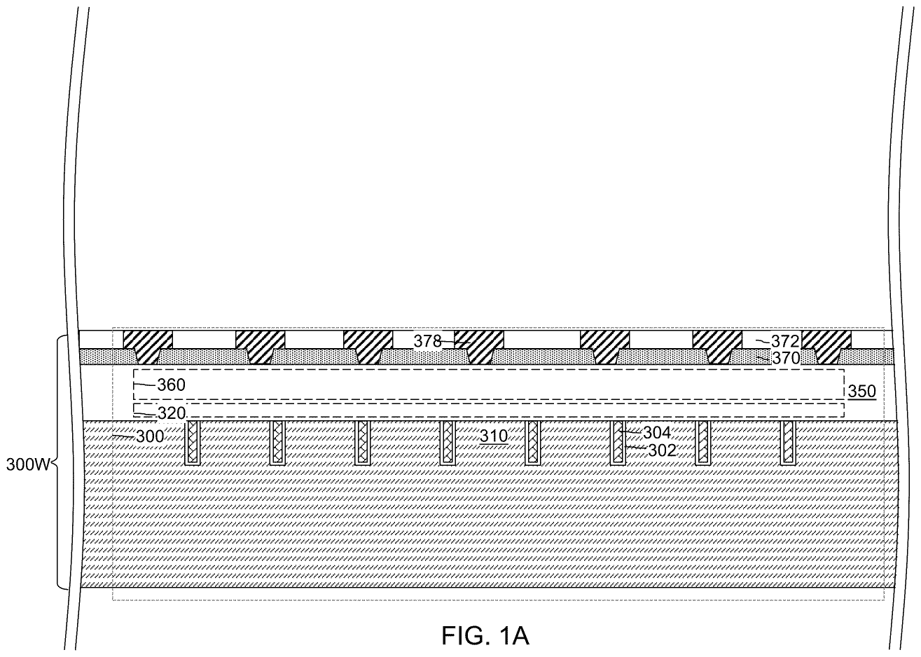

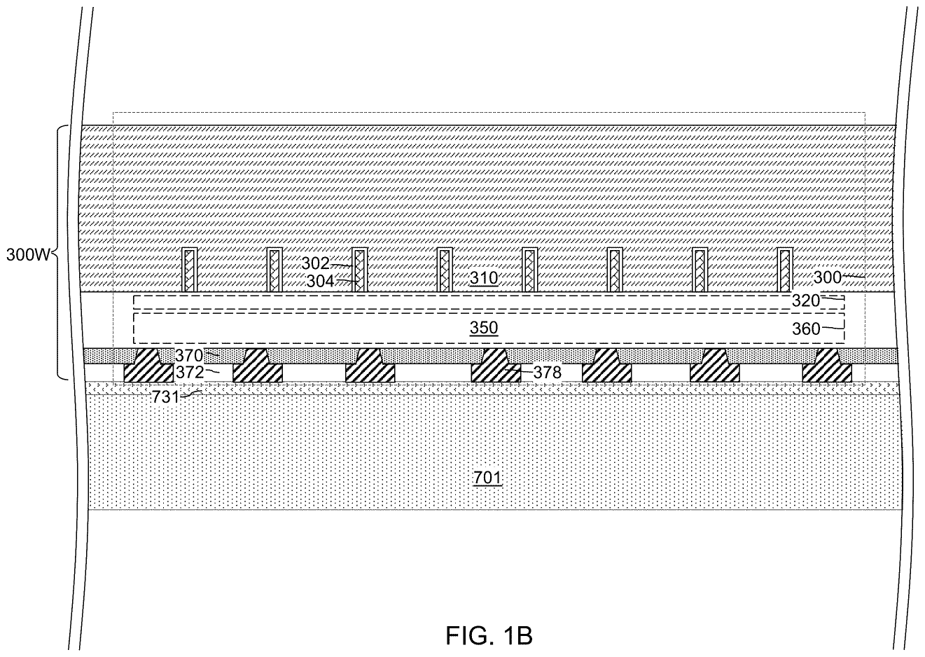

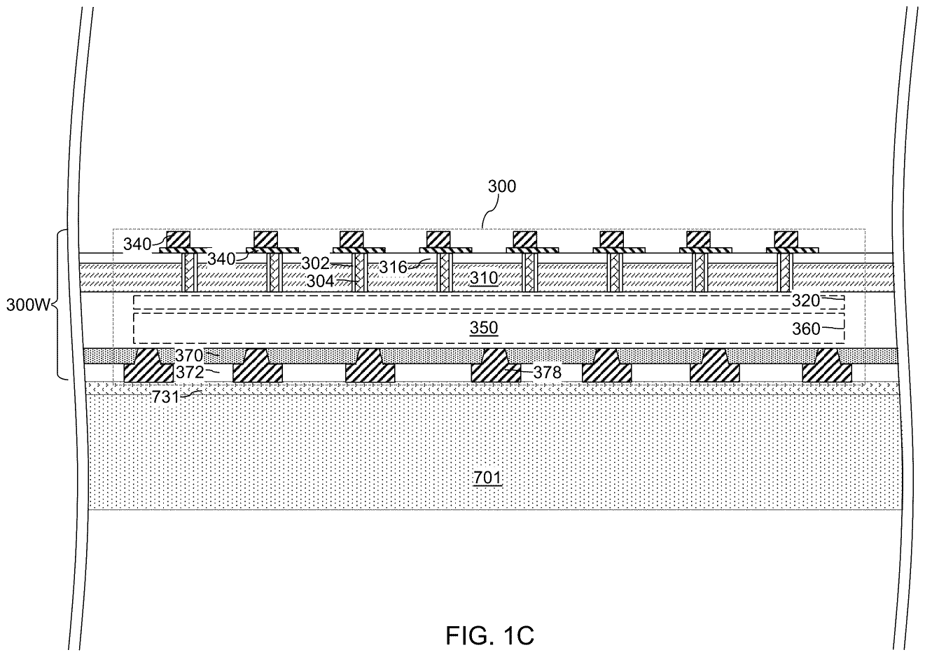

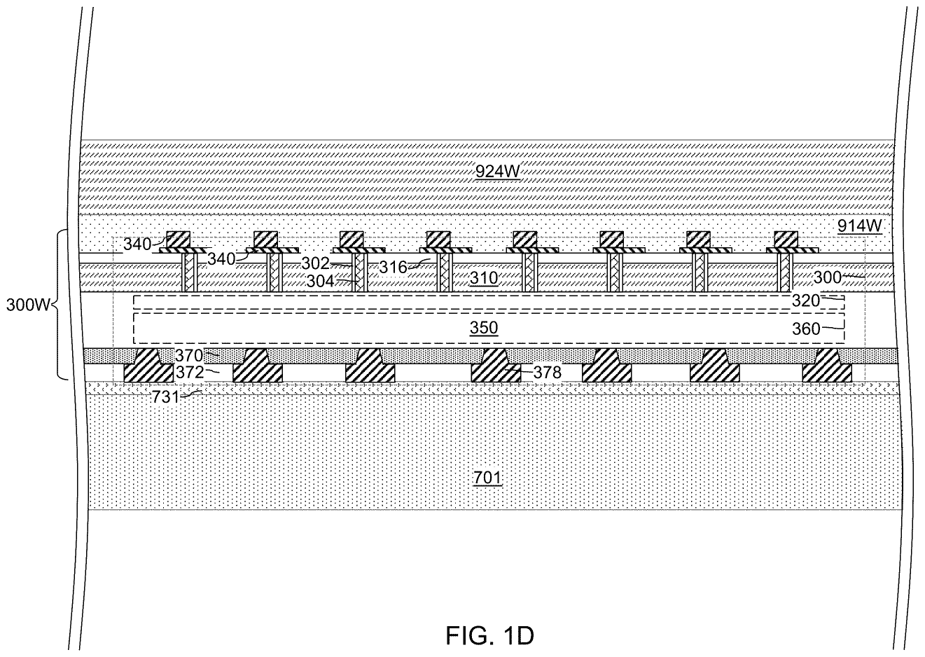

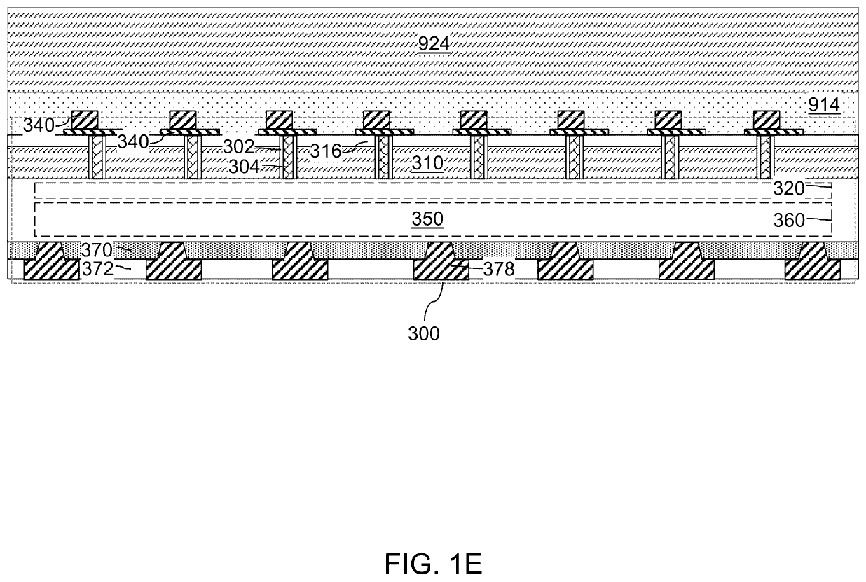

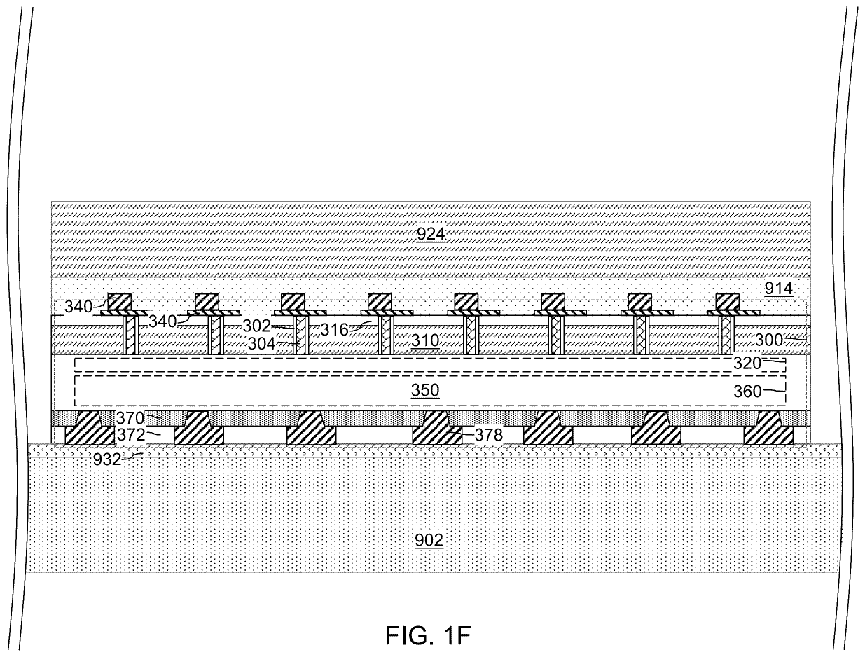

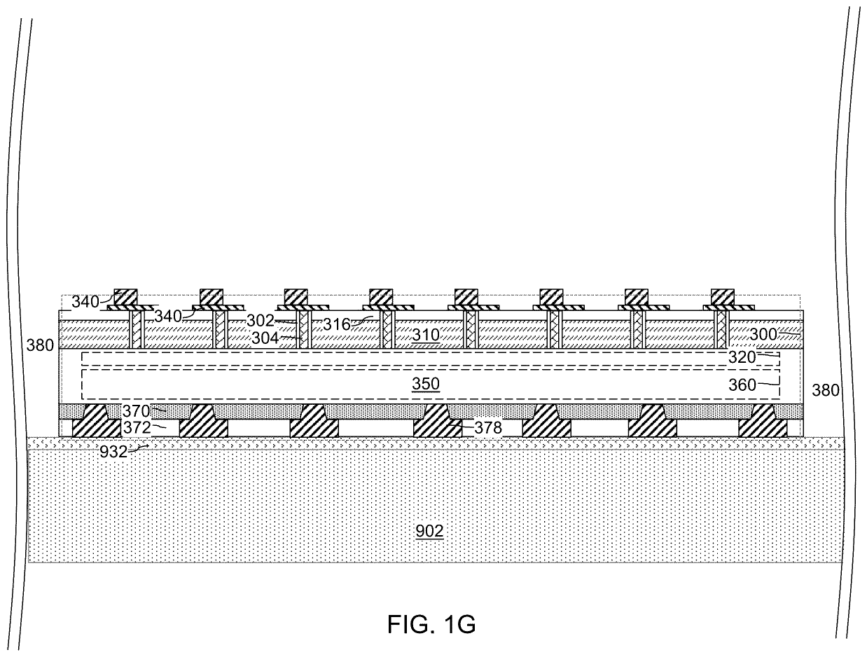

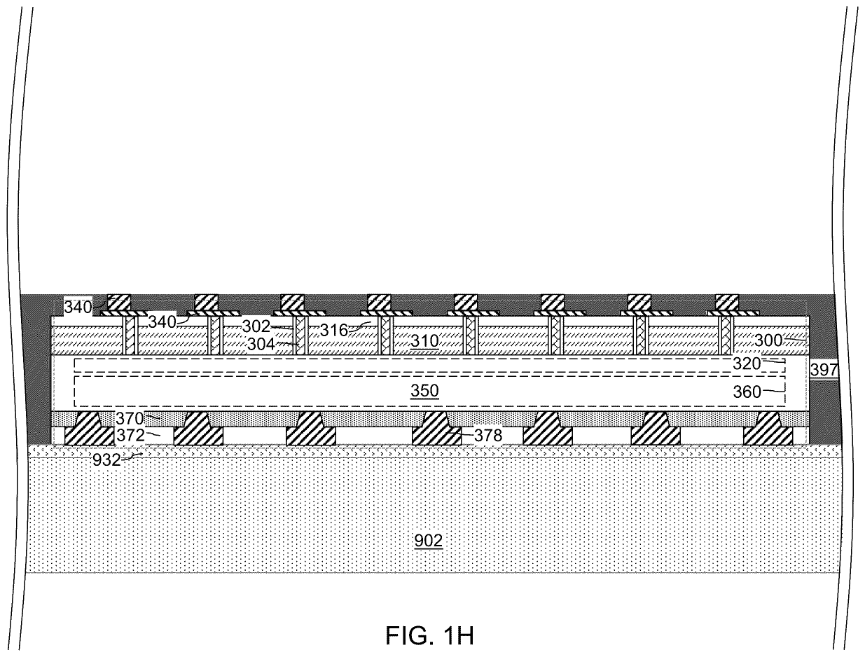

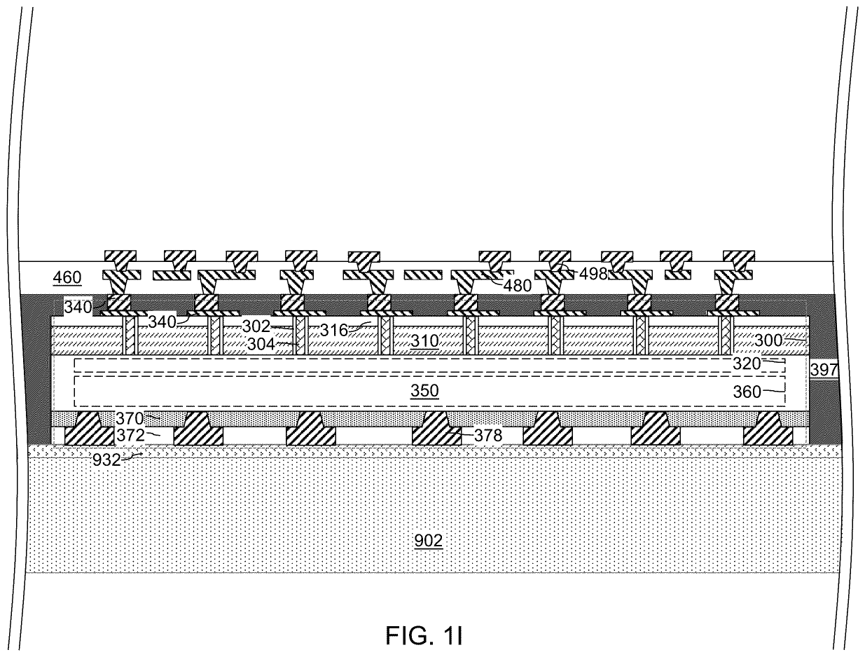

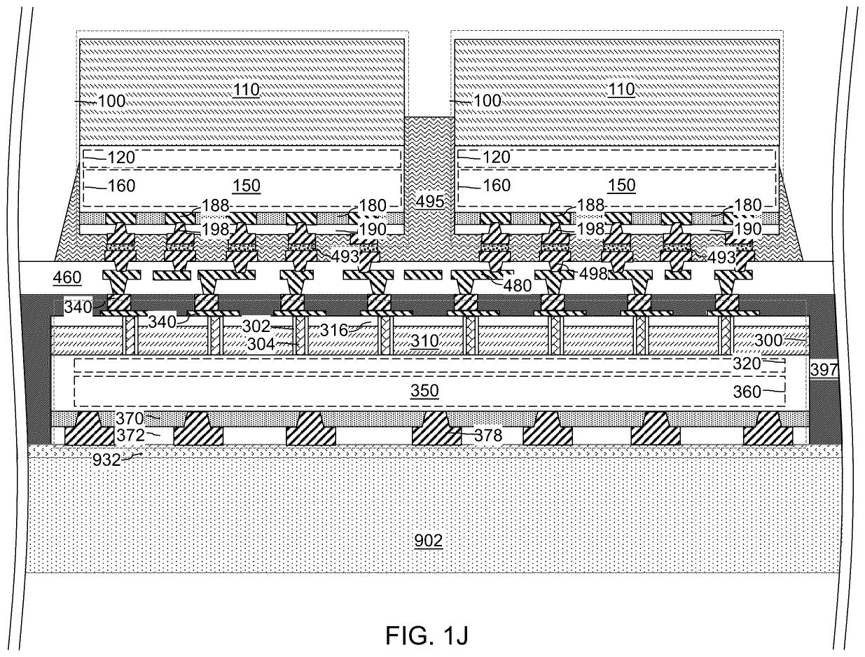

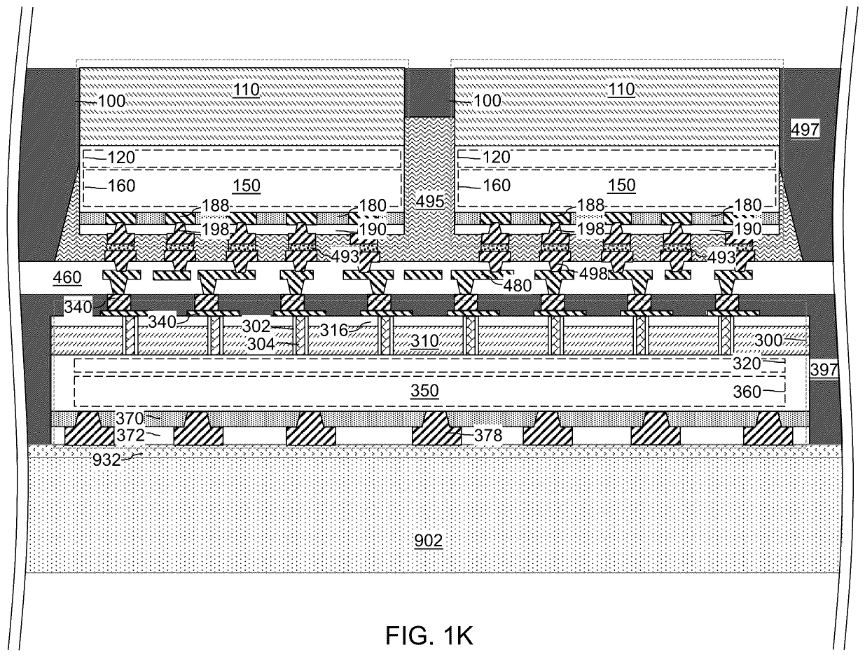

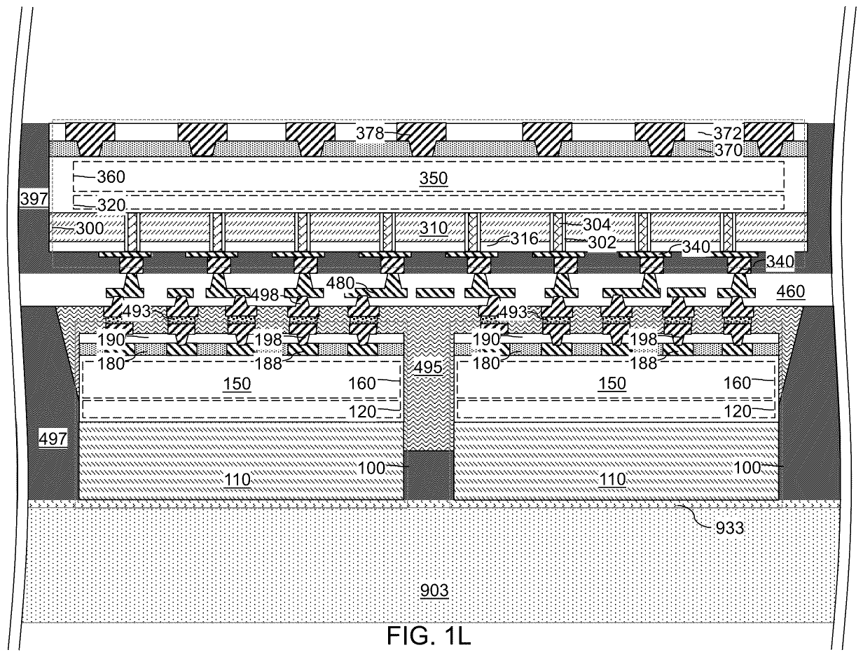

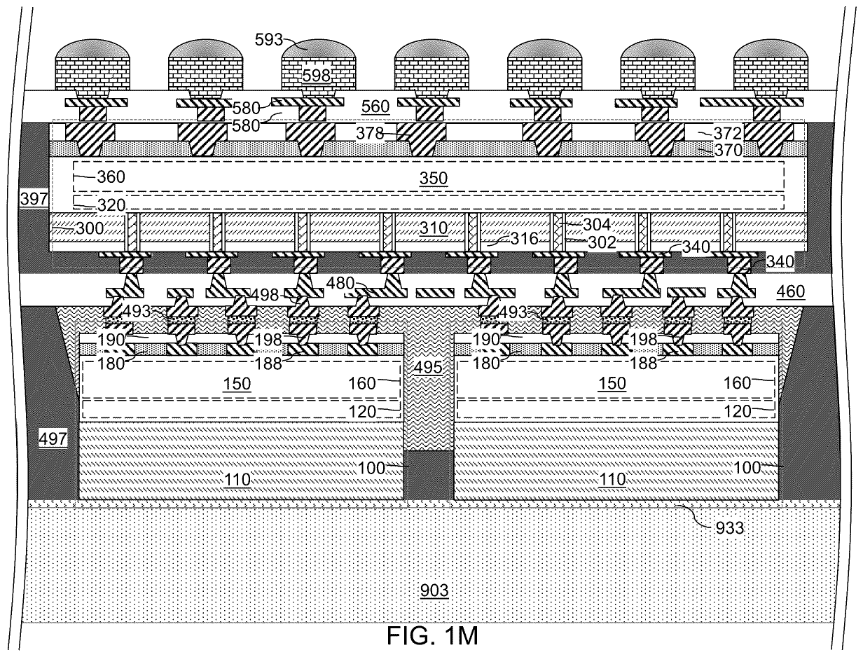

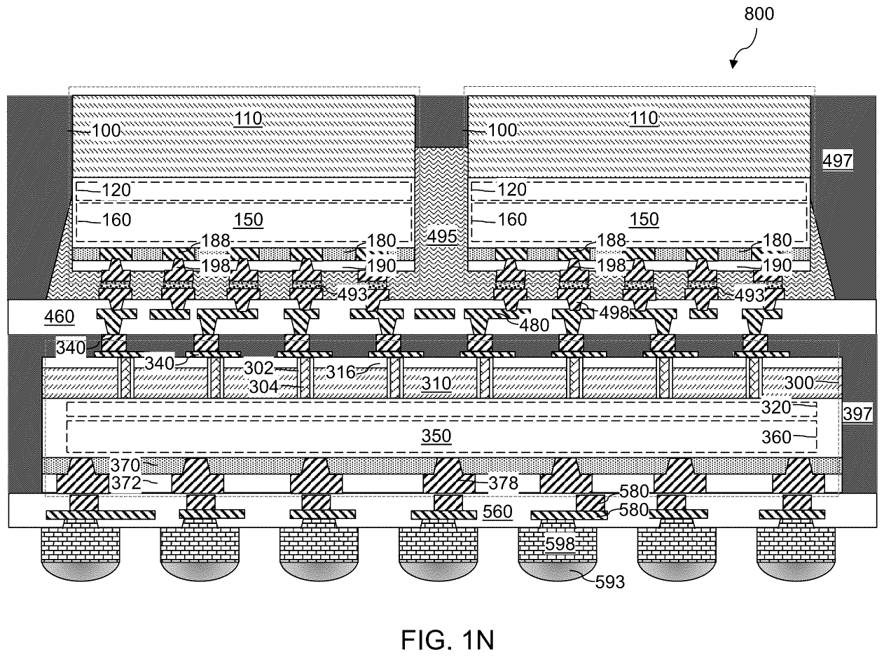

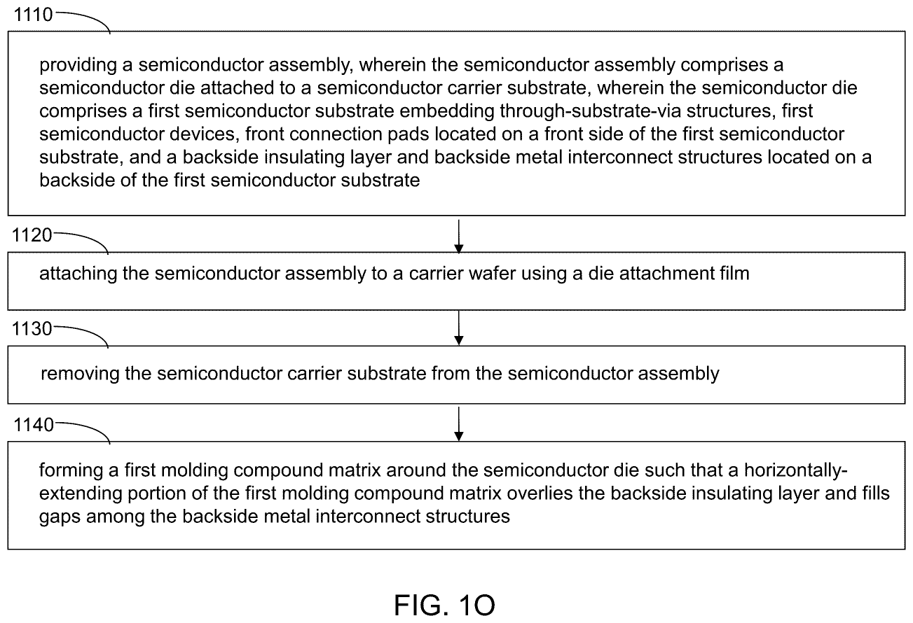

FIGS. 1A-1N are sequential vertical cross-sectional views of a first embodiment structure during a sequence of processing steps according to an embodiment of the present disclosure.

Referring to FIG. 1A, a device wafer 300W is illustrated, which includes a first semiconductor substrate 310 and structural elements formed therein and thereupon. The first semiconductor substrate 310 may comprise a semiconductor wafer such as a commercially available silicon wafer having a diameter of 150 mm, 200 mm, 300 mm, or 450 mm. A two-dimensional array of through-substrate-via-containing (TSV-containing) semiconductor dies 300 may be formed in the device wafer 300W. As used herein, a through-substrate-via-containing semiconductor die refers to a semiconductor die that contains through-substrate-via (TSV) structures, i.e., via structures that vertically extend through the substrate of the semiconductor die. It is to be understood that the TSV-containing semiconductor die 300 illustrated in FIG. 1A is an in-process structure in which TSV structures 304 are formed therein in an upper portion of the first semiconductor substrate 310, and the TSV structures 304 do not vertically extend through the first semiconductor substrate 310. Furthermore, the TSV structures 304 provide a configuration that vertically extends through a thinned first semiconductor substrate 310 upon subsequent thinning of the first semiconductor substrate 310 from the backside.

The two-dimensional array of TSV-containing semiconductor dies 300 may be a rectangular periodic array having a first pitch along a first horizontal direction and having a second pitch along a second horizontal direction. The first pitch may be greater than 5 mm, and/or may be greater than 10 mm, and/or may be greater than 20 nm. The second pitch may be greater than 5 mm, and/or may be greater than 10 mm, and/or may be greater than 20 nm. Borders between neighboring pairs of TSV-containing semiconductor dies 300 comprise dicing channels. Each TSV-containing semiconductor die 300 is located within a respective set of dicing channels. While only a single TSV-containing semiconductor die 300 is illustrated in FIG. 1A, it is understood that the device wafer 300W generally contains a two-dimensional periodic array of TSV-containing semiconductor dies 300.

Generally, an array of via cavities may be formed in an upper portion of the first semiconductor substrate 310. The lateral dimension of each via cavity may be in a range from 0.3 micron to 20 microns, such as from 1 micron to 10 microns, although lesser and greater lateral dimensions may also be used. The depth of each via cavity may be in a range from 1 micron to 30 microns, such as from 3 microns to 15 microns, although lesser and greater depths may also be used. An insulating material layer may be conformally deposited in peripheral regions of the via cavities. The thickness of the insulating material layer may be in a range from 10 nm to 300 nm, although lesser and greater thicknesses may also be used. At least one conductive material, such as at least one metallic material, may be deposited in remaining volumes of the via cavities. A planarization process may be performed to remove portions of the at least one conductive material and the insulating material layer from above the horizontal plane including the top surface of the first semiconductor substrate 310. Remaining portions of the at least one conductive material comprise TSV structures 304. Remaining portions of the insulating material layer comprise insulating spacers 302.

First semiconductor devices 320 may be formed on the top surface of the first semiconductor substrate 310. The first semiconductor devices 320 may comprise active devices such as field effect transistors, and may optionally comprise passive devices such as capacitors, resistors, inductors, etc. The first semiconductor devices 320 may comprise a central processing unit (CPU), a graphic processing unit (GPU), a neural process unit (NPU), a digital signal processor (DSP), an embedded volatile memory, and/or an embedded non-volatile memory.

First metal interconnect structures 360 formed within first dielectric material layers 350 may be formed over the first semiconductor devices 320. The first metal interconnect structures 360 may comprise metal lines, metal via structures, metal pads, or any other metallic structures that may be used to provide electrical interconnection to and from semiconductor devices. The first dielectric material layers 350 may comprise any interlayer dielectric (ILD) material known in the art. In one embodiment, the first dielectric material layers 350 may comprise, and/or may consist of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. It is noted that “organosilicate glass” as used in the semiconductor industry is an inorganic material despite the name. Organosilicate glass (OSG) refers to a silicon dioxide (SiO₂)-based dielectric material that incorporates organic groups, typically alkyl groups such as methyl or ethyl, to modify its properties. These organic groups are introduced to lower the dielectric constant of the material, which reduces parasitic capacitance in integrated circuits, thereby enhancing performance. However, the core structure of organosilicate glass remains primarily composed of silicon-oxygen bonds, characteristic of inorganic materials. Thus, while organosilicate glass contains organic components as functional additives, it is classified as an inorganic material due to its predominant silicon-oxygen backbone.

At least one front capping dielectric layer (370, 372) and front connection pads 378 may be subsequently formed over the first metal interconnect structures 360. The at least one front capping dielectric layer (370, 372) may comprise a stack of a first front capping dielectric layer 370 and a second front capping dielectric layer 372. In one embodiment, the front connection pads 378 may comprise metal via portions vertically extending through the first front capping dielectric layer 370 and metal pad portions formed within the second front capping dielectric layer 372. In one embodiment, the first front capping dielectric layer 370 may be formed over the first metal interconnect structures 360, and via openings may be formed through the first front capping dielectric layer 370. A metal layer may be deposited in the via openings and over the top surface of the first front capping dielectric layer 370, and may be subsequently patterned to form the front connection pads 378. The second front capping dielectric layer 372 may be formed by depositing and planarizing a dielectric material over the front connection pads 378. Top surfaces of the front connection pads 378 may be physically exposed, and may be formed within the horizontal plane including the top surface of the second front capping dielectric layer 372. In one embodiment, the first front capping dielectric layer 370 may comprise silicon nitride, and the second front capping dielectric layer 372 may comprise silicon oxide. The front connection pads 378 may comprise copper or aluminum.

Referring to FIG. 1B, the device wafer 300W may be attached to a handle wafer 701, for example, using a die attachment film 731. The handle wafer 701 may be any wafer that may be used to provide mechanical support during subsequent handling of the device wafer 300W. In one embodiment, the handle wafer 701 may comprise a glass carrier wafer having a same lateral dimension as the device wafer 300W.

Referring to FIG. 1C, the device wafer 300W may be inverted and thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing process. The remaining portion of the insulating material constitutes a backside insulating layer 316. Physically exposed backside surfaces of the TSV structures 304 may be coplanar with a physically exposed horizontal surface of the backside insulating layer 316.

At least one metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Referring to FIG. 1D, a semiconductor carrier wafer 924W may be attached to the device wafer 300W using a continuous adhesive layer 914W. The semiconductor carrier wafer 924W may comprise a commercially available semiconductor wafer (such as a silicon wafer) having a same lateral extent as the device wafer 300W. The continuous adhesive layer 914W may comprise a glue layer. For example, the continuous adhesive layer 914W may comprise a thermosetting adhesive, such as benzocyclobutene (BCB) or an epoxy-based adhesive. The continuous adhesive layer 914W provides adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 914W, 924W) of the device wafer 300W, the continuous adhesive layer 914W, and the semiconductor carrier wafer 924W is formed.

Referring to FIG. 1E, the die attachment film 731 may be deactivated to facilitate the detachment of the handle wafer 701 from the wafer-level bonded assembly (300W, 914W, 924W). For instance, the die attachment film 731 may comprise an ultraviolet-decomposable material, and the handle wafer 701 may comprise a transparent wafer such as a glass substrate. In this embodiment, ultraviolet radiation may impinge on the die attachment film through the handle wafer 701 to break down the adhesive properties of the film, enabling easy detachment. Once the die attachment film 731 is deactivated, the handle wafer 701 is removed, leaving the device wafer 300W securely bonded to the semiconductor carrier wafer 924W via the continuous adhesive layer 914W. To prepare the surface for subsequent processing, any residual die attachment film 731 may be eliminated through a cleaning process, such as solvent cleaning or plasma etching, ensuring a contaminant-free interface.

The wafer-level bonded assembly (300W, 914W, 924W) may be subsequently diced along dicing channels. The dicing channels extend along boundaries between neighboring pairs of TSV-containing semiconductor dies 300. Diced portions of the wafer-level bonded assembly (300W, 914W, 924W) comprise semiconductor assemblies (300, 914, 924). Each semiconductor assembly (300, 914, 924) comprises a through-substrate-via-containing (TSV-containing) semiconductor die 300, an adhesive layer 914, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and backside metal interconnect structures 340 located on a backside of the first semiconductor substrate 310.

Referring to FIG. 1F, a plurality of semiconductor assemblies (300, 914, 924) provided through the processing steps described with reference to FIGS. 1A-1E may be attached to a carrier wafer 902 using a die attachment film 932. It is to be understood that a region around a single semiconductor assembly (300, 914, 924) is illustrated in FIG. 1F and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 914, 924) may be attached to the die attachment film 932. In one embodiment, the two-dimensional array of semiconductor assemblies (300, 914, 924) may be arranged as a two-dimensional rectangular array of semiconductor assemblies (300, 914, 924). A gap may be present between each neighboring pair of semiconductor assemblies (300, 914, 924).

Referring to FIG. 1G, each of the semiconductor carrier substrates 924 within the array of semiconductor assemblies (300, 914, 924) may be detached from a respective one of the TSV-containing semiconductor dies 300. Each semiconductor carrier substrate 924 may be detached from a respective TSV-containing semiconductor die 300 by performing a debonding process that uses thermal debonding or solvent debonding. For example, each adhesive layer 914 may be deactivated to facilitate the detachment of the semiconductor carrier substrates 924 from the TSV-containing semiconductor dies 300. Specifically, the adhesive layers 914, which may comprise a thermally-decomposable material, may be decomposed by performing an anneal process at an elevated temperature in a range from 150° C. to 300° C. Alternatively, the adhesive layers 914 may be removed by dissolution using a suitable solvent. Once deactivated, the semiconductor carrier substrates 924 are removed, leaving the TSV-containing semiconductor dies 300 exposed and ready for subsequent processing. To ensure a pristine surface, any residual adhesive from the adhesive layers 914 may be eliminated through a cleaning process, such as solvent cleaning or plasma etching, ensuring a contaminant-free interface for further manufacturing steps. Thus, the semiconductor carrier substrate 924 and the adhesive layer 914 may be removed from each semiconductor assembly (300, 914, 924). The removal of the semiconductor carrier substrate 924 and the adhesive layer 914 from the semiconductor dies 300 may result in an gap 380 or cavity between adjacent semiconductor dies 300.

Referring to FIG. 1H, a first molding compound matrix 397 may be formed around the two-dimensional array of TSV-containing semiconductor dies 300. The first molding compound matrix 397 may comprise an epoxy molding compound (EMC). Typically, the EMC contains an epoxy resin, a hardener, silica fillers, and other additives to enhance its performance. A high filler content, such as 85% by weight, may be used to reduce mold shrinkage, minimize warpage, and improve flowability during the encapsulation process. The filler distribution suppresses flow marks during molding, thereby promoting a smooth application of the EMC. The EMC may be cured at a temperature ranging from 125° C. to 150° C., thereby preserving the integrity of the assembly during the molding process. The first molding compound matrix 397 may also fill the gaps 380 that occur between semiconductor dies 300 after the removal of the semiconductor carrier substrate 924 and the adhesive layer 914 from the semiconductor dies 300. See e.g., FIG. 1G.

After curing, excess molding compound may be removed from above the first backside metal interconnect structures 340 by performing a planarization process. Specifically, portions of the cured EMC material that overlie the horizontal plane including topmost surfaces of the first backside metal interconnect structures 340 may be removed by performing a chemical mechanical polishing process. A remaining portion of the cured EMC material constitutes the first molding compound matrix 397.

The first molding compound matrix 397 may embed a two-dimensional array of TSV-containing semiconductor dies 300, may have a top surface located within a horizontal plane including topmost surfaces of the first backside metal interconnect structures 340, and may comprise a planar bottom surface contacting the top surface of the die attachment film 932. The first molding compound matrix 397 provides mechanical support and environmental protection for the TSV-containing semiconductor dies 300. The first molding compound matrix 397 may contact sidewalls of the backside metal interconnect structures 340 and a horizontal top surface of the backside insulating layer 316.

Referring to FIG. 1I, a first bonding dielectric layer 460 having formed therein first bonding-level metal interconnect structures 480 may be formed on the top surface of the first molding compound matrix 397. The first bonding dielectric layer 460 comprises at least one interlayer dielectric (ILD) layer, which may include at least one via-level dielectric layer and/or at least one line-level dielectric layer. The first bonding dielectric layer 460 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The first bonding-level metal interconnect structures 480 may comprise metal via structures, metal line structures, metal pad structures, etc.

First bump structures 498 may be formed at the topmost level of the first bonding dielectric layer 460. Each of the first bump structures 498 may be formed on a respective one of the backside metal interconnect structures 340, which overlies the first molding compound matrix 397. In one embodiment, the first bump structures 498 may comprise via portions formed within, and laterally surrounded by, the first bonding dielectric layer 460. Further, the first bump structures 498 may comprise pillar structures or pad structures overlying the topmost surface of the first bonding dielectric layer 460. In one embodiment, the first bump structures 498 may comprise chip connection (C2) bonding structures such as microbump structures.

Referring to FIG. 1J, device semiconductor dies 100 may be attached to the first bump structures 498 using arrays of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having formed therein a respective set of connection metal pads 188, and a respective bump-level dielectric layer 190 having formed therein a respective set of second bump structures 198. The second bump structures 198 of the device semiconductor dies 100 may be bonded to the first bump structures 498 through the arrays of solder material portions 493.

An underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

Referring to FIG. 1K, a second molding compound matrix 497 may be formed around the device semiconductor dies 100 and the underfill material portion 495 and directly on the first bonding dielectric layer 460. The second molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing process. A remaining portion of the cured EMC material constitutes the second molding compound matrix 497.

The second molding compound matrix 497 may embed a two-dimensional array of sets of device semiconductor dies 100, may have a top surface located within a horizontal plane including topmost surfaces of the device semiconductor dies 100, and may comprise a planar bottom surface contacting the top surface of the first bonding dielectric layer 460. The second molding compound matrix 497 provides mechanical support and environmental protection for the device semiconductor dies 100. Generally, the second molding compound matrix 497 is vertically spaced from the first molding compound matrix 397 by the first bonding dielectric layer 460, and does not contact the first molding compound matrix 397. The second molding compound matrix 497 may be formed around the device semiconductor dies 100 directly on the first bonding dielectric layer 460.

Referring to FIG. 1L, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation. A suitable clean process may be performed to clean physically exposed surfaces of the front connection pads 378, the second front capping dielectric layer 372, and a horizontal surface of the first molding compound matrix 397.

Referring to FIG. 1M, a second bonding dielectric layer 560 having formed therein a second bonding-level metal interconnect structures 580 may be formed on the front connection pads 378. The second bonding dielectric layer 560 may be formed directly on the first molding compound matrix 397. The second bonding dielectric layer 560 comprises at least one interlayer dielectric (ILD) layer, which may include at least one via-level dielectric layer and/or at least one line-level dielectric layer. The second bonding dielectric layer 560 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The second bonding-level metal interconnect structures 580 may comprise metal via structures, metal line structures, metal pad structures, etc.

Metal bump structures 598 may be formed at the topmost level of the second bonding dielectric layer 560. Each of the metal bump structures 598 may be formed on a respective one of the second bonding-level metal interconnect structures 580, which overlies and contacts the first molding compound matrix 397. In one embodiment, the metal bump structures 598 may comprise via portions formed within, and laterally surrounded by, the second bonding dielectric layer 560. Further, the metal bump structures 598 may comprise pad structures overlying the topmost surface of the second bonding dielectric layer 560. In one embodiment, the metal bump structures 598 may comprise controlled collapse chip connection (C4) pads. Each of the metal bump structures 598 may be formed directly on a respective one of the second bonding-level metal interconnect structures 580 and over the second bonding dielectric layer 560. Solder balls 593 may be attached to the metal bump structures 598.

Referring to FIG. 1N, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the second molding compound matrix 497.

A dicing process may be performed to dice (singulate) a reconstituted die including a two-dimensional array of TSV-containing semiconductor dies 300, the first molding compound matrix 397, the first bonding dielectric layer 460, a two-dimensional array of sets of device semiconductor dies 100, a two-dimensional array of underfill material portions 495, and the second molding compound matrix 497. Generally, the reconstituted die comprises at least the bonding dielectric layer 560, the first molding compound matrix 397, and the first bonding dielectric layer 460. Diced portions of the reconstituted die comprise composite dies 800. Each composite die 800 comprises a TSV-containing semiconductor die 300, a diced portion of the second bonding dielectric layer 560, a diced portion of the first molding compound matrix 397, a diced portion of the first bonding dielectric layer 460, and a diced portion of the second molding compound matrix 497.

The exemplary structure illustrated in FIG. 1N comprises a semiconductor package, which comprises: a through-substrate-via-containing (TSV-containing) semiconductor die 300 comprising a first semiconductor substrate 310 having through-substrate-via (TSV) structures 304 formed therein, first semiconductor devices 320 and front connection pads 378 located on a front side of the first semiconductor substrate 310, and backside metal interconnect structures 340 located on a backside of the first semiconductor substrate 310; a first molding compound matrix 397 laterally surrounding the TSV-containing semiconductor die 300; a first bonding dielectric layer 460 located on the backside metal interconnect structures 340; and first bump structures 498 located on the first bonding dielectric layer 460.

In one embodiment, the semiconductor package comprises device semiconductor dies 100 attached to the first bump structures 498 via arrays of solder material portions 493. In one embodiment, the semiconductor package comprises: an underfill material portion 495 laterally surrounding the arrays of solder material portions 493; and a second molding compound matrix 497 laterally surrounding the device semiconductor dies 100 and the underfill material portion 495. In one embodiment, sidewalls of the first bonding dielectric layer 460 are vertically coincident with outer sidewalls of the second molding compound matrix 497. In one embodiment, the second molding compound matrix 497 is vertically spaced from the first molding compound matrix 397 by the first bonding dielectric layer 460.

In one embodiment, sidewalls of the first bonding dielectric layer 460 are vertically coincident with outer sidewalls of the first molding compound matrix 397. In one embodiment, the semiconductor package comprises a second bonding dielectric layer 560 having bonding-level metal interconnect structures 580 formed therein and contacting the front connection pads 378. In one embodiment, the second bonding dielectric layer 560 may be in contact with the first molding compound matrix 397. In one embodiment, sidewalls of the second bonding dielectric layer 560 are vertically coincident with outer sidewalls of the first molding compound matrix 397.

In one embodiment, the first bonding dielectric layer 460 may have first bonding-level metal interconnect structures 480 formed therein. The first bump structures 498 are in contact with a subset of the first bonding-level metal interconnect structures 480. In one embodiment, the first molding compound matrix 397 is in contact with sidewalls of the backside metal interconnect structures 340. In one embodiment, the TSV-containing semiconductor die 300 comprises a backside insulating layer 316 interposed between the first semiconductor substrate 310 and the backside metal interconnect structures 340. In one embodiment, the first molding compound matrix 397 is in contact with a horizontal surface of the backside insulating layer 316. In one embodiment, the first semiconductor devices 320 comprise first field effect transistors; and each of the device semiconductor dies 100 comprises a respective set of additional field effect transistors.

Referring to FIG. 1O, a first flow chart including a subset of processing steps for forming a semiconductor structure is provided.

Referring to step 1110 and FIGS. 1A-1E, a semiconductor assembly (300, 914, 924) is provided, which comprises a through-substrate-via-containing (TSV-containing) semiconductor die 300, an adhesive layer 914, and a semiconductor carrier substrate 924. The TSV-containing semiconductor die 300 comprises a first semiconductor substrate 310 having formed therein through-substrate-via (TSV) structures 304, first semiconductor devices 320 and front connection pads 378 located on a front side of the first semiconductor substrate 310, and backside metal interconnect structures 340 located on a backside of the first semiconductor substrate 310.

Referring to step 1120 and FIG. 1F, the semiconductor assembly (300, 914, 924) may be attached to a carrier wafer 902 using a die attachment film 932.

Referring to step 1130 and FIGS. 1G-1N, the semiconductor carrier substrate 924 and the adhesive layer 914 may be removed from the semiconductor assembly (300, 914, 924).

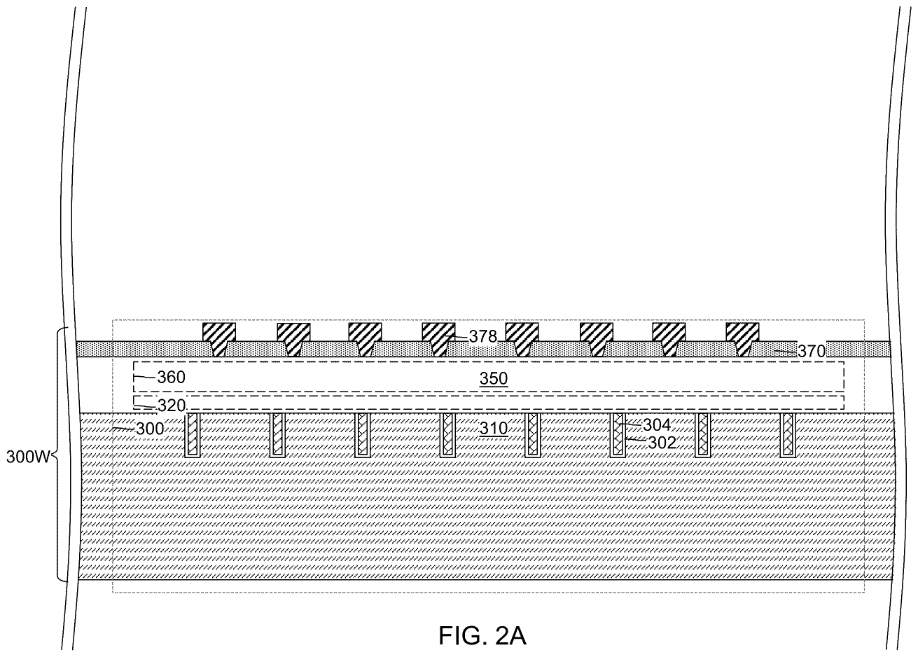

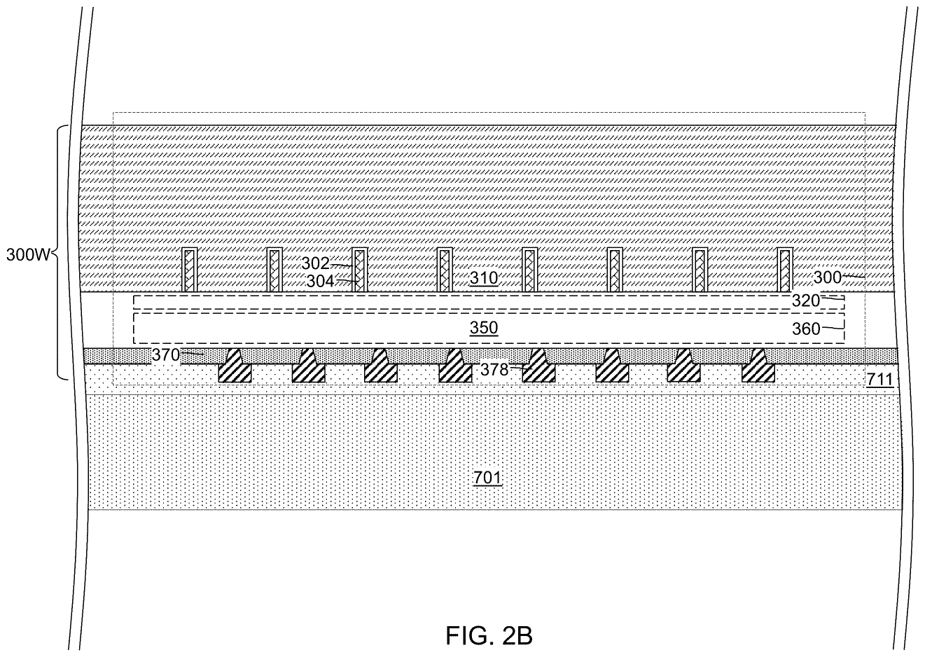

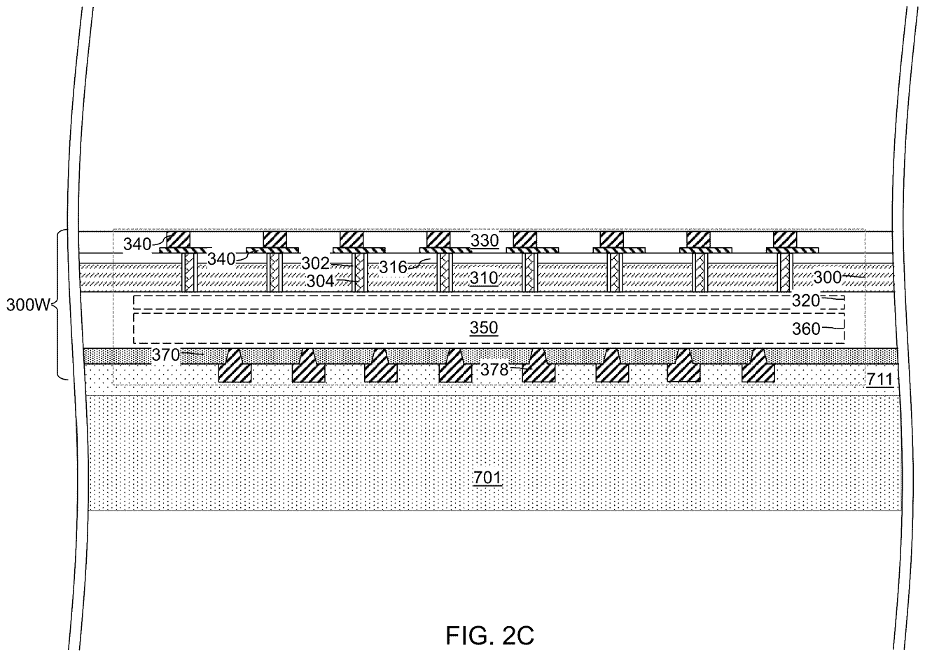

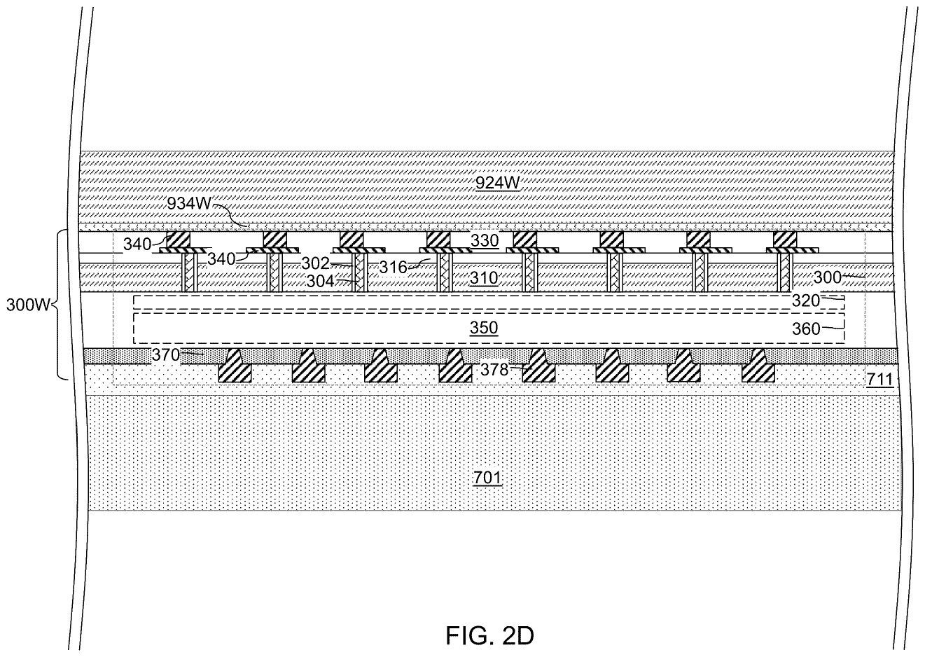

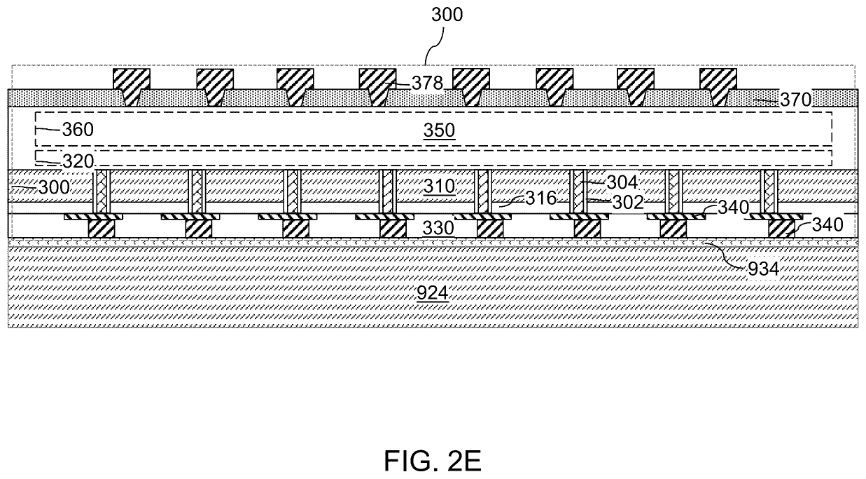

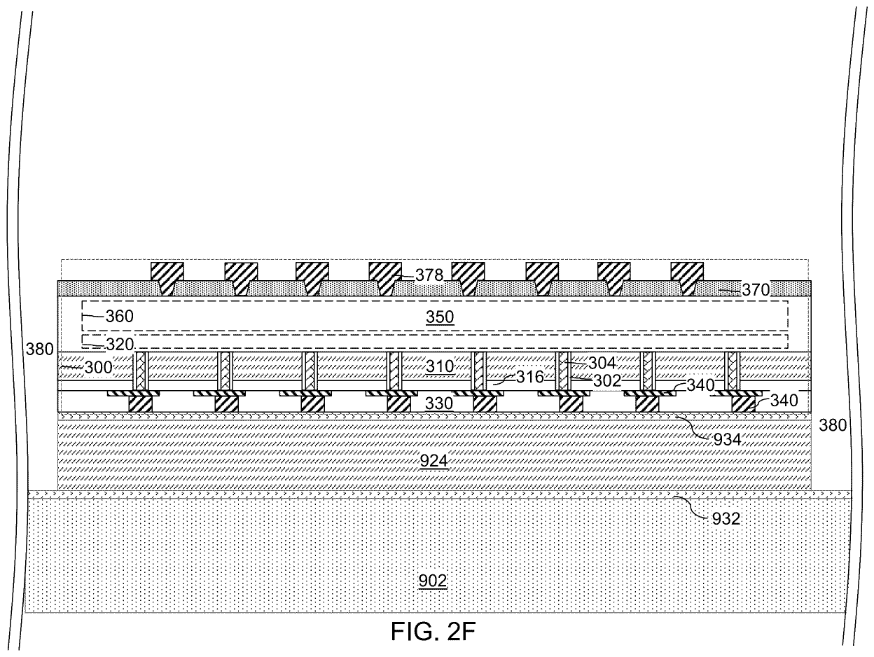

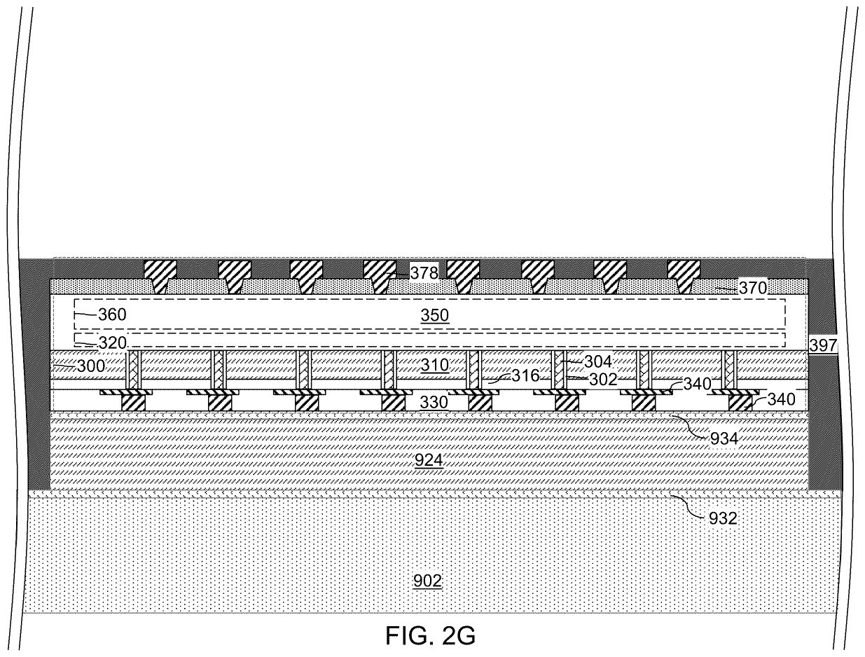

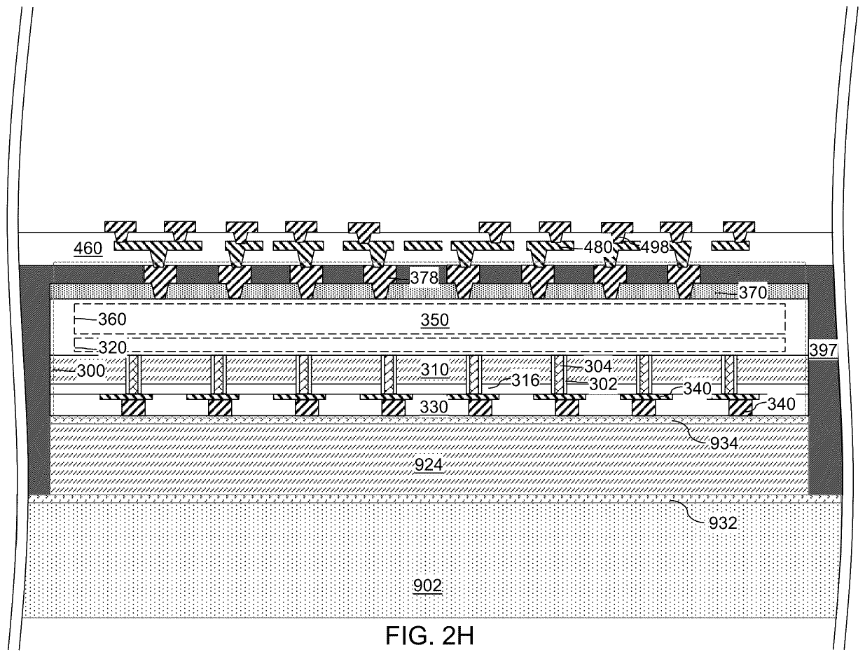

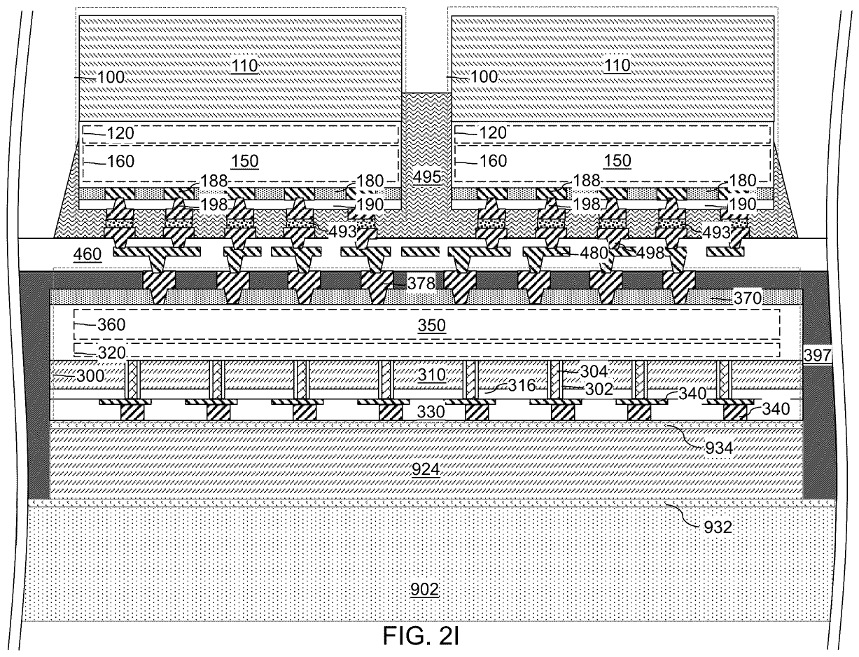

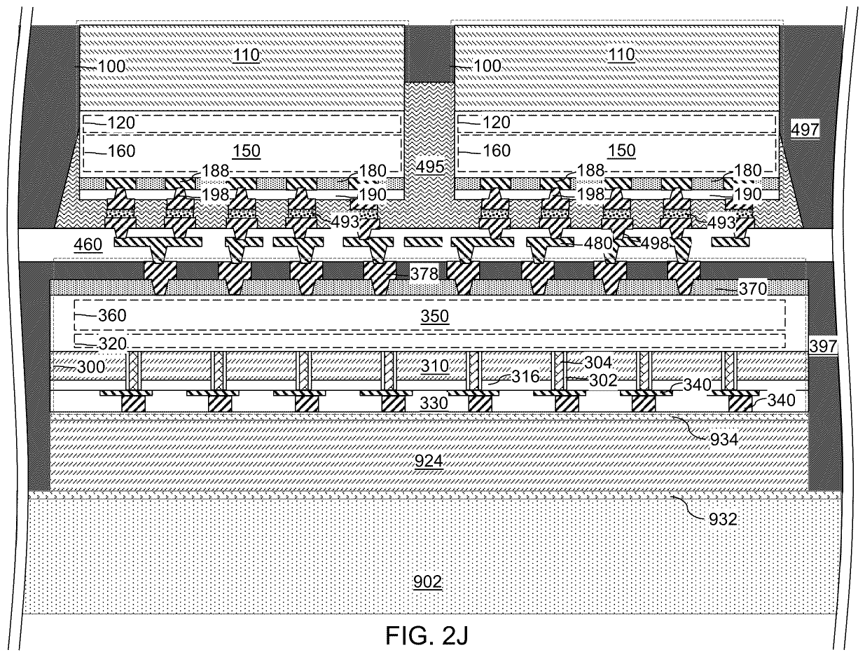

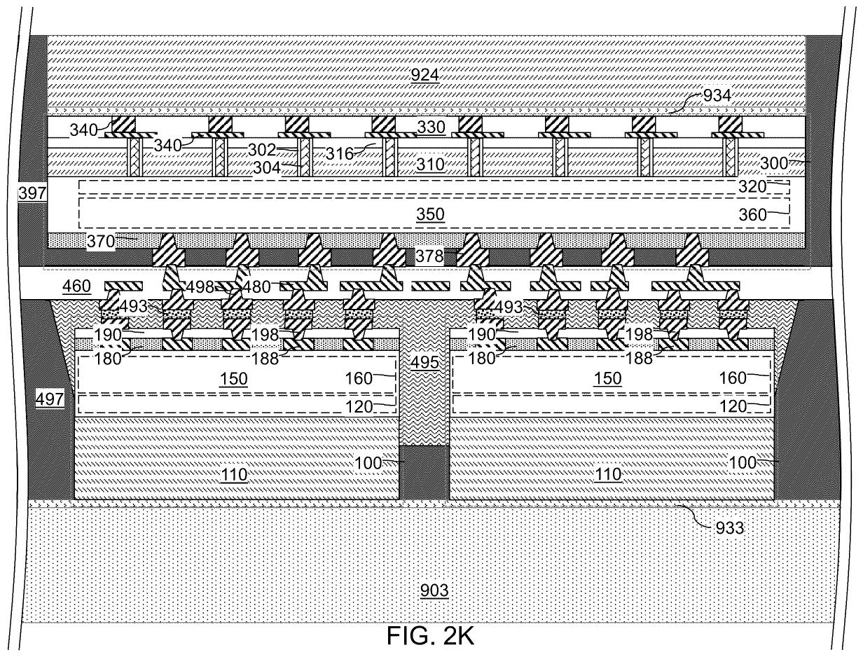

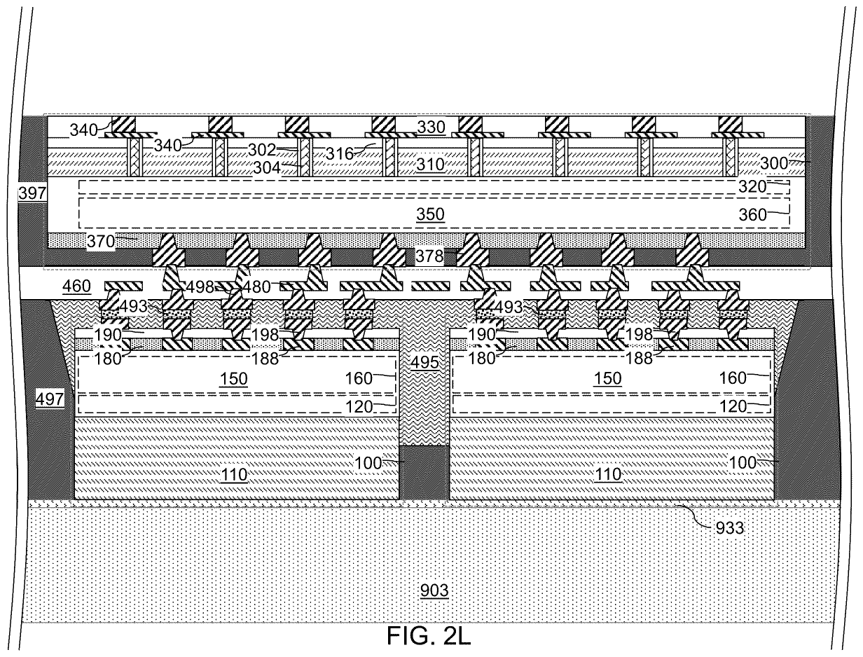

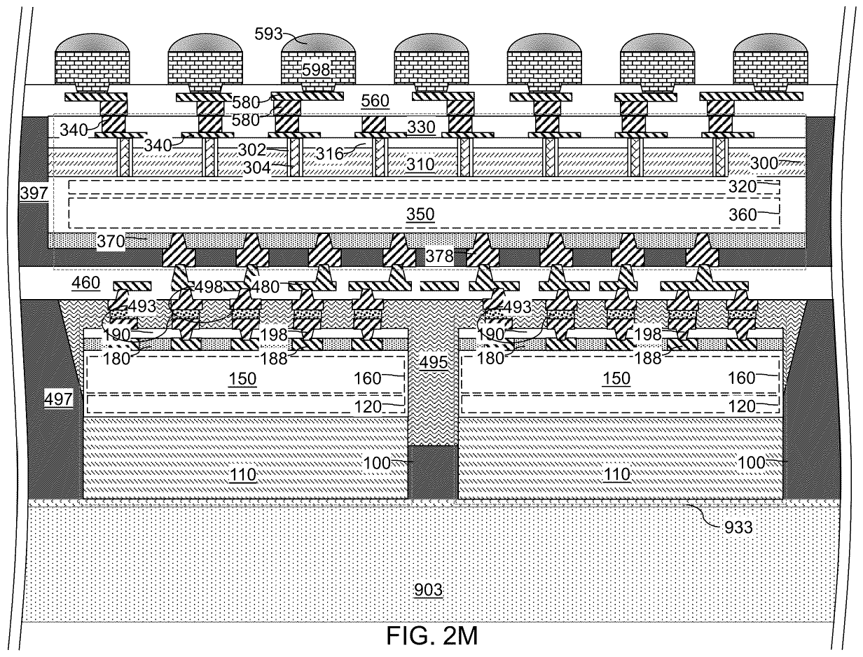

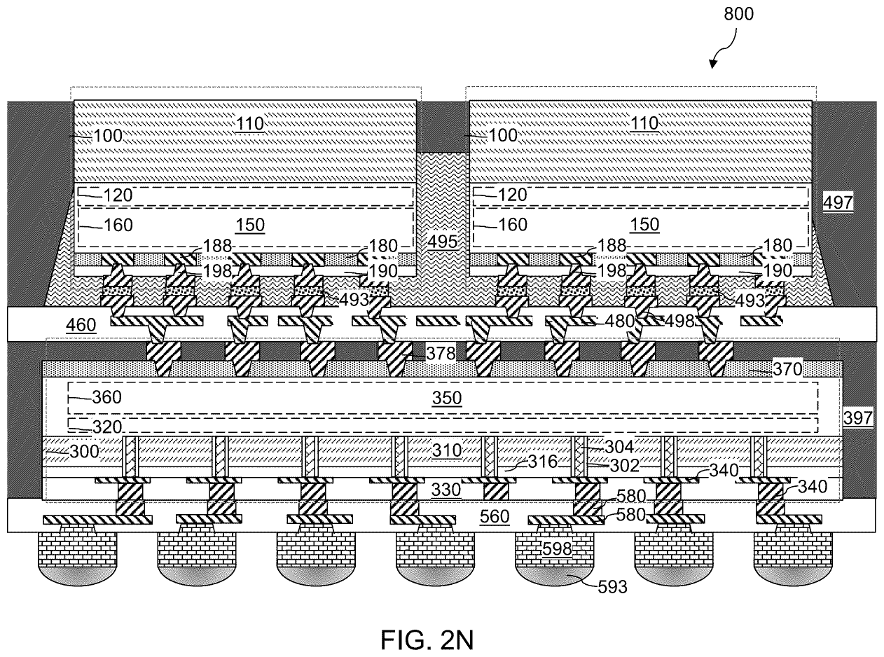

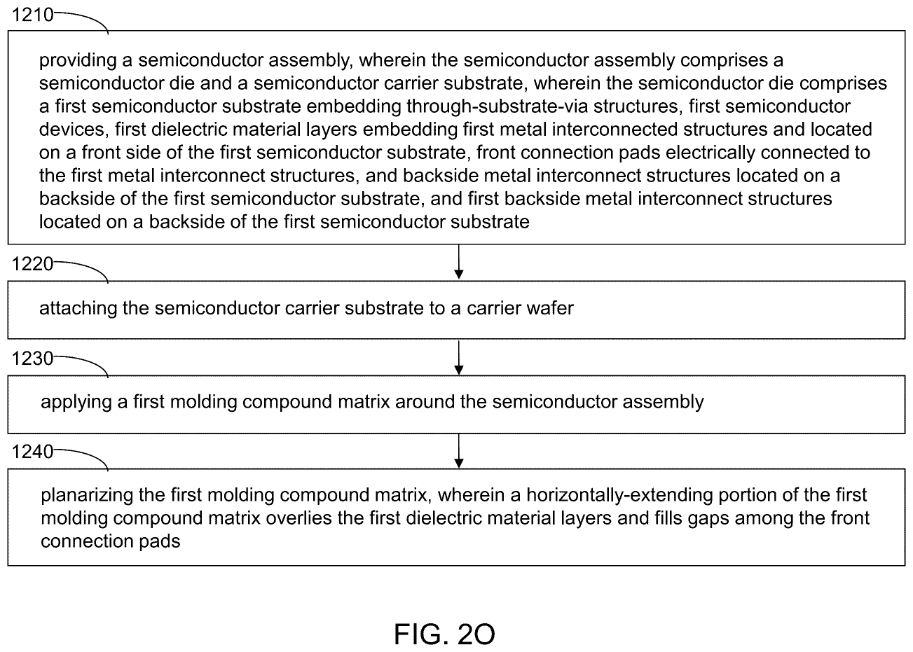

FIGS. 2A-2N are sequential vertical cross-sectional views of a second embodiment structure during a sequence of processing steps according to an embodiment of the present disclosure.

Referring to FIG. 2A, a device wafer 300W is illustrated, which includes a first semiconductor substrate 310 and structural elements formed therein and thereupon. The device wafer 300W may be derived from the device wafer 300W illustrated in FIG. 1A by omitting formation of the second front capping dielectric layer 372. In this embodiment, the front connection pads 378 may comprise metal via portions vertically extending through the first front capping dielectric layer 370 and metal pad portions overlying the first front capping dielectric layer 370. In one embodiment, the first front capping dielectric layer 370 may be formed over the first metal interconnect structures 360, and via openings may be formed through the first front capping dielectric layer 370. A metal layer may be deposited in the via openings and over the top surface of the first front capping dielectric layer 370, and may be subsequently patterned to form the front connection pads 378. Top surfaces and sidewalls of the metal pad portions of the front connection pads 378 may be physically exposed. In one embodiment, the first front capping dielectric layer 370 may comprise silicon nitride. The front connection pads 378 may comprise copper or aluminum.

Referring to FIG. 2B, the device wafer 300W may be attached to a handle wafer 701, for example, using an adhesive layer 711. The adhesive layer 711 may comprise a thermally decomposable material, a UV-decomposable material, or a combination thereof, depending on the process criteria. In semiconductor manufacturing, adhesive layers are commonly made from polymers such as polyimides, benzocyclobutene (BCB), epoxy-based adhesives, or other thermosetting resins. These materials are selected based on their ability to provide strong adhesion while allowing for subsequent easy detachment during debonding processes. For example, UV-decomposable adhesives may be preferred when the handle wafer 701 is a transparent substrate like glass, enabling UV exposure through the handle wafer to facilitate debonding. Thermally decomposable adhesives may be utilized when thermal processing may be used to degrade the adhesive and separate the wafers. The adhesive layer 711 ensures secure attachment during the handling and processing of the device wafer 300W. The handle wafer 701, in this embodiment, may comprise a glass carrier wafer with the same lateral dimensions as the device wafer 300W, providing mechanical support during subsequent steps in the manufacturing process.

Referring to FIG. 2C, the device wafer 300W may be thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing process. The remaining portion of the insulating material constitutes a backside insulating layer 316. Physically exposed backside surfaces of the TSV structures 304 may be coplanar with a physically exposed horizontal surface of the backside insulating layer 316.

At least one metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Referring to FIG. 2D, a semiconductor carrier wafer 924W may be attached to the device wafer 300W using a continuous die attachment film 934W. For example, the continuous die attachment film 934W may comprise a thermally decomposable adhesive material. The continuous die attachment film 934W provides adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 934W, 924W) of the device wafer 300W, the continuous die attachment film 934W, and the semiconductor carrier wafer 924W is formed.

Referring to FIG. 2E, the adhesive layer 711 may be deactivated to facilitate the detachment of the handle wafer 701 from the wafer-level bonded assembly (300W, 934W, 924W). For instance, the adhesive layer 711 may comprise an ultraviolet-decomposable material, and the handle wafer 701 may comprise a transparent wafer such as a glass substrate. In this embodiment, ultraviolet radiation may impinge on the die attachment film through the handle wafer 701 to break down the adhesive properties of the film, enabling easy detachment. Alternatively, the adhesive layer 711 may be dissolved in a solvent. Once the adhesive layer 711 is deactivated, the handle wafer 701 is removed, leaving the device wafer 300W securely bonded to the semiconductor carrier wafer 924W via the continuous die attachment film 934W. To prepare the surface for subsequent processing, any residual adhesive layer may be eliminated through a cleaning process, such as solvent cleaning or plasma etching, ensuring a contaminant-free interface.

The wafer-level bonded assembly (300W, 934W, 924W) may be subsequently diced along dicing channels. The dicing channels extend along boundaries between neighboring pairs of TSV-containing semiconductor dies 300. Diced portions of the wafer-level bonded assembly (300W, 934W, 924W) comprise semiconductor assemblies (300, 934, 924). Each semiconductor assembly (300, 934, 924) comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310.

Referring to FIG. 2F, a plurality of semiconductor assemblies (300, 934, 924) provided through the processing steps described with reference to FIGS. 2A-2E may be attached to a carrier wafer 902 using a die attachment film 932. Gaps 380 may be present between adjacent semiconductor assemblies (300, 934, 924). It is to be understood that a region around a single semiconductor assembly (300, 934, 924) is illustrated in FIG. 2F and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 934, 924) may be attached to the die attachment film 932. Horizontal surfaces of the first backside metal interconnect structures 340 and the first backside dielectric material layers 330 may contact the die attachment film 932. In one embodiment, the two-dimensional array of semiconductor assemblies (300, 934, 924) may be arranged as a two-dimensional rectangular array of semiconductor assemblies (300, 934, 924). A gap 380 may be present between each neighboring pair of semiconductor assemblies (300, 934, 924).

Referring to FIG. 2G, a first molding compound matrix 397 may be formed around the two-dimensional array of TSV-containing semiconductor dies 300. The first molding compound matrix 397 may also fill the gaps 380 that occur between adjacent semiconductor dies 300 in the two-dimensional rectangular array of semiconductor assemblies (300, 934, 924). See e.g., FIG. 2F.

The first molding compound matrix 397 may comprise an epoxy molding compound (EMC). Typically, the EMC contains an epoxy resin, a hardener, silica fillers, and other additives to enhance its performance. A high filler content, such as 85% by weight, may be used to reduce mold shrinkage, minimize warpage, and improve flowability during the encapsulation process. The filler distribution suppresses flow marks during molding, thereby promoting a smooth application of the EMC. The EMC may be cured at a temperature ranging from 125° C. to 150° C., thereby preserving the integrity of the assembly during the molding process.

After curing, excess molding compound may be removed from above the front connection pads 378 by performing a planarization process. Specifically, portions of the cured EMC material that overlie the horizontal plane including topmost surfaces of the front connection pads 378 may be removed by performing a chemical mechanical polishing (CMP) process. A remaining portion of the cured EMC material constitutes the first molding compound matrix 397.

The first molding compound matrix 397 may embed a two-dimensional array of TSV-containing semiconductor dies 300, may have a top surface located within a horizontal plane including topmost surfaces of the front connection pads 378, and may comprise a planar bottom surface contacting the top surface of the die attachment film 932. The first molding compound matrix 397 provides mechanical support and environmental protection for the TSV-containing semiconductor dies 300. The first molding compound matrix 397 may contact sidewalls of the front connection pads 378 and a horizontal top surface of the first front capping dielectric layer 370.

Referring to FIG. 2H, a first bonding dielectric layer 460 having a first bonding-level metal interconnect structures 480 formed therein may be formed the top surface of the first molding compound matrix 397. The first bonding dielectric layer 460 comprises at least one interlayer dielectric (ILD) layer, which may include at least one via-level dielectric layer and/or at least one line-level dielectric layer. The first bonding dielectric layer 460 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The first bonding-level metal interconnect structures 480 may comprise metal via structures, metal line structures, metal pad structures, etc.

First bump structures 498 may be formed at the topmost level of the first bonding dielectric layer 460. Each of the first bump structures 498 may be formed on a respective one of the backside metal interconnect structures 340, which overlies the first molding compound matrix 397. In one embodiment, the first bump structures 498 may comprise via portions formed within, and laterally surrounded by, the first bonding dielectric layer 460. Further, the first bump structures 498 may comprise pillar structures or pad structures overlying the topmost surface of the first bonding dielectric layer 460. In one embodiment, the first bump structures 498 may comprise chip connection (C2) bonding structures such as microbump structures.

Referring to FIG. 2I, device semiconductor dies 100 may be attached to the first bump structures 498 using arrays of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having a respective set of connection metal pads 188 formed therein, and a respective bump-level dielectric layer 190 having a respective set of second bump structures 198 formed therein. The second bump structures 198 of the device semiconductor dies 100 may be bonded to the first bump structures 498 through the arrays of solder material portions 493.

An underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

Referring to FIG. 2J, a second molding compound matrix 497 may be formed around the device semiconductor dies 100 and the underfill material portion 495 and directly on the first bonding dielectric layer 460. The second molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing (CMP) process. A remaining portion of the cured EMC material constitutes the second molding compound matrix 497.

The second molding compound matrix 497 may embed a two-dimensional array of sets of device semiconductor dies 100, may have a top surface located within a horizontal plane including topmost surfaces of the device semiconductor dies 100, and may comprise a planar bottom surface contacting the top surface of the first bonding dielectric layer 460. The second molding compound matrix 497 provides mechanical support and environmental protection for the device semiconductor dies 100. Generally, the second molding compound matrix 497 is vertically spaced from the first molding compound matrix 397 by the first bonding dielectric layer 460, and does not contact the first molding compound matrix 397. The second molding compound matrix 497 may be formed around the device semiconductor dies 100 directly on the first bonding dielectric layer 460.

Referring to FIG. 2K, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation.

Referring to FIG. 2L, a chemical mechanical polishing process may be performed to polish the semiconductor carrier substrates 924, the die attachment films 934, and portions of the first molding compound matrix 397 that are more distal from the additional carrier wafer 903 than the horizontal plane including interfaces between the first backside metal interconnect structures 340 and the die attachment films 934. Distal horizontal surfaces of the first backside metal interconnect structures 340 and a backside horizontal surface of the first backside dielectric material layers 330 may be physically exposed. The distal horizontal surfaces of the first backside metal interconnect structures 340 and the backside horizontal surface of the first backside dielectric material layers 330 may be formed within the same horizontal plane as a polished horizontal surface of the first molding compound matrix 397.

Referring to FIG. 2M, a second bonding dielectric layer 560 having second bonding-level metal interconnect structures 580 formed therein may be formed on the front connection pads 378. The second bonding dielectric layer 560 may be formed directly on the first molding compound matrix 397. The second bonding dielectric layer 560 comprises at least one interlayer dielectric (ILD) layer, which may include at least one via-level dielectric layer and/or at least one line-level dielectric layer. The second bonding dielectric layer 560 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The second bonding-level metal interconnect structures 580 may comprise metal via structures, metal line structures, metal pad structures, etc.

Metal bump structures 598 may be formed at the topmost level of the second bonding dielectric layer 560. Each of the metal bump structures 598 may be formed on a respective one of the second bonding-level metal interconnect structures 580, which overlies and contacts the first molding compound matrix 397. In one embodiment, the metal bump structures 598 may comprise via portions formed within, and laterally surrounded by, the first bonding dielectric layer 460. Further, the metal bump structures 598 may comprise pad structures overlying the topmost surface of the second bonding dielectric layer 560. In one embodiment, the metal bump structures 598 may comprise controlled collapse chip connection (C4) pads. Each of the metal bump structures 598 may be formed directly on a respective one of the second bonding-level metal interconnect structures 580 and over the second bonding dielectric layer 560. Solder balls 593 may be attached to the metal bump structures 598.

Referring to FIG. 2N, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the second molding compound matrix 497.

A dicing process may be performed to dice (singulate) a reconstituted die including a two-dimensional array of TSV-containing semiconductor dies 300, the first molding compound matrix 397, the first bonding dielectric layer 460, a two-dimensional array of sets of device semiconductor dies 100, a two-dimensional array of underfill material portions 495, and the second molding compound matrix 497. Generally, the reconstituted die comprises at least the bonding dielectric layer 560, the first molding compound matrix 397, and the first bonding dielectric layer 460. Diced portions of the reconstituted die comprise composite dies 800. Each composite die 800 comprises a TSV-containing semiconductor die 300, a diced portion of the second bonding dielectric layer 560, a diced portion of the first molding compound matrix 397, a diced portion of the first bonding dielectric layer 460, and a diced portion of the second molding compound matrix 497.

The exemplary structure illustrated in FIG. 1N comprises a semiconductor package, which comprises: a through-substrate-via-containing (TSV-containing) semiconductor die 300 comprising a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310; a first molding compound matrix 397 laterally surrounding the TSV-containing semiconductor die 300; a first bonding dielectric layer 460 located on the front connection pads 378; and first bump structures 498 located on the first bonding dielectric layer 460.

In one embodiment, the first molding compound matrix 397 may be in contact with sidewalls of the front connection pads 378. In one embodiment, the TSV-containing semiconductor die 300 comprises first metal interconnect structures 360 formed within first dielectric material layers 350 and interposed between the first semiconductor substrate 310 and the front connection pads 378. In one embodiment, the TSV-containing semiconductor die 300 comprises a front capping dielectric layer 370 laterally surrounding via portions of the front connection pads 378 and having a horizontal surface in contact with the first molding compound matrix 397.

In one embodiment, sidewalls of the first bonding dielectric layer 460 are vertically coincident with outer sidewalls of the first molding compound matrix 397. In one embodiment, the semiconductor package comprises a second bonding dielectric layer 560 having bonding-level metal interconnect structures 580 formed therein and contacting the first backside metal interconnect structures 340. In one embodiment, the second bonding dielectric layer 560 is in contact with the first molding compound matrix 397. In one embodiment, sidewalls of the second bonding dielectric layer 560 are vertically coincident with outer sidewalls of the first molding compound matrix 397.

In one embodiment, the semiconductor package comprises device semiconductor dies 100 attached to the first bump structures 498 via arrays of solder material portions 493. In one embodiment, the semiconductor package comprises: an underfill material portion 495 laterally surrounding the arrays of solder material portions 493; and a second molding compound matrix 497 laterally surrounding the device semiconductor dies 100 and the underfill material portion 495. In one embodiment, sidewalls of the first bonding dielectric layer 460 are vertically coincident with outer sidewalls of the second molding compound matrix 497. In one embodiment, the second molding compound matrix 497 is vertically spaced from the first molding compound matrix 397 by the first bonding dielectric layer 460. In one embodiment, the first bonding dielectric layer 460 has first bonding-level metal interconnect structures 480 formed therein. The first bump structures 498 are in contact with a subset of the first bonding-level metal interconnect structures 480. In one embodiment, the first semiconductor devices 320 comprise first field effect transistors; and each of the device semiconductor dies 100 comprises a respective set of additional field effect transistors.

Referring to FIG. 2O, a second flow chart including a subset of processing steps for forming a semiconductor structure is provided.

Referring to step 1210 and FIGS. 2A-2E, a semiconductor assembly (300, 934, 924) is provided, which comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310.

Referring to step 1220 and FIG. 2F, the semiconductor carrier substrate 924 of the semiconductor assembly (300, 934, 924) may be attached to a carrier wafer 902 using a die attachment film 932.

Referring to step 1230 and FIGS. 2G-2N, a first molding compound matrix 397 may be formed around the semiconductor assembly (300, 934, 924).

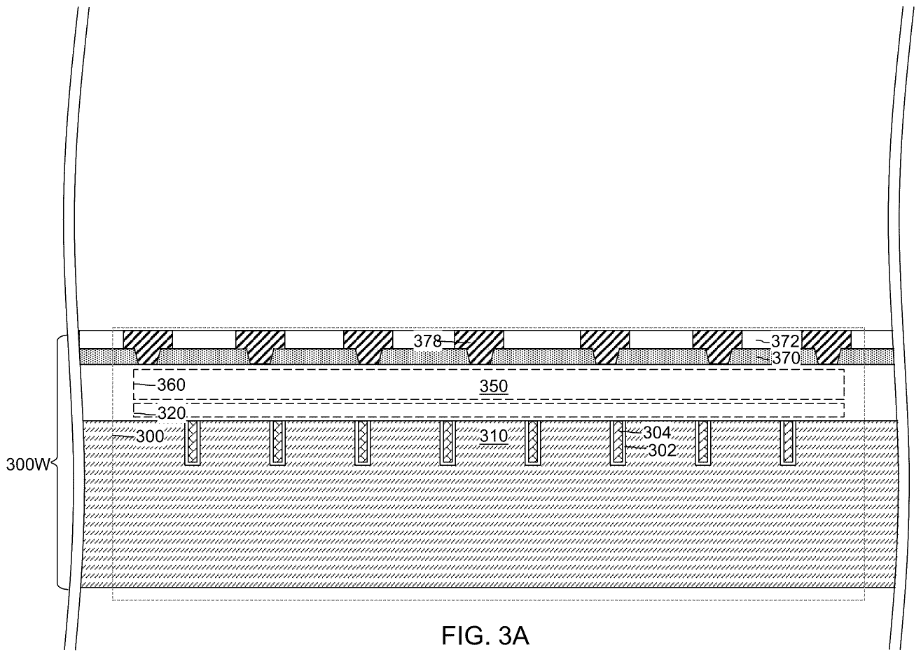

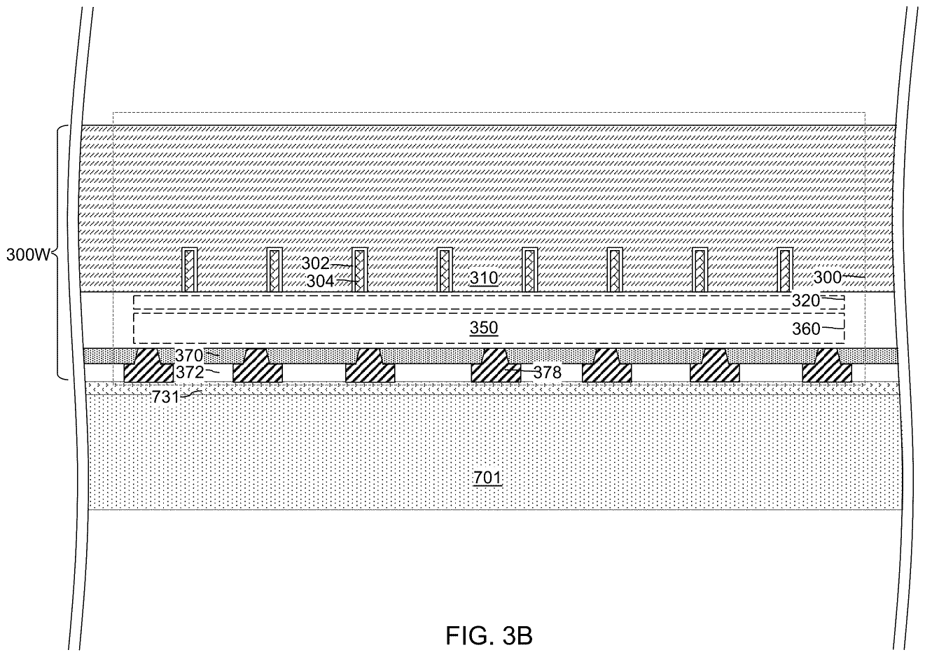

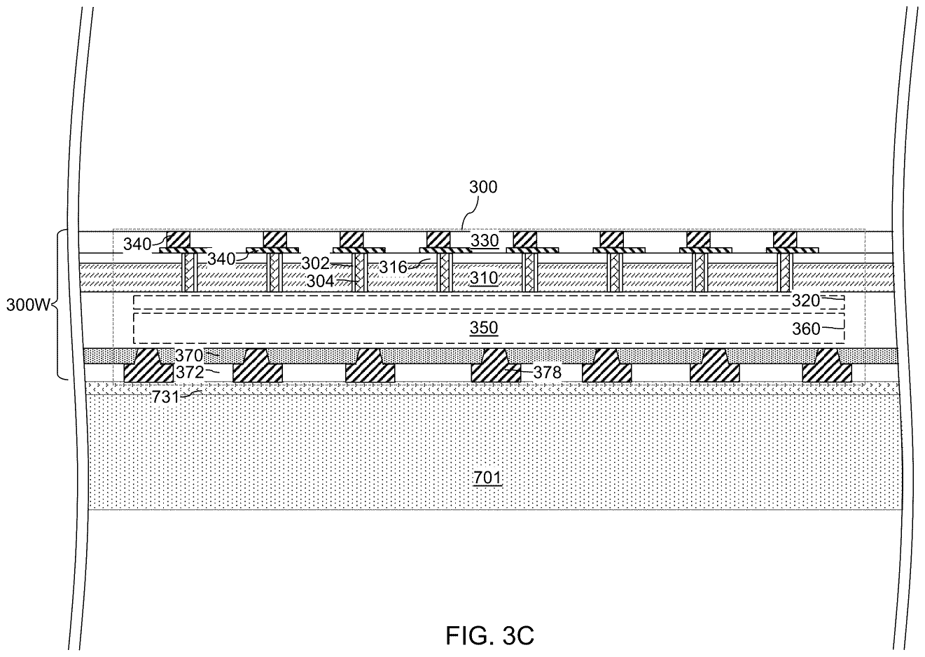

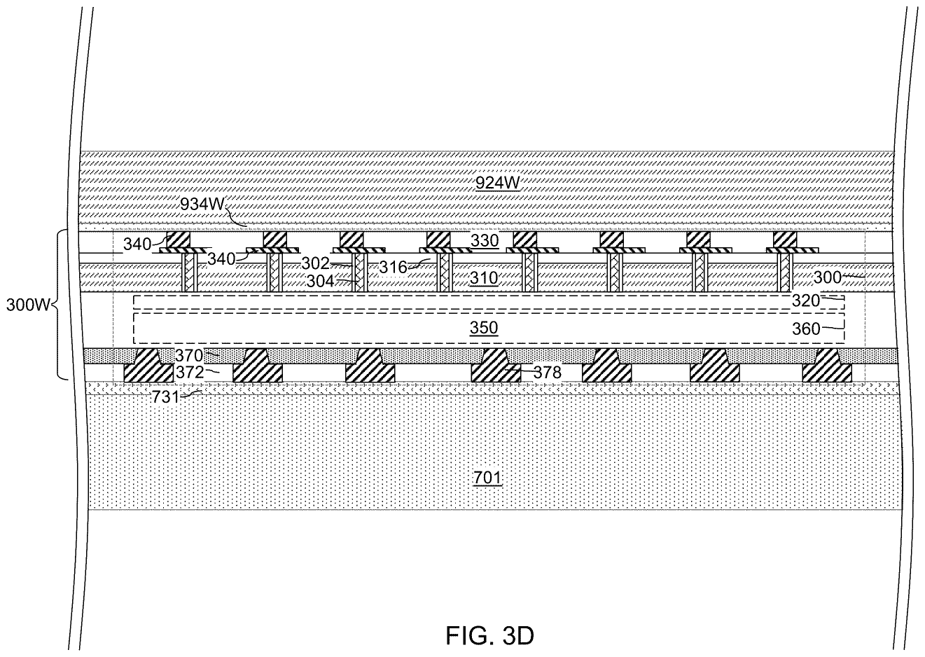

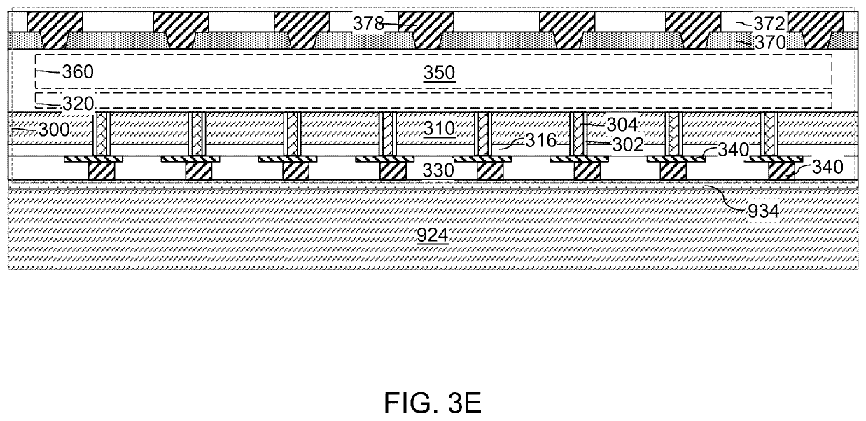

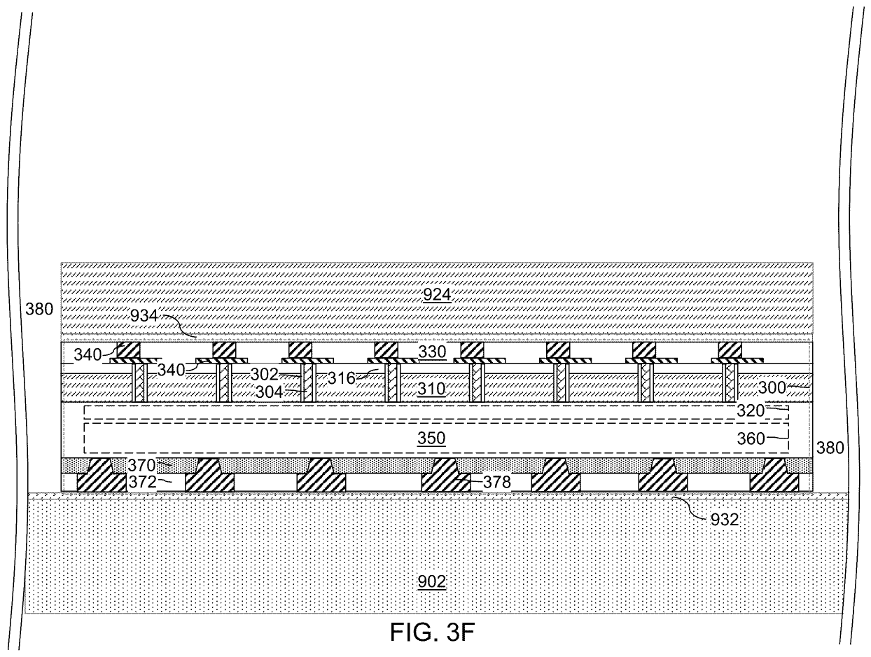

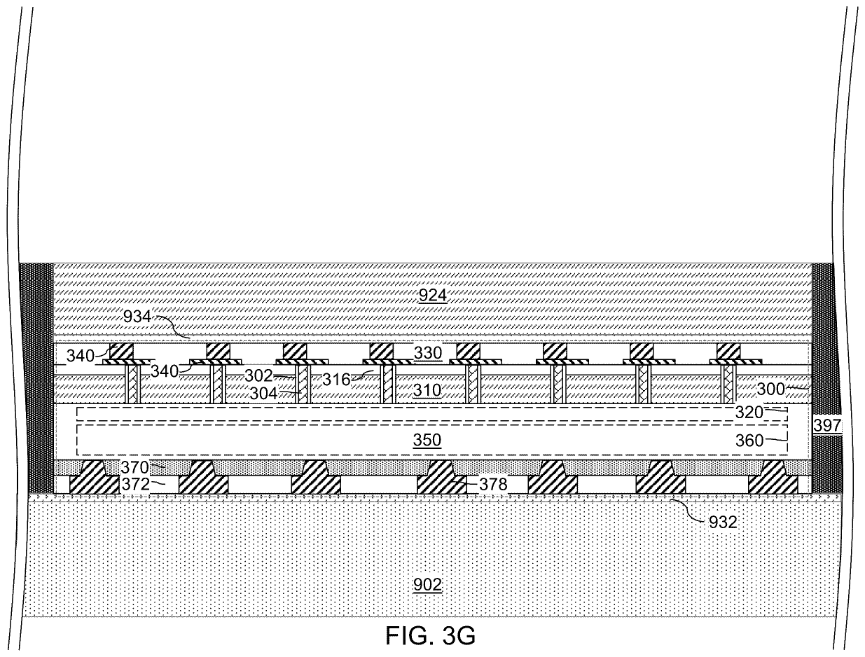

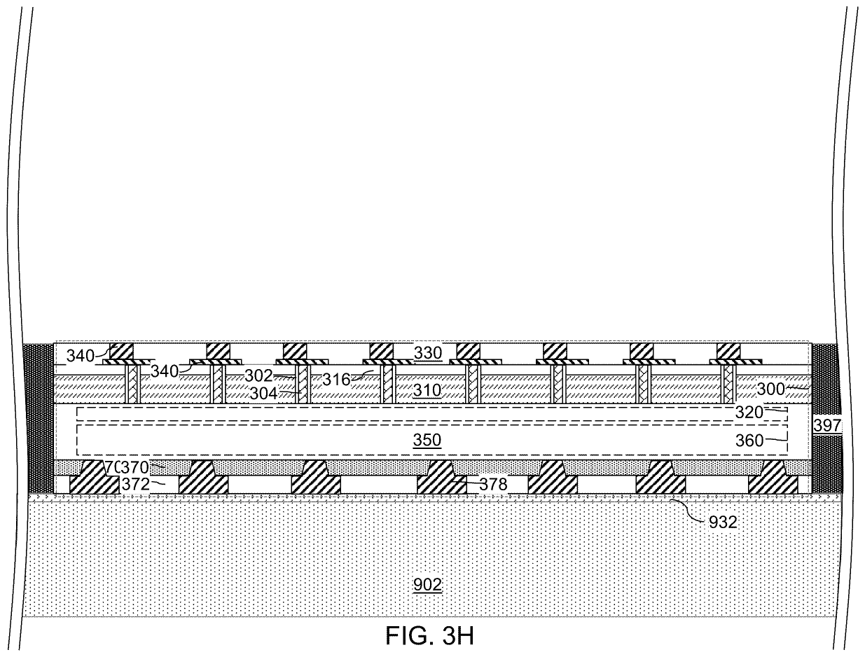

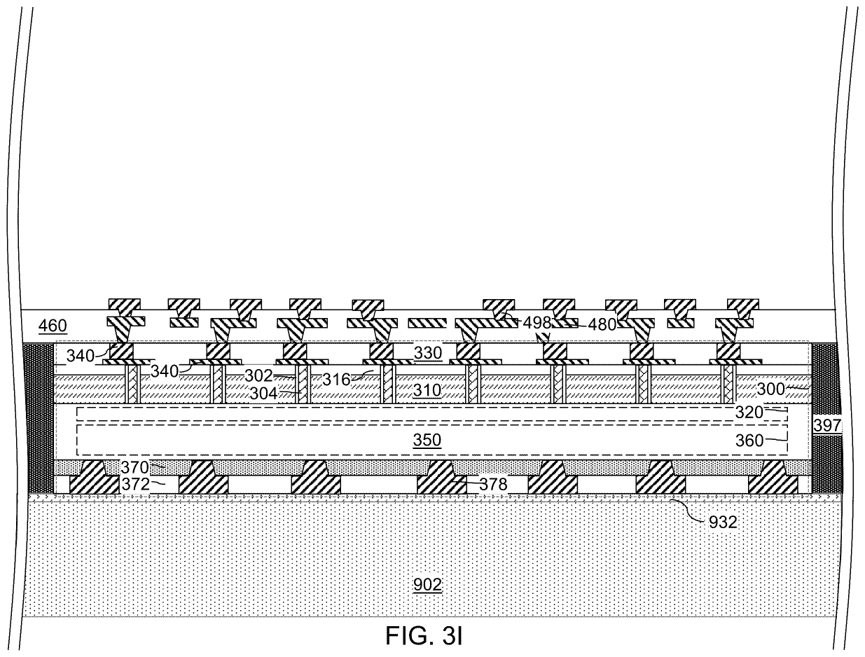

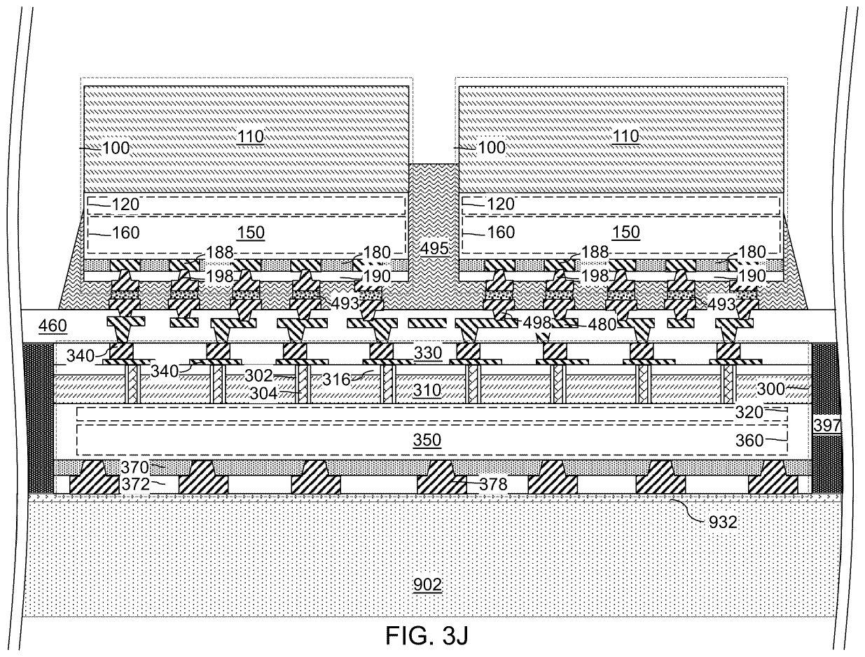

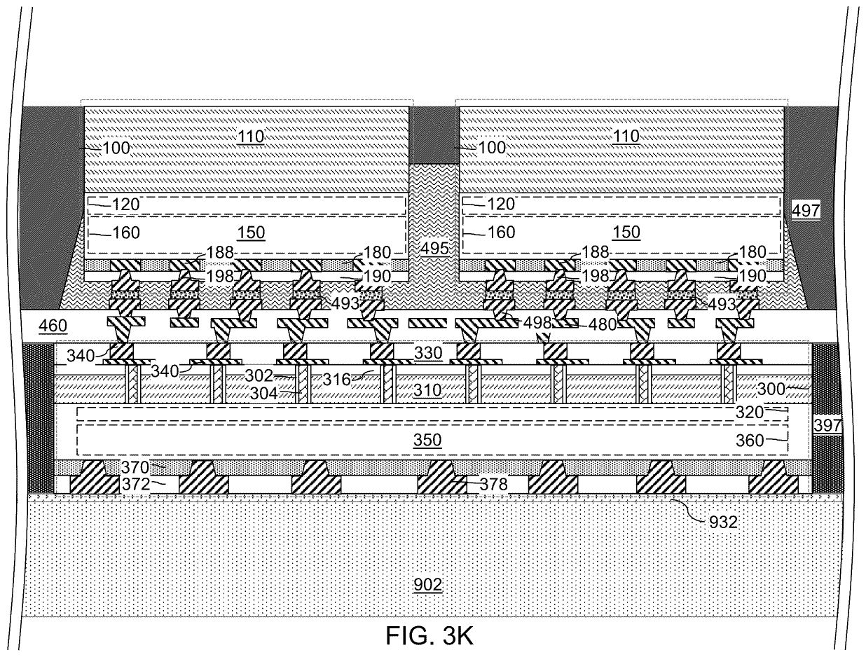

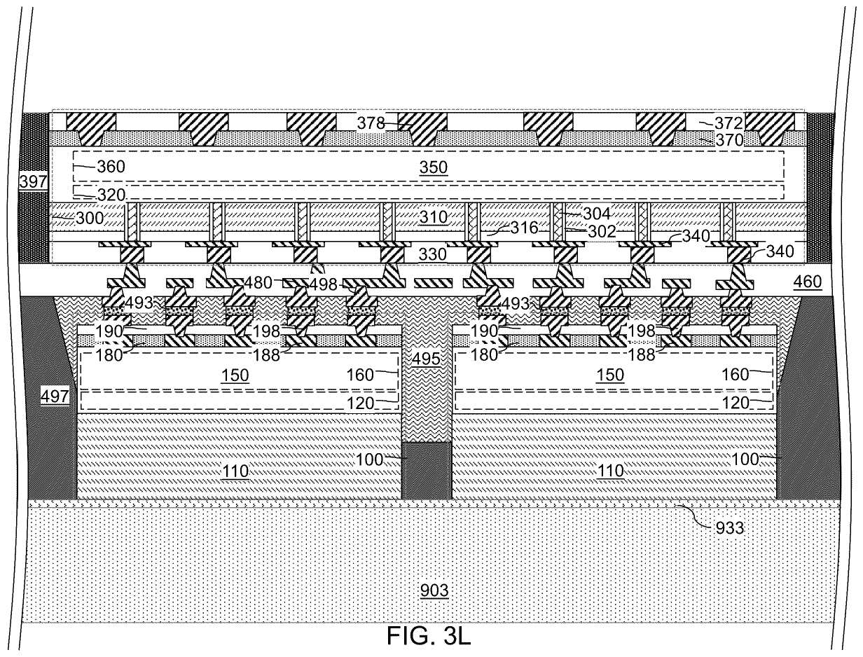

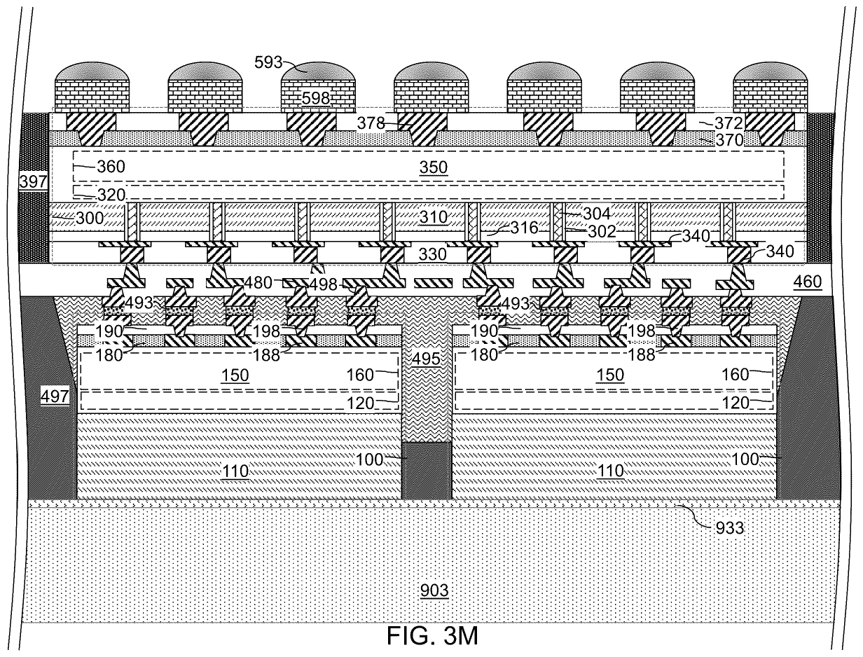

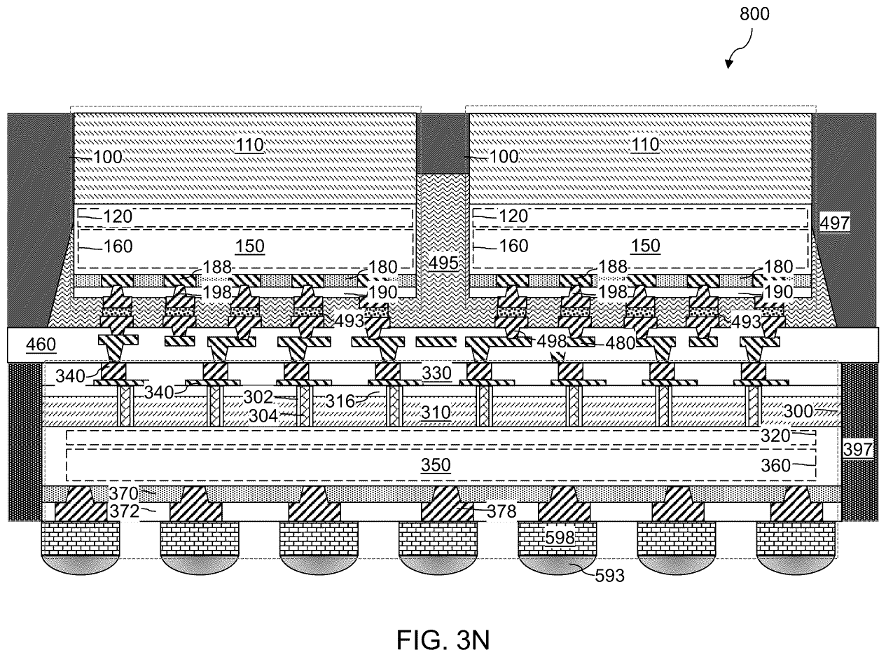

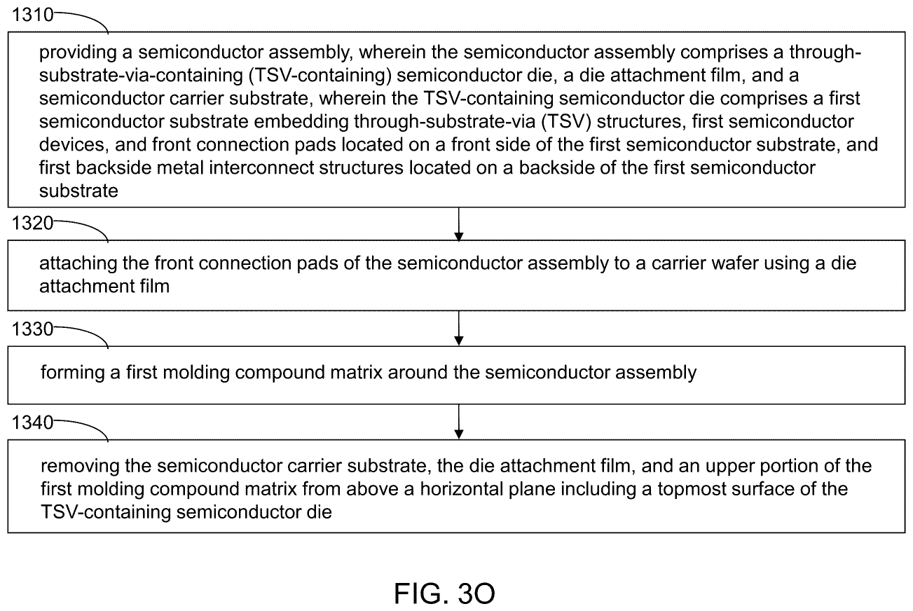

FIGS. 3A-3N are sequential vertical cross-sectional views of a third embodiment structure during a sequence of processing steps according to an embodiment of the present disclosure.

Referring to FIG. 3A, a device wafer 300W is illustrated, which includes a first semiconductor substrate 310 and structural elements formed therein and thereupon. The device wafer 300W may be the same as the device wafer 300W illustrated in FIG. 1A.

Referring to FIG. 3B, the device wafer 300W may be attached to a handle wafer 701, for example, using a die attachment film 731. The handle wafer 701 may be any wafer that may be used to provide mechanical support during subsequent handling of the device wafer 300W. In one embodiment, the handle wafer 701 may comprise a glass carrier wafer having a same lateral dimension as the device wafer 300W.

Referring to FIG. 3C, the device wafer 300W may be thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing process. The remaining portion of the insulating material constitutes a backside insulating layer 316. Physically exposed backside surfaces of the TSV structures 304 may be coplanar with a physically exposed horizontal surface of the backside insulating layer 316.

At least one metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Referring to FIG. 3D, a semiconductor carrier wafer 924W may be attached to the device wafer 300W using a continuous die attachment film 934W. For example, the continuous die attachment film 934W may comprise a thermally decomposable adhesive material. The continuous die attachment film 934W provides adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 934W, 924W) of the device wafer 300W, the continuous die attachment film 934W, and the semiconductor carrier wafer 924W is formed.

Referring to FIG. 3E, the die attachment film 731 may be deactivated to facilitate the detachment of the handle wafer 701 from the wafer-level bonded assembly (300W, 934W, 924W). For instance, the die attachment film 731 may comprise an ultraviolet-decomposable material, and the handle wafer 701 may comprise a transparent wafer such as a glass substrate. In this embodiment, ultraviolet radiation may impinge on the die attachment film through the handle wafer 701 to break down the adhesive properties of the film, enabling easy detachment. Once the die attachment film 731 is deactivated, the handle wafer 701 is removed, leaving the device wafer 300W securely bonded to the semiconductor carrier wafer 924W via the continuous die attachment film 934W. To prepare the surface for subsequent processing, any residual adhesive layer may be eliminated through a cleaning process, such as solvent cleaning or plasma etching, ensuring a contaminant-free interface.

The wafer-level bonded assembly (300W, 934W, 924W) may be subsequently diced along dicing channels. The dicing channels extend along boundaries between neighboring pairs of TSV-containing semiconductor dies 300. Diced portions of the wafer-level bonded assembly (300W, 934W, 924W) comprise semiconductor assemblies (300, 934, 924). Each semiconductor assembly (300, 934, 924) comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310.

Referring to FIG. 3F, a plurality of semiconductor assemblies (300, 934, 924) provided through the processing steps described with reference to FIGS. 3A-3E may be attached to a carrier wafer 902 using a die attachment film 932. It is to be understood that a region around a single semiconductor assembly (300, 934, 924) is illustrated in FIG. 3F and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 934, 924) may be attached to the die attachment film 932. Horizontal surfaces of the front connection pads 378 and the second front capping dielectric layer 372 may contact the die attachment film 932. In one embodiment, the two-dimensional array of semiconductor assemblies (300, 934, 924) may be arranged as a two-dimensional rectangular array of semiconductor assemblies (300, 934, 924). A gap 380 may be present between each neighboring pair of semiconductor assemblies (300, 934, 924).

Referring to FIG. 3G, a first molding compound matrix 397 may be formed around the two-dimensional array of TSV-containing semiconductor dies 300. The first molding compound matrix 397 may also fill the gaps 380 that occur between adjacent semiconductor dies 300 in the two-dimensional rectangular array of semiconductor assemblies (300, 934, 924). See e.g., FIG. 3F. The first molding compound matrix 397 may comprise an epoxy molding compound (EMC). Typically, the EMC contains an epoxy resin, a hardener, silica fillers, and other additives to enhance its performance. A high filler content, such as 85% by weight, may be used to reduce mold shrinkage, minimize warpage, and improve flowability during the encapsulation process. The filler distribution suppresses flow marks during molding, thereby promoting a smooth application of the EMC. The EMC may be cured at a temperature ranging from 125° C. to 150° C., thereby preserving the integrity of the assembly during the molding process.

After curing, excess molding compound may be removed from above the semiconductor carrier substrates 924 by performing a planarization process (e.g., CMP process). Specifically, portions of the cured EMC material that overlie the horizontal plane including the backside surfaces of the semiconductor carrier substrates 924 may be removed by performing a chemical mechanical polishing process. A remaining portion of the cured EMC material constitutes the first molding compound matrix 397.

The first molding compound matrix 397 may embed a two-dimensional array of TSV-containing semiconductor dies 300, may have a top surface located within a horizontal plane including the backside surfaces of the semiconductor carrier substrates 924, and may comprise a planar bottom surface contacting the top surface of the die attachment film 932. The first molding compound matrix 397 provides mechanical support and environmental protection for the TSV-containing semiconductor dies 300. The first molding compound matrix 397 may contact sidewalls of each TSV-containing semiconductor die 300, each die attachment film 934, and each semiconductor carrier substrate 924.

Referring to FIG. 3H, a chemical mechanical polishing (CMP) process may be performed to polish the semiconductor carrier substrates 924, the die attachment films 934, and portions of the first molding compound matrix 397 that are more distal from the carrier wafer 902 than the horizontal plane including interfaces between the first backside metal interconnect structures 340 and the die attachment films 934. Distal horizontal surfaces of the first backside metal interconnect structures 340 and a backside horizontal surface of the first backside dielectric material layers 330 may be physically exposed. The distal horizontal surfaces of the first backside metal interconnect structures 340 and the backside horizontal surface of the first backside dielectric material layers 330 may be formed within the same horizontal plane as a polished horizontal surface of the first molding compound matrix 397.

Referring to FIG. 3I, a first bonding dielectric layer 460 having first bonding-level metal interconnect structures 480 formed therein may be formed on the top surface of the first molding compound matrix 397. The first bonding dielectric layer 460 comprises at least one interlayer dielectric (ILD) layer, which may include at least one via-level dielectric layer and/or at least one line-level dielectric layer. The first bonding dielectric layer 460 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The first bonding-level metal interconnect structures 480 may comprise metal via structures, metal line structures, metal pad structures, etc.

First bump structures 498 may be formed at the topmost level of the first bonding dielectric layer 460. Each of the first bump structures 498 may be formed on a respective one of the backside metal interconnect structures 340, which overlies the first molding compound matrix 397. In one embodiment, the first bump structures 498 may comprise via portions formed within, and laterally surrounded by, the first bonding dielectric layer 460. Further, the first bump structures 498 may comprise pillar structures or pad structures overlying the topmost surface of the first bonding dielectric layer 460. In one embodiment, the first bump structures 498 may comprise chip connection (C2) bonding structures such as microbump structures.

Referring to FIG. 3J, device semiconductor dies 100 may be attached to the first bump structures 498 using arrays of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having a respective set of connection metal pads 188 formed therein, and a respective bump-level dielectric layer 190 having a respective set of second bump structures 198 formed therein. The second bump structures 198 of the device semiconductor dies 100 may be bonded to the first bump structures 498 through the arrays of solder material portions 493.

An underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

Referring to FIG. 3K, a second molding compound matrix 497 may be formed around the device semiconductor dies 100 and the underfill material portion 495 and directly on the first bonding dielectric layer 460. The second molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing process. A remaining portion of the cured EMC material constitutes the second molding compound matrix 497.

The second molding compound matrix 497 may embed a two-dimensional array of sets of device semiconductor dies 100, may have a top surface located within a horizontal plane including topmost surfaces of the device semiconductor dies 100, and may comprise a planar bottom surface contacting the top surface of the first bonding dielectric layer 460. The second molding compound matrix 497 provides mechanical support and environmental protection for the device semiconductor dies 100. Generally, the second molding compound matrix 497 is vertically spaced from the first molding compound matrix 397 by the first bonding dielectric layer 460, and does not contact the first molding compound matrix 397. The second molding compound matrix 497 may be formed around the device semiconductor dies 100 directly on the first bonding dielectric layer 460.

Referring to FIG. 3L, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation.

Referring to FIG. 3M, metal bump structures 598 may be formed on the second front capping dielectric layer 372. Each of the metal bump structures 598 may be formed on a respective one of the front connection pads 378. In one embodiment, the metal bump structures 598 may comprise pad structures contacting a planar surface of the second front capping dielectric layer 372. In one embodiment, the metal bump structures 598 may comprise controlled collapse chip connection (C4) pads. Each of the metal bump structures 598 may be formed directly on a respective one of the front connection pads 378 and over the second front capping dielectric layer 372. Solder balls 593 may be attached to the metal bump structures 598.

Referring to FIG. 3N, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the second molding compound matrix 497.

A dicing process may be performed to dice (singulate) a reconstituted die including a two-dimensional array of TSV-containing semiconductor dies 300, the first molding compound matrix 397, the first bonding dielectric layer 460, a two-dimensional array of sets of device semiconductor dies 100, a two-dimensional array of underfill material portions 495, and the second molding compound matrix 497. Generally, the reconstituted die comprises at least the bonding dielectric layer 560, the first molding compound matrix 397, and the first bonding dielectric layer 460. Diced portions of the reconstituted die comprise composite dies 800. Each composite die 800 comprises a TSV-containing semiconductor die 300, a diced portion of the first bonding dielectric layer 460, a diced portion of the first molding compound matrix 397, and a diced portion of the second molding compound matrix 497.

The exemplary structure illustrated in FIG. 3N comprises a semiconductor package, which comprises: a through-substrate-via-containing (TSV-containing) semiconductor die 300 comprising a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310; a first molding compound matrix 397 laterally surrounding the TSV-containing semiconductor die 300; a first bonding dielectric layer 460 located on the first backside metal interconnect structures 340; and first bump structures 498 located on the first bonding dielectric layer 460.

In one embodiment, the first molding compound matrix 397 is in contact with a frame-shaped horizontal surface of the first bonding dielectric layer 460. In one embodiment, the TSV-containing semiconductor die 300 comprises first backside dielectric material layers 330 having the first backside metal interconnect structures 340 formed therein and comprising sidewalls that contact inner sidewalls of the first molding compound matrix 397. In one embodiment, the TSV-containing semiconductor die 300 comprises first backside metal interconnect structures 340 formed within first backside dielectric material layers 330. In one embodiment, all outer sidewalls of the first backside dielectric material layers 330 and all outer sidewalls of the at least one front capping dielectric layer (370, 372) are in contact within inner sidewalls of the first molding compound matrix 397.

In one embodiment, sidewalls of the first bonding dielectric layer 460 are vertically coincident with outer sidewalls of the first molding compound matrix 397. In one embodiment, the semiconductor package comprises metal bump structures 598 contacting a respective one of the front connection pads 378. Sidewalls of the first bonding dielectric layer 460 are vertically coincident with outer sidewalls of the first molding compound matrix 397.

In one embodiment, the semiconductor package comprises device semiconductor dies 100 attached to the first bump structures 498 via arrays of solder material portions 493. In one embodiment, the semiconductor package comprises: an underfill material portion 495 laterally surrounding the arrays of solder material portions 493; and a second molding compound matrix 497 laterally surrounding the device semiconductor dies 100 and the underfill material portion 495. In one embodiment, the second molding compound matrix 497 is vertically spaced from the first molding compound matrix 397 by the first bonding dielectric layer 460. Sidewalls of the first bonding dielectric layer 460 are vertically coincident with outer sidewalls of the second molding compound matrix 497.

In one embodiment, the first bonding dielectric layer 460 may have first bonding-level metal interconnect structures 480 formed therein, wherein the first bump structures 498 are in contact with a subset of the first bonding-level metal interconnect structures 480. In one embodiment, the first semiconductor devices 320 comprise first field effect transistors; and each of the device semiconductor dies 100 comprises a respective set of additional field effect transistors.

Referring to FIG. 3O, a third flow chart including a subset of processing steps for forming a semiconductor structure is illustrated.

Referring to step 1310 and FIGS. 3A-3E, a semiconductor assembly (300, 934, 924) is provided. The semiconductor assembly (300, 934, 924) comprises a through-substrate-via-containing (TSV-containing) semiconductor die 300, a die attachment film 934, and a semiconductor carrier substrate 924, wherein the TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310.

Referring to step 1320 and FIG. 3F, the front connection pads 378 of the semiconductor assembly (300, 934, 924) may be attached to a carrier wafer 902 using a die attachment film 932.

Referring to step 1330 and FIGS. 3G-3N, the semiconductor carrier substrate 924 and the die attachment film 934 may be removed.

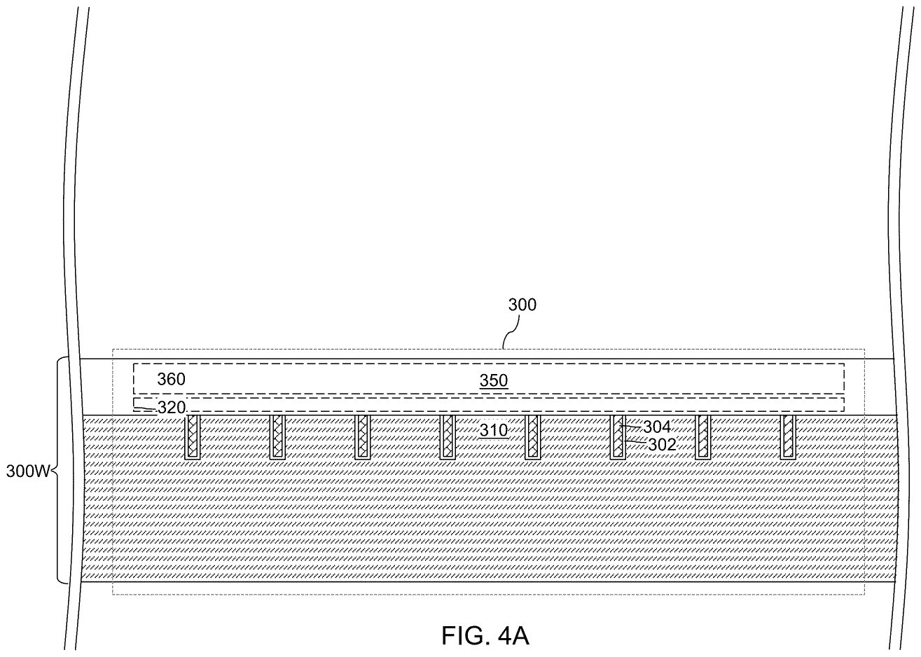

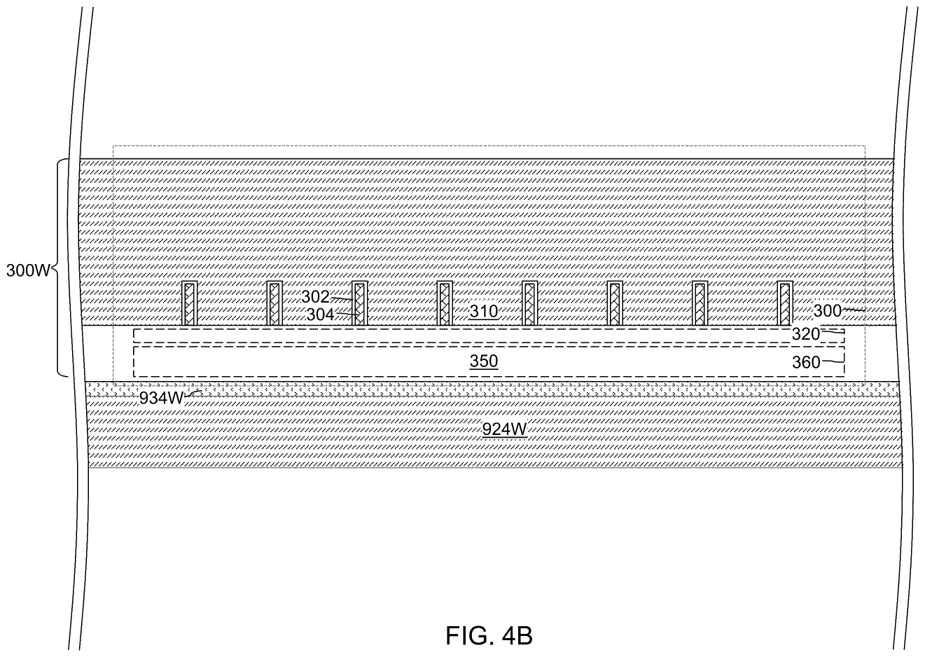

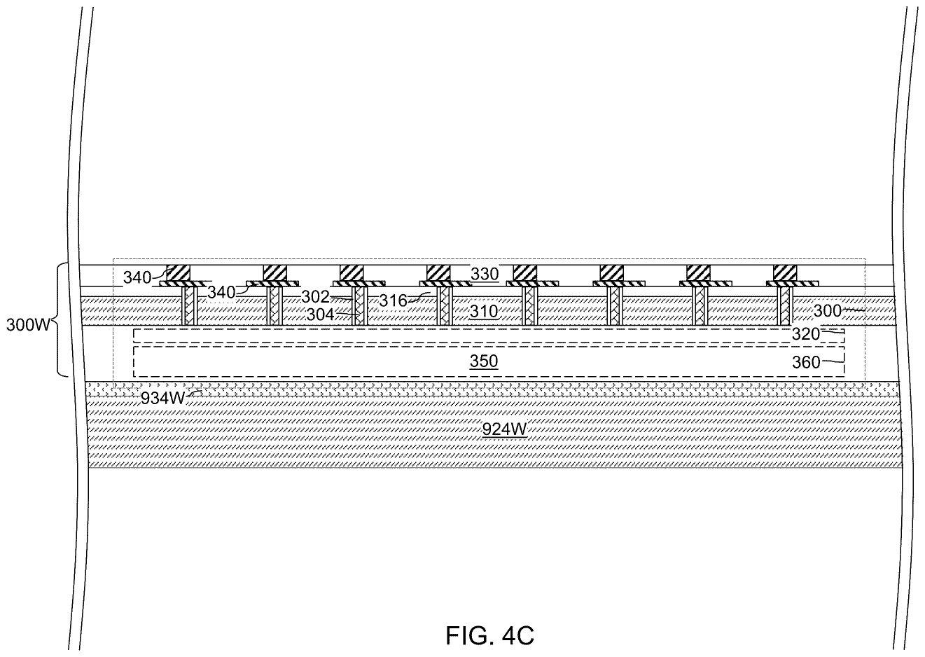

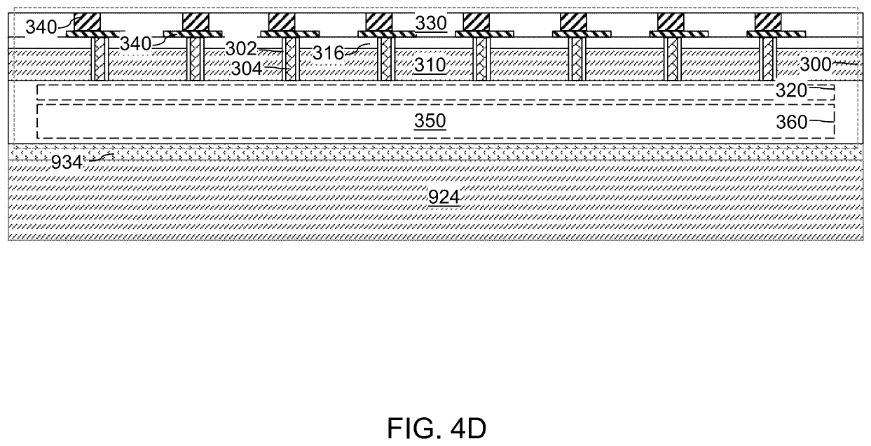

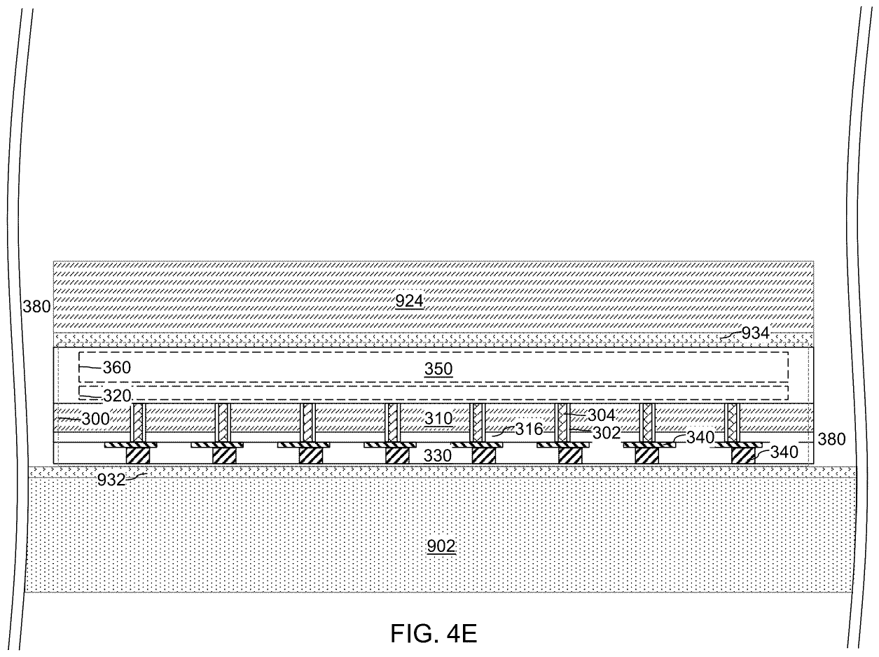

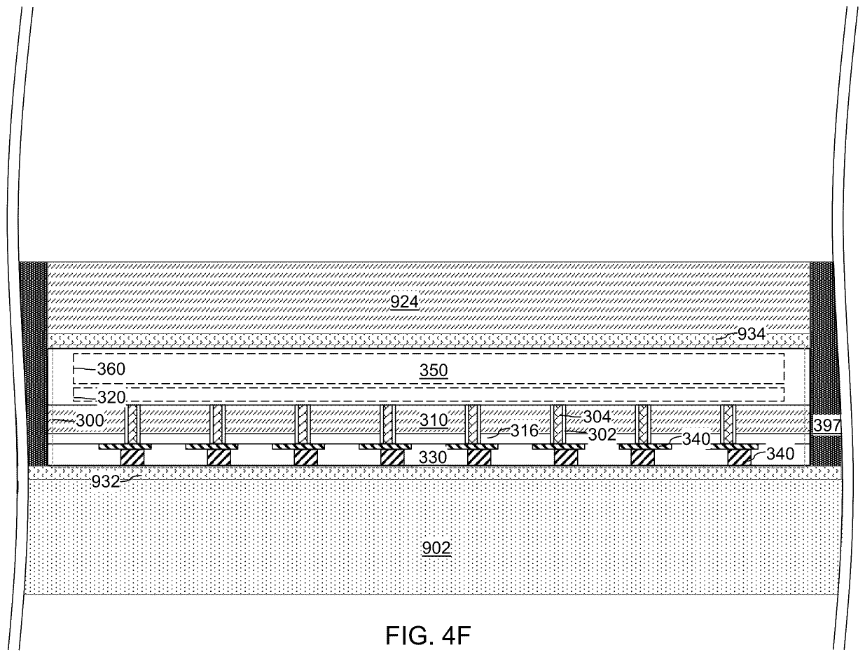

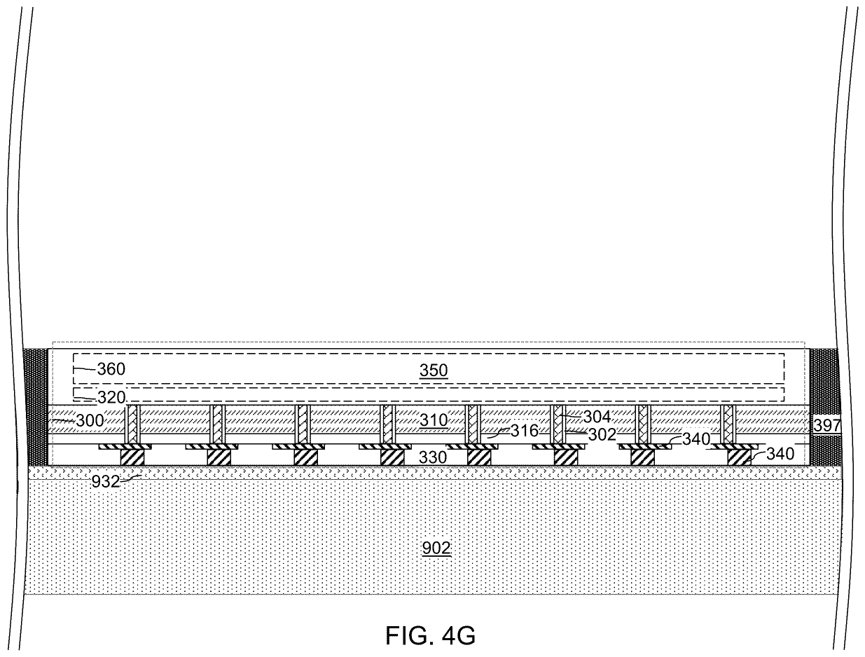

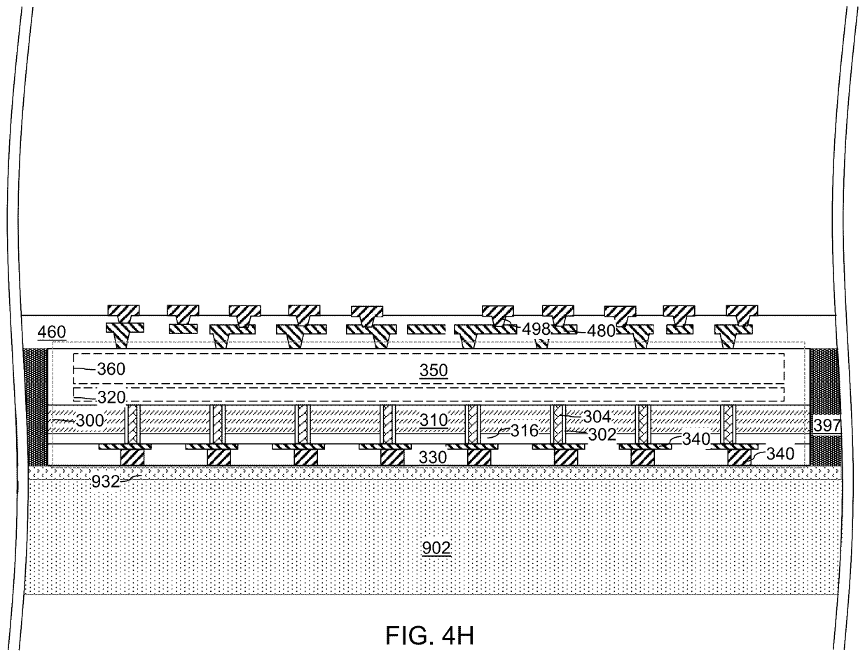

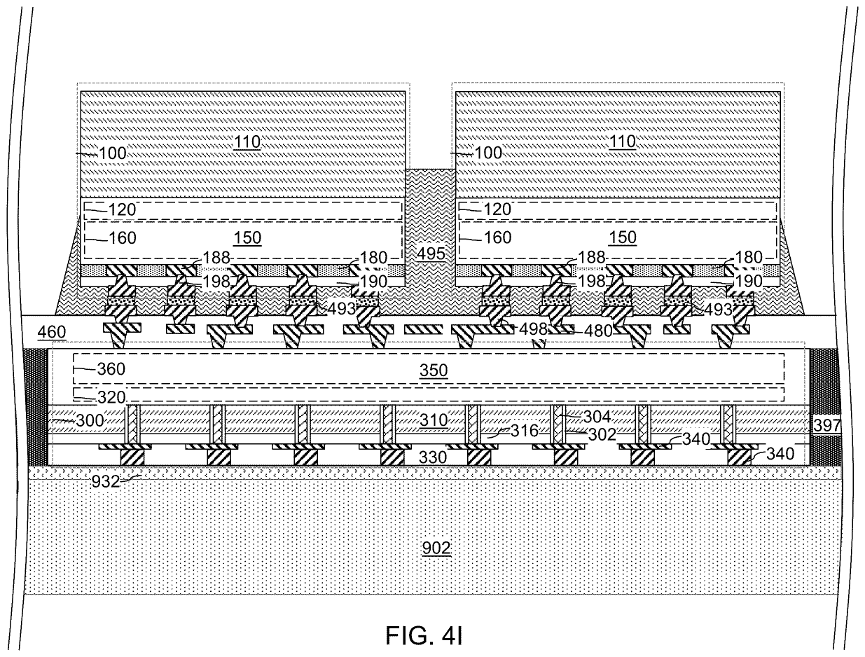

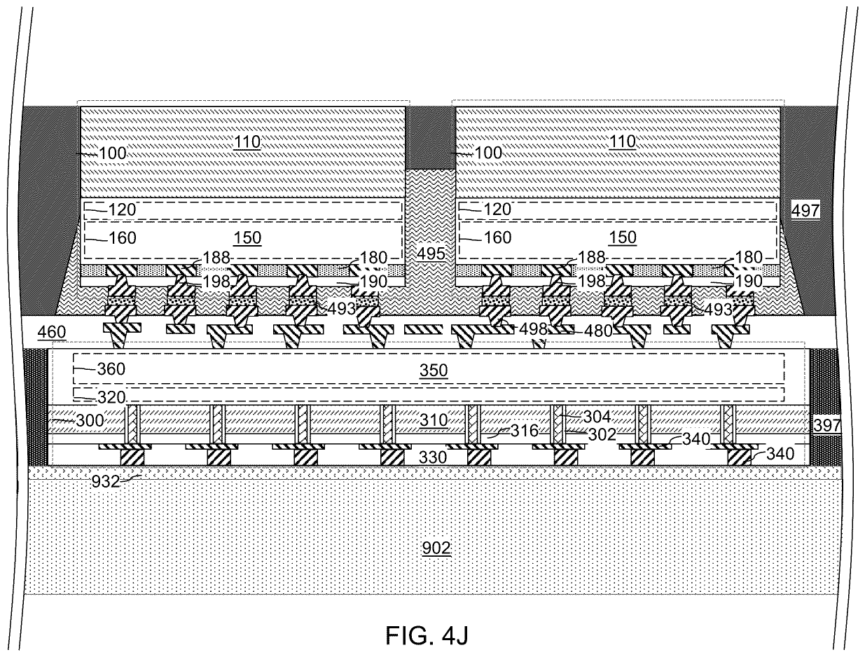

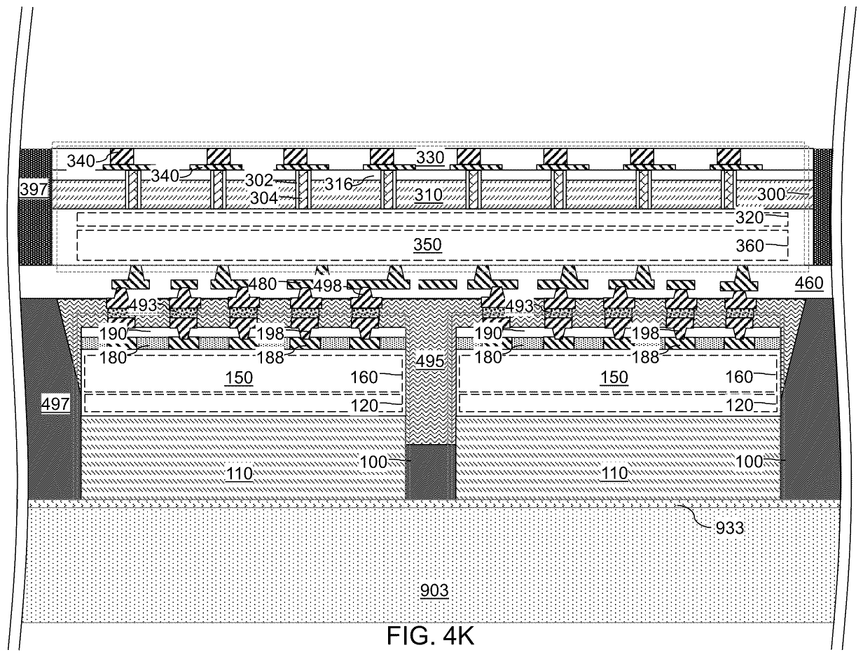

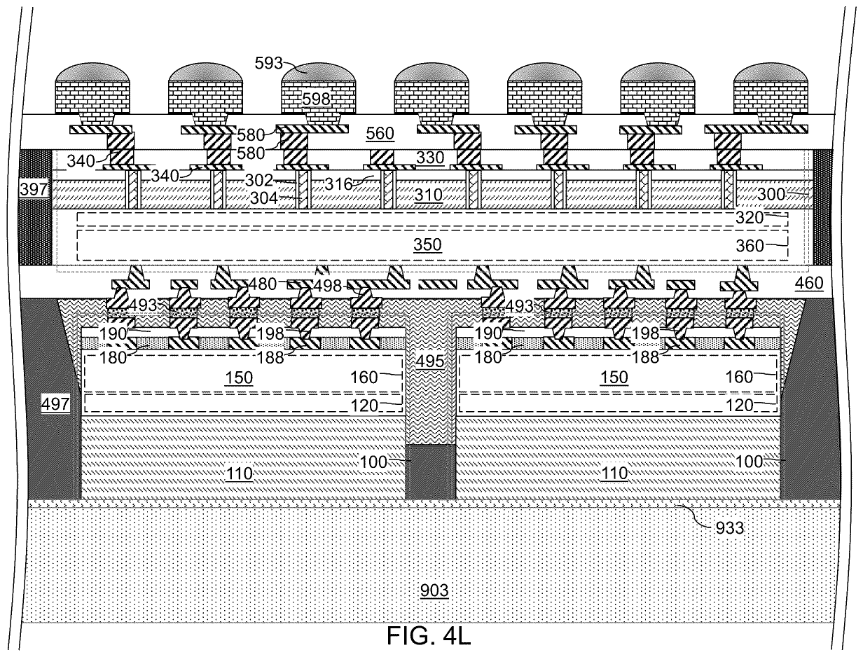

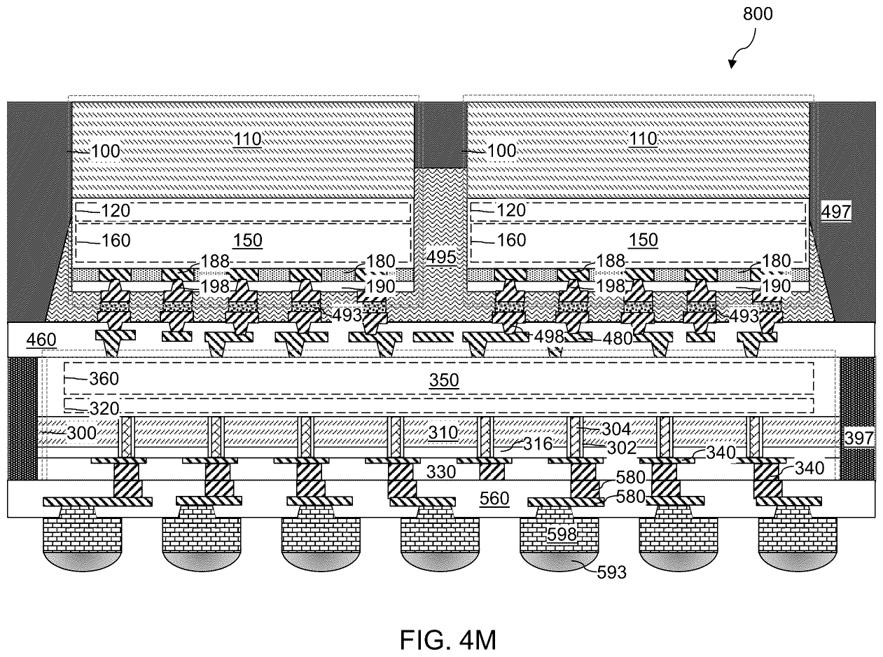

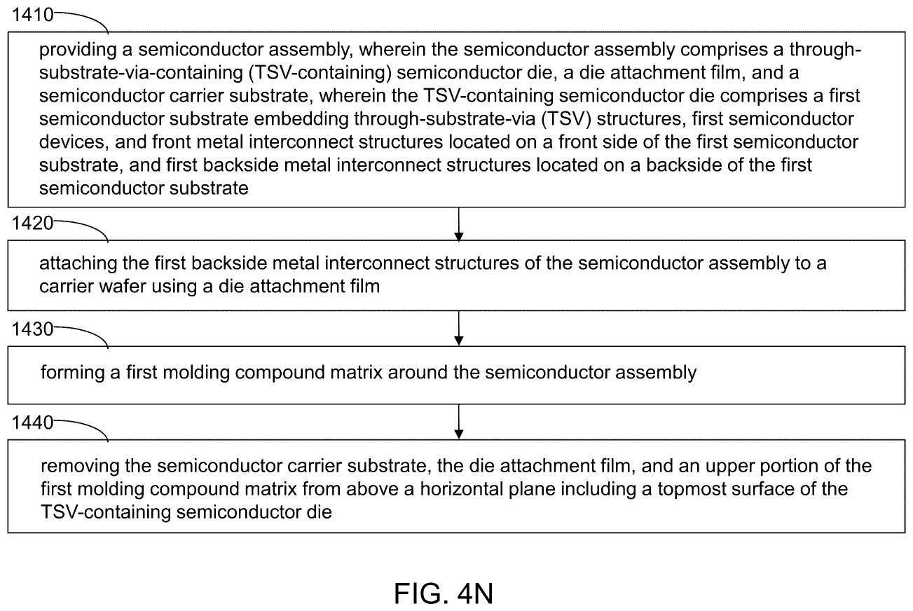

FIGS. 4A-4M are sequential vertical cross-sectional views of a fourth embodiment structure during a sequence of processing steps according to an embodiment of the present disclosure.

Referring to FIG. 4A, a device wafer 300W is illustrated, which includes a first semiconductor substrate 310 and structural elements formed therein and thereupon. The device wafer 300W may be derived from the device wafer 300W illustrated in FIG. 1A by omitting formation of the at least one front capping dielectric layer (370, 372) and the front connection pads 378. Thus, a topmost surface of the first dielectric material layers 350 and topmost surfaces of the first metal interconnect structures 360 may be physically exposed.

Referring to FIG. 4B, a semiconductor carrier wafer 924W may be attached to the device wafer 300W using a continuous die attachment film 934W. For example, the continuous die attachment film 934W may comprise a thermally decomposable adhesive material. The continuous die attachment film 934W provides adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 934W, 924W) of the device wafer 300W, the continuous die attachment film 934W, and the semiconductor carrier wafer 924W is formed.

Referring to FIG. 4C, the device wafer 300W may be thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing (CMP) process. The remaining portion of the insulating material constitutes a backside insulating layer 316. Physically exposed backside surfaces of the TSV structures 304 may be coplanar with a physically exposed horizontal surface of the backside insulating layer 316.

At least one metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Referring to FIG. 4D, the wafer-level bonded assembly (300W, 934W, 924W) may be subsequently diced along dicing channels. The dicing channels extend along boundaries between neighboring pairs of TSV-containing semiconductor dies 300. Diced portions of the wafer-level bonded assembly (300W, 934W, 924W) comprise semiconductor assemblies (300, 934, 924). Each semiconductor assembly (300, 934, 924) comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and first backside metal interconnect structures 340 located on a backside of the first semiconductor substrate 310.

Referring to FIG. 4E, a plurality of semiconductor assemblies (300, 934, 924) provided through the processing steps described with reference to FIGS. 3A-3E may be attached to a carrier wafer 902 using a die attachment film 932. It is to be understood that a region around a single semiconductor assembly (300, 934, 924) is illustrated in FIG. 4D and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 934, 924) may be attached to the die attachment film 932. Horizontal surfaces of the first backside metal interconnect structures 340 and the first backside dielectric material layers 330 may contact the die attachment film 932. In one embodiment, the two-dimensional array of semiconductor assemblies (300, 934, 924) may be arranged as a two-dimensional rectangular array of semiconductor assemblies (300, 934, 924). A gap 380 may be present between each neighboring pair of semiconductor assemblies (300, 934, 924).

Referring to FIG. 4F, a first molding compound matrix 397 may be formed around the two-dimensional array of TSV-containing semiconductor dies 300. The first molding compound matrix 397 may also fill the gaps 380 that occur between adjacent semiconductor dies 300 in the two-dimensional rectangular array of semiconductor assemblies (300, 934, 924). See e.g., FIG. 4E. The first molding compound matrix 397 may comprise an epoxy molding compound (EMC). Typically, the EMC contains an epoxy resin, a hardener, silica fillers, and other additives to enhance its performance. A high filler content, such as 85% by weight, may be used to reduce mold shrinkage, minimize warpage, and improve flowability during the encapsulation process. The filler distribution suppresses flow marks during molding, thereby promoting a smooth application of the EMC. The EMC may be cured at a temperature ranging from 125° C. to 150° C., thereby preserving the integrity of the assembly during the molding process.

After curing, excess molding compound may be removed from above the semiconductor carrier substrates 924 by performing a planarization process (e.g., CMP process). Specifically, portions of the cured EMC material that overlie the horizontal plane including the backside surfaces of the semiconductor carrier substrates 924 may be removed by performing a chemical mechanical polishing process. A remaining portion of the cured EMC material constitutes the first molding compound matrix 397.

The first molding compound matrix 397 may embed a two-dimensional array of TSV-containing semiconductor dies 300, may have a top surface located within a horizontal plane including the backside surfaces of the semiconductor carrier substrates 924, and may comprise a planar bottom surface contacting the top surface of the die attachment film 932. The first molding compound matrix 397 provides mechanical support and environmental protection for the TSV-containing semiconductor dies 300. The first molding compound matrix 397 may contact sidewalls of each TSV-containing semiconductor die 300, each die attachment film 934, and each semiconductor carrier substrate 924.

Referring to FIG. 4G, a chemical mechanical polishing (CMP) process may be performed to polish the semiconductor carrier substrates 924, the die attachment films 934, and portions of the first molding compound matrix 397 that are more distal from the carrier wafer 902 than the horizontal plane including interfaces between the first backside metal interconnect structures 340 and the die attachment films 934. Distal horizontal surfaces of the first backside metal interconnect structures 340 and a backside horizontal surface of the first backside dielectric material layers 330 may be physically exposed. The distal horizontal surfaces of the first backside metal interconnect structures 340 and the backside horizontal surface of the first backside dielectric material layers 330 may be formed within the same horizontal plane as a polished horizontal surface of the first molding compound matrix 397.

Referring to FIG. 4H, a first bonding dielectric layer 460 having first bonding-level metal interconnect structures 480 formed therein may be formed on the top surface of the first molding compound matrix 397. The first bonding dielectric layer 460 comprises at least one interlayer dielectric (ILD) layer, which may include at least one via-level dielectric layer and/or at least one line-level dielectric layer. The first bonding dielectric layer 460 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The first bonding-level metal interconnect structures 480 may comprise metal via structures, metal line structures, metal pad structures, etc.

First bump structures 498 may be formed at the topmost level of the first bonding dielectric layer 460. Each of the first bump structures 498 may be formed on a respective one of the backside metal interconnect structures 340, which overlies the first molding compound matrix 397. In one embodiment, the first bump structures 498 may comprise via portions formed within, and laterally surrounded by, the first bonding dielectric layer 460. Further, the first bump structures 498 may comprise pillar structures or pad structures overlying the topmost surface of the first bonding dielectric layer 460. In one embodiment, the first bump structures 498 may comprise chip connection (C2) bonding structures such as microbump structures.

Referring to FIG. 4I, device semiconductor dies 100 may be attached to the first bump structures 498 using arrays of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having a respective set of connection metal pads 188 formed therein, and a respective bump-level dielectric layer 190 having a respective set of second bump structures 198 formed therein. The second bump structures 198 of the device semiconductor dies 100 may be bonded to the first bump structures 498 through the arrays of solder material portions 493.

An underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

Referring to FIG. 4J, a second molding compound matrix 497 may be formed around the device semiconductor dies 100 and the underfill material portion 495 and directly on the first bonding dielectric layer 460. The second molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing process. A remaining portion of the cured EMC material constitutes the second molding compound matrix 497.

The second molding compound matrix 497 may embed a two-dimensional array of sets of device semiconductor dies 100, may have a top surface located within a horizontal plane including topmost surfaces of the device semiconductor dies 100, and may comprise a planar bottom surface contacting the top surface of the first bonding dielectric layer 460. The second molding compound matrix 497 provides mechanical support and environmental protection for the device semiconductor dies 100. Generally, the second molding compound matrix 497 is vertically spaced from the first molding compound matrix 397 by the first bonding dielectric layer 460, and does not contact the first molding compound matrix 397. The second molding compound matrix 497 may be formed around the device semiconductor dies 100 directly on the first bonding dielectric layer 460.

Referring to FIG. 4K, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation.

Referring to FIG. 4L, a second bonding dielectric layer 560 having second bonding-level metal interconnect structures 580 formed therein may be formed on the first backside metal interconnect structures 340 and the first backside dielectric material layers 330. The second bonding dielectric layer 560 may be formed directly on the first molding compound matrix 397. The second bonding dielectric layer 560 comprises at least one interlayer dielectric (ILD) layer, which may include at least one via-level dielectric layer and/or at least one line-level dielectric layer. The second bonding dielectric layer 560 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The second bonding-level metal interconnect structures 580 may comprise metal via structures, metal line structures, metal pad structures, etc.

Metal bump structures 598 may be formed on the first backside metal interconnect structures 340 and the second bonding dielectric layer 560. Each of the metal bump structures 598 may be formed on a respective one of the first backside metal interconnect structures 340. In one embodiment, the metal bump structures 598 may comprise via portions formed within, and laterally surrounded by, the second bonding dielectric layer 560. Further, the metal bump structures 598 may comprise pad structures overlying the topmost surface of the second bonding dielectric layer 560. In one embodiment, the metal bump structures 598 may comprise controlled collapse chip connection (C4) pads. Each of the metal bump structures 598 may be formed directly on a respective one of the second bonding-level metal interconnect structures 580 and over the second bonding dielectric layer 560. Solder balls 593 may be attached to the metal bump structures 598.

Referring to FIG. 4M, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the second molding compound matrix 497.

A dicing process may be performed to dice a reconstituted die including a two-dimensional array of TSV-containing semiconductor dies 300, the first molding compound matrix 397, the first bonding dielectric layer 460, a two-dimensional array of sets of device semiconductor dies 100, a two-dimensional array of underfill material portions 495, and the second molding compound matrix 497. Generally, the reconstituted die comprises at least the bonding dielectric layer 560, the first molding compound matrix 397, and the first bonding dielectric layer 460. Diced portions of the reconstituted die comprise composite dies 800. Each composite die 800 comprises a TSV-containing semiconductor die 300, a diced portion of the second bonding dielectric layer 560, a diced portion of the first molding compound matrix 397, a diced portion of the first bonding dielectric layer 460, and a diced portion of the second molding compound matrix 497.

The exemplary structure illustrated in FIG. 4M comprises a semiconductor package, which comprises: a first semiconductor substrate 310 having through-substrate-via (TSV) structures 304 formed therein, first semiconductor devices 320 and first metal interconnect structures 360 located on a front side of the first semiconductor substrate 310, and first backside metal interconnect structures 340 located on a backside of the first semiconductor substrate 310; a first molding compound matrix 397 laterally surrounding the TSV-containing semiconductor die 300; a first bonding dielectric layer 460 located on the first metal interconnect structures 360; and first bump structures 498 located on the first bonding dielectric layer 460.

In one embodiment, the first molding compound matrix 397 is in contact with a frame-shaped horizontal surface of the first bonding dielectric layer 460. In one embodiment, the semiconductor package further comprises device semiconductor dies 100 attached to the first bump structures 498 via arrays of solder material portions 493. In one embodiment, the semiconductor package comprises: an underfill material portion 495 laterally surrounding the arrays of solder material portions 493; and a second molding compound matrix 497 laterally surrounding the device semiconductor dies 100 and the underfill material portion 495.

In one embodiment, the second molding compound matrix 497 is vertically spaced from the first molding compound matrix 397 by the first bonding dielectric layer 460. In one embodiment, sidewalls of the first bonding dielectric layer 460 are vertically coincident with outer sidewalls of the second molding compound matrix 497. In one embodiment, device semiconductor dies 100 comprise horizontal surfaces that are located within a horizontal plane including a horizontal surface of the second molding compound matrix 497.

In one embodiment, sidewalls of the first bonding dielectric layer 460 are vertically coincident with outer sidewalls of the first molding compound matrix 397. In one embodiment, first bonding-level metal interconnect structures 480 are formed within the first bonding dielectric layer 460, wherein the first bump structures 498 contact a subset of the first bonding-level metal interconnect structures 480.

In one embodiment, the semiconductor package comprises a second bonding dielectric layer 560 having bonding-level metal interconnect structures 580 formed therein and located on the backside metal interconnect structures 340. In one embodiment, the second bonding dielectric layer 560 is in contact with a frame-shaped horizontal surface of the first molding compound matrix 397. In one embodiment, sidewalls of the second bonding dielectric layer 560 are vertically coincident with outer sidewalls of the first molding compound matrix 397. In one embodiment, the semiconductor package comprises metal bump structures 598 contacting a subset of the bonding-level metal interconnect structures 580. In one embodiment, the first semiconductor devices 320 comprise first field effect transistors; and each of the device semiconductor dies 100 comprises a respective set of additional field effect transistors.

Referring to FIG. 4N, a fourth flow chart including a subset of processing steps for forming a semiconductor structure is illustrated.

Referring to step 1410 and FIGS. 4A-4D, a semiconductor assembly (300, 934, 924) may be provided. The semiconductor assembly (300, 934, 924) comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and first metal interconnect structures 360 located on a front side of the first semiconductor substrate 310, and first backside metal interconnect structures 340 located on a backside of the first semiconductor substrate 310.

Referring to step 1420 and FIG. 4E, the first backside metal interconnect structures 340 of the semiconductor assembly (300, 934, 924) may be attached to a carrier wafer 902 using a die attachment film 932.

Referring to step 1430 and FIGS. 4F-4M, the semiconductor carrier substrate 924 and the die attachment film 934 may be removed.

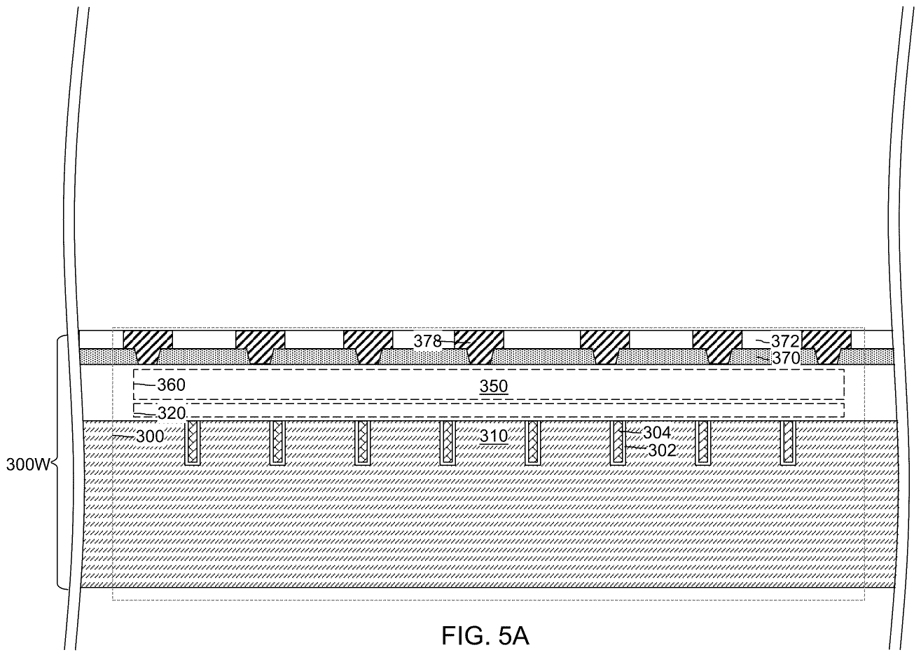

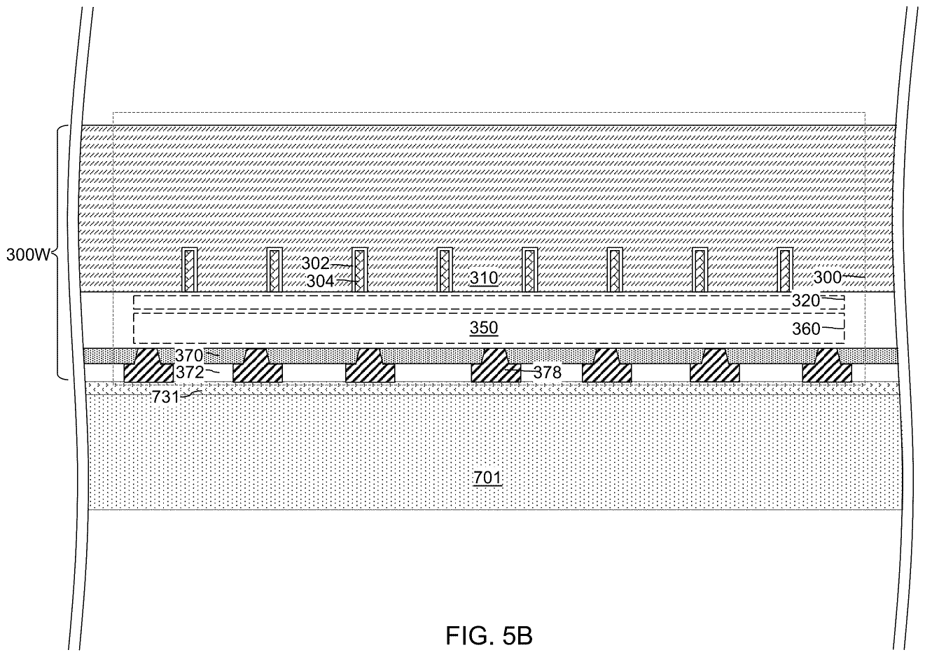

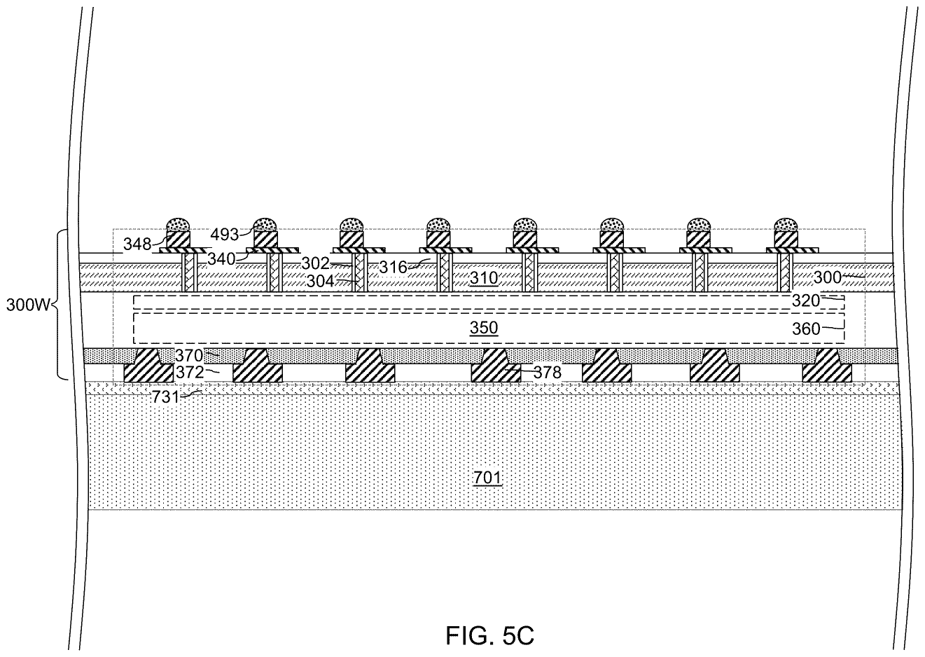

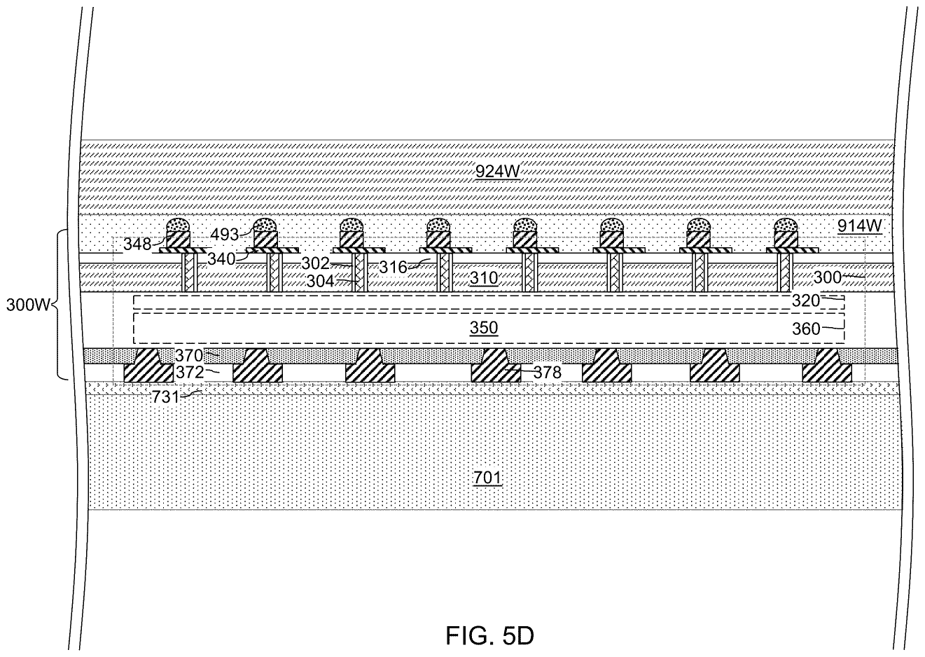

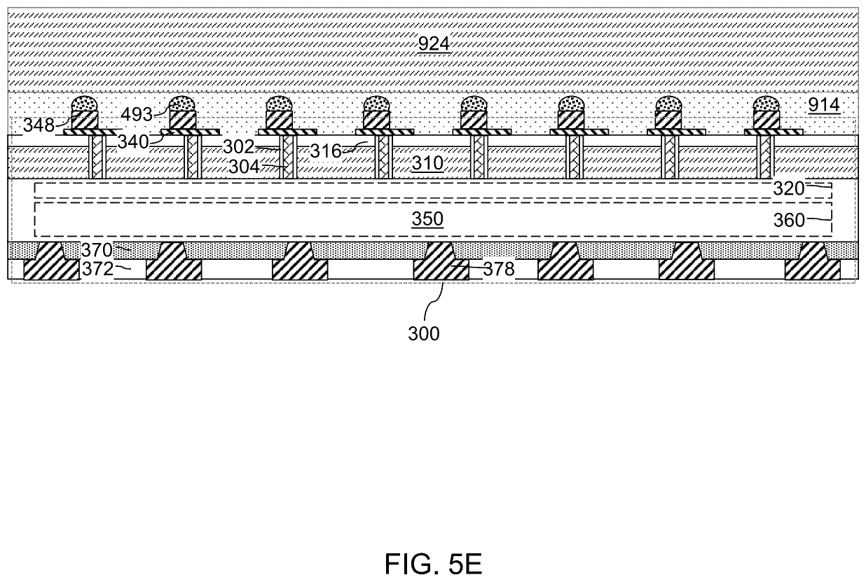

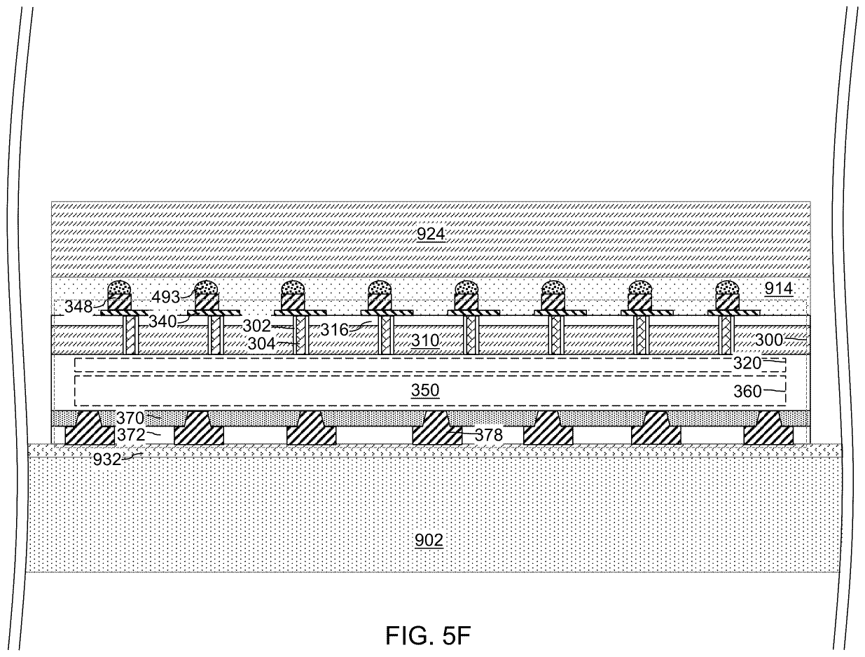

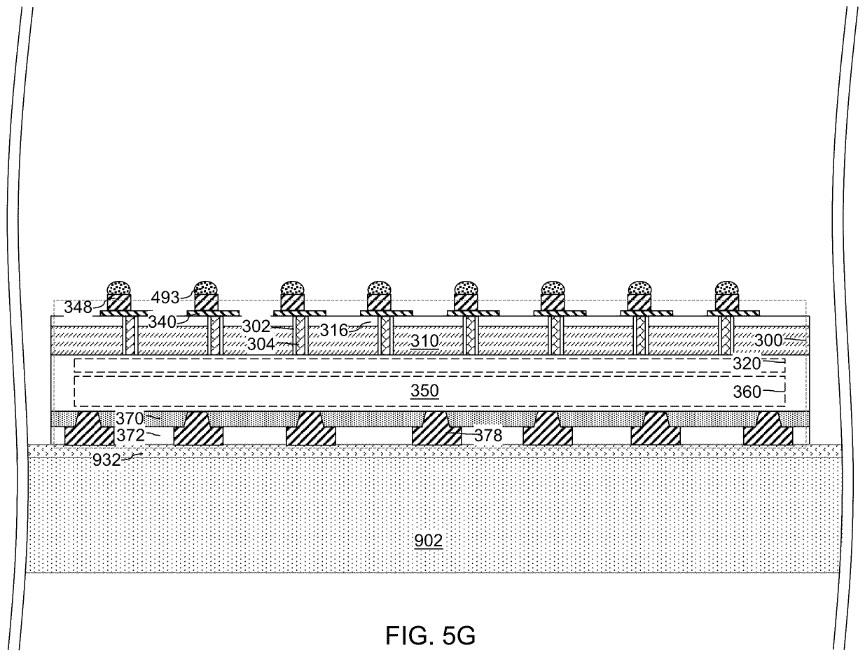

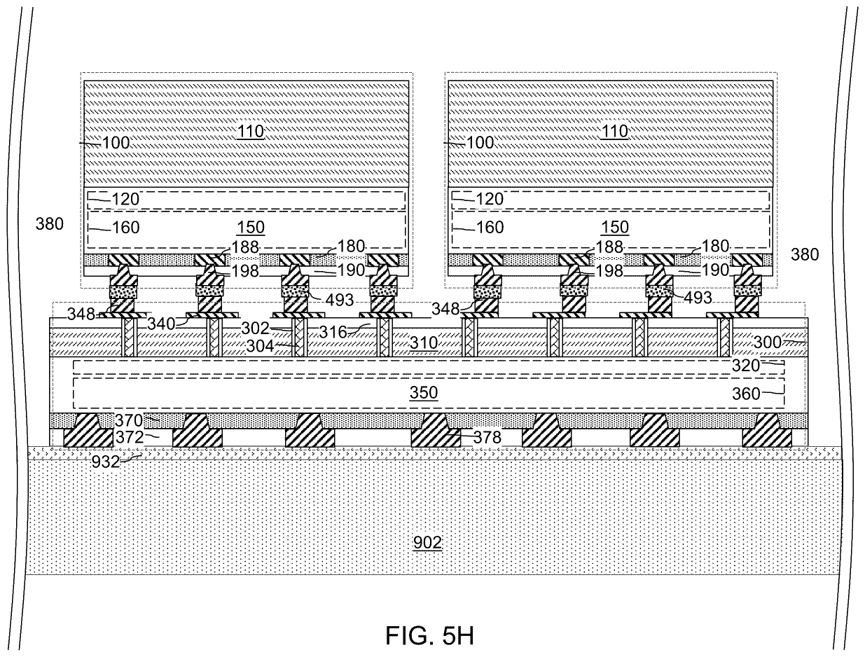

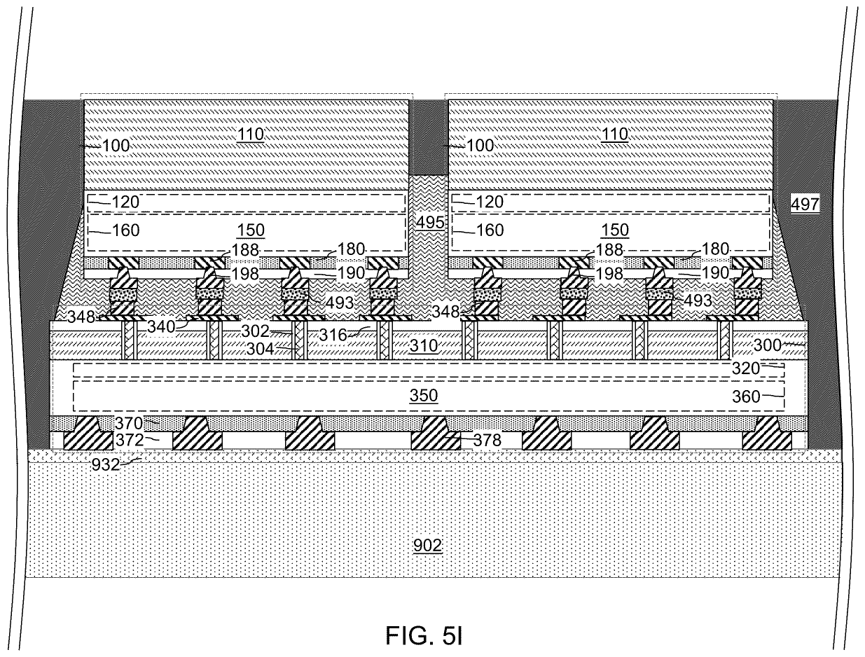

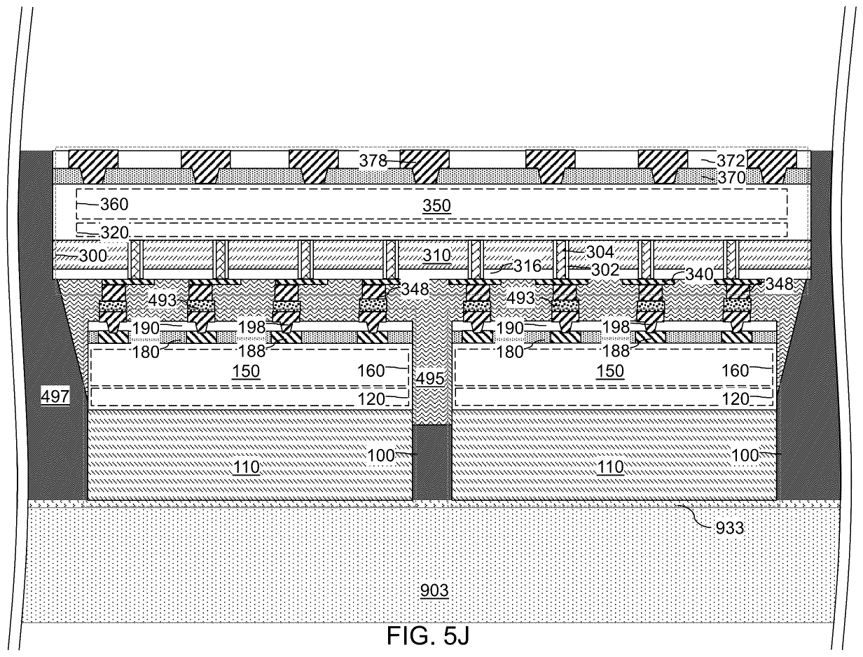

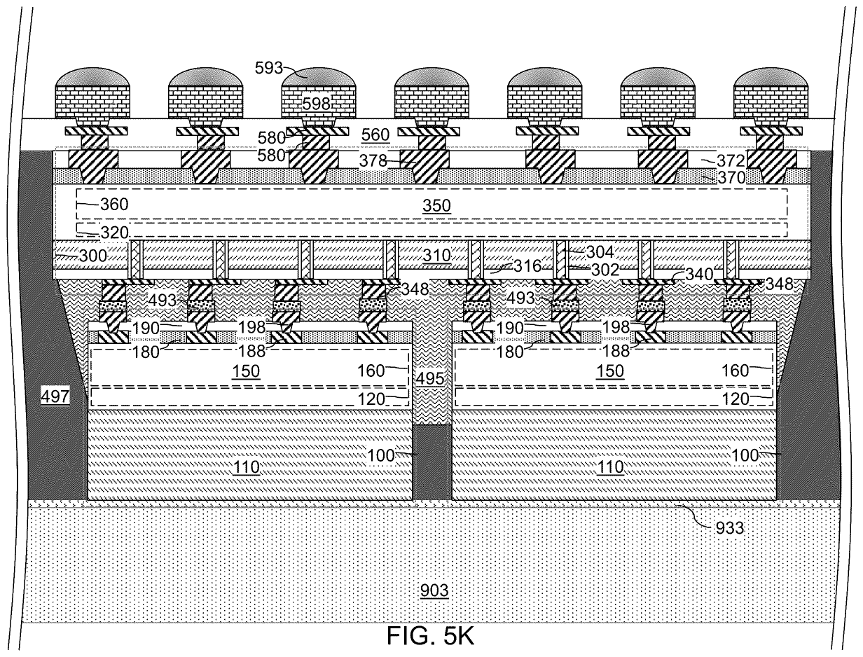

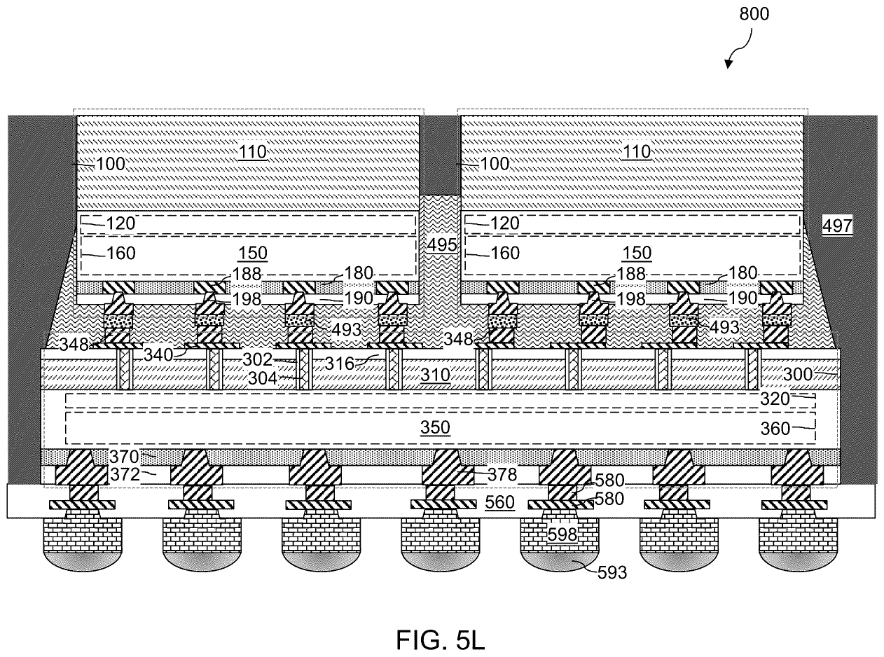

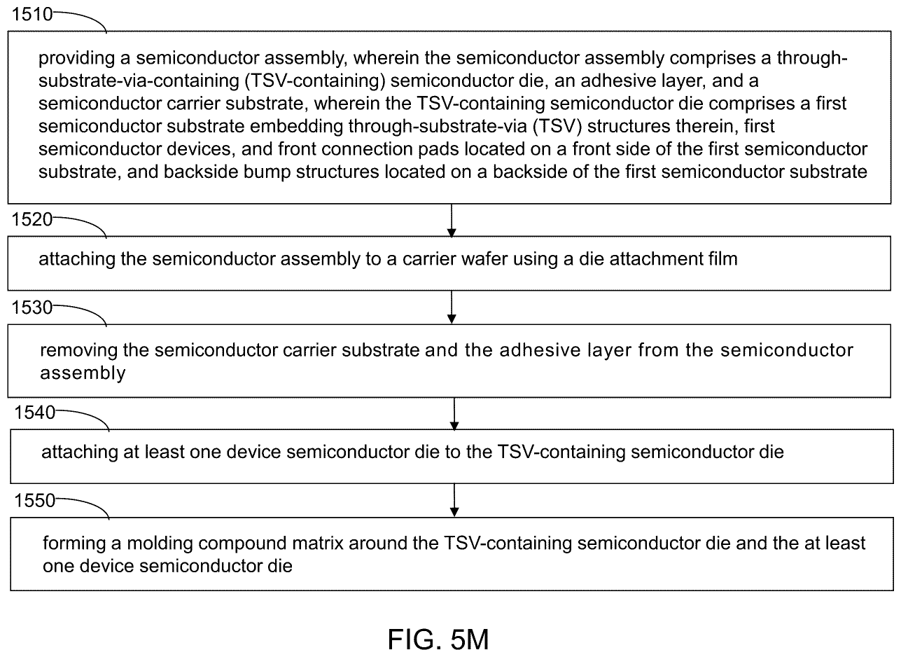

FIGS. 5A-5L are sequential vertical cross-sectional views of a fifth embodiment structure during a sequence of processing steps according to an embodiment of the present disclosure.

Referring to FIG. 5A, a device wafer 300W is illustrated, which includes a first semiconductor substrate 310 and structural elements formed therein and thereupon. The device wafer 300W illustrated in FIG. 5A may be the same as the device wafer 300W illustrated in FIG. 1A.

Referring to FIG. 5B, the device wafer 300W may be attached to a handle wafer 701, for example, using a die attachment film 731. The handle wafer 701 may be any wafer that may be used to provide mechanical support during subsequent handling of the device wafer 300W. In one embodiment, the handle wafer 701 may comprise a glass carrier wafer having a same lateral dimension as the device wafer 300W.

Referring to FIG. 5C, the device wafer 300W may be thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing (CMP) process. The remaining portion of the insulating material constitutes a backside insulating layer 316. Physically exposed backside surfaces of the TSV structures 304 may be coplanar with a physically exposed horizontal surface of the backside insulating layer 316.

A metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Backside bump structures 348 may be formed on the first backside metal interconnect structures 340. For example, the backside bump structures 348 may be formed by depositing a metallic seed layer, by depositing and patterning a photoresist masking layer, by performing an electroplating process, and by removing the photoresist masking layer and removing unmasked portions of the metallic seed layer. Each backside bump structure 348 may be formed on a respective one of the first backside metal interconnect structures 340. In one embodiment, the backside bump structures 348 may comprise chip connection (C2) bump structures such as microbump structures. Solder material portions 493 may be formed on the backside bump structures.

Referring to FIG. 5D, a semiconductor carrier wafer 924W may be attached to the device wafer 300W using a continuous adhesive layer 914W. The semiconductor carrier wafer 924W may comprise a commercially available semiconductor wafer (such as a silicon wafer) having a same lateral extent as the device wafer 300W. The continuous adhesive layer 914W may comprise a glue layer. For example, the continuous adhesive layer 914W may comprise a thermosetting adhesive, such as benzocyclobutene (BCB) or an epoxy-based adhesive. The continuous adhesive layer 914W provides adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 914W, 924W) of the device wafer 300W, the continuous adhesive layer 914W, and the semiconductor carrier wafer 924W is formed.

Referring to FIG. 5E, the die attachment film 731 may be deactivated to facilitate the detachment of the handle wafer 701 from the wafer-level bonded assembly (300W, 914W, 924W). For instance, the die attachment film 731 may comprise an ultraviolet-decomposable material, and the handle wafer 701 may comprise a transparent wafer such as a glass substrate. In this embodiment, ultraviolet radiation may impinge on the die attachment film through the handle wafer 701 to break down the adhesive properties of the film, enabling easy detachment. Once the die attachment film 731 is deactivated, the handle wafer 701 is removed, leaving the device wafer 300W securely bonded to the semiconductor carrier wafer 924W via the continuous adhesive layer 914W. To prepare the surface for subsequent processing, any residual die attachment film 731 may be eliminated through a cleaning process, such as solvent cleaning or plasma etching, ensuring a contaminant-free interface.

The wafer-level bonded assembly (300W, 914W, 924W) may be subsequently diced along dicing channels. The dicing channels extend along boundaries between neighboring pairs of TSV-containing semiconductor dies 300. Diced portions of the wafer-level bonded assembly (300W, 914W, 924W) comprise semiconductor assemblies (300, 914, 924). Each semiconductor assembly (300, 914, 924) comprises a through-substrate-via-containing (TSV-containing) semiconductor die 300, an adhesive layer 914, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and backside metal interconnect structures 340 located on a backside of the first semiconductor substrate 310.

Referring to FIG. 5F, a plurality of semiconductor assemblies (300, 914, 924) provided through the processing steps described with reference to FIGS. 5A-5E may be attached to a carrier wafer 902 using a die attachment film 932. It is to be understood that a region around a single semiconductor assembly (300, 914, 924) is illustrated in FIG. 5F and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 914, 924) may be attached to the die attachment film 932. In one embodiment, the two-dimensional array of semiconductor assemblies (300, 914, 924) may be arranged as a two-dimensional rectangular array of semiconductor assemblies (300, 914, 924). A gap may be present between each neighboring pair of semiconductor assemblies (300, 914, 924).

Referring to FIG. 5G, each of the semiconductor carrier substrates 924 within the array of semiconductor assemblies (300, 914, 924) may be detached from a respective one of the TSV-containing semiconductor dies 300. Each semiconductor carrier substrate 924 may be detached from a respective TSV-containing semiconductor die 300 by performing a debonding process that uses thermal debonding or solvent debonding. For example, each adhesive layer 914 may be deactivated to facilitate the detachment of the semiconductor carrier substrates 924 from the TSV-containing semiconductor dies 300. Specifically, the adhesive layers 914, which may comprise a thermally-decomposable material, may be decomposed by performing an anneal process at an elevated temperature in a range from 150° C. to 300° C. Alternatively, the adhesive layers 914 may be removed by dissolution using a suitable solvent. Once deactivated, the semiconductor carrier substrates 924 are removed, leaving the TSV-containing semiconductor dies 300 exposed and ready for subsequent processing. To ensure a pristine surface, any residual adhesive from the adhesive layers 914 may be eliminated through a cleaning process, such as solvent cleaning or plasma etching, ensuring a contaminant-free interface for further manufacturing steps. Thus, the semiconductor carrier substrate 924 and the adhesive layer 914 may be removed from each semiconductor assembly (300, 914, 924). The array of solder material portions 493 may be physically exposed.

Referring to FIG. 5H, device semiconductor dies 100 may be attached to the backside bump structures 348 via the array of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction. Each of the device semiconductor dies 100 is attached to the backside bump structures 348 via a respective array of solder material portions 493.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having a respective set of connection metal pads 188 formed therein, and a respective bump-level dielectric layer 190 having a respective set of second bump structures 198 formed therein. The second bump structures 198 of the device semiconductor dies 100 may be bonded to the first bump structures 498 through the arrays of solder material portions 493. Gaps 380 may be present between adjacent semiconductor dies 300.

Referring to FIG. 5I, an underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

A molding compound matrix 497 may be formed around the device semiconductor dies 100 and the underfill material portion 495 and directly on the sidewalls of the TSV-containing semiconductor dies 300. The molding compound matrix 497 may also fill gaps 380 between adjacent semiconductor dies 300. The molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing process. A remaining portion of the cured EMC material constitutes the molding compound matrix 497.

The molding compound matrix 497 may embed a two-dimensional array of sets of device semiconductor dies 100 and a two-dimensional array of TSV-containing semiconductor dies 300. The molding compound matrix 497 may have a top surface located within a horizontal plane including topmost surfaces of the device semiconductor dies 100, and may comprise a planar bottom surface contacting the top surface of the die attachment film 932. The molding compound matrix 497 provides mechanical support and environmental protection for the device semiconductor dies 100 and the TSV-containing semiconductor dies 300.

Referring to FIG. 5J, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation. A suitable clean process may be performed to clean physically exposed surfaces of the front connection pads 378, the second front capping dielectric layer 372, and a horizontal surface of the first molding compound matrix 397.

Referring to FIG. 5K, a bonding dielectric layer 560 having bonding-level metal interconnect structures 580 formed therein may be formed on the front connection pads 378. The bonding dielectric layer 560 may be formed directly on the first molding compound matrix 397. The bonding dielectric layer 560 comprises at least one interlayer dielectric (ILD) layer, which may include at least one via-level dielectric layer and/or at least one line-level dielectric layer. The bonding dielectric layer 560 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The bonding-level metal interconnect structures 580 may comprise metal via structures, metal line structures, metal pad structures, etc.

Metal bump structures 598 may be formed at the topmost level of the bonding dielectric layer 560. Each of the metal bump structures 598 may be formed on a respective one of the bonding-level metal interconnect structures 580, which overlies and contacts the first molding compound matrix 397. In one embodiment, the metal bump structures 598 may comprise via portions formed within, and laterally surrounded by, the bonding dielectric layer 560. Further, the metal bump structures 598 may comprise pad structures overlying the topmost surface of the bonding dielectric layer 560. In one embodiment, the metal bump structures 598 may comprise controlled collapse chip connection (C4) pads. Each of the metal bump structures 598 may be formed directly on a respective one of the bonding-level metal interconnect structures 580 and over the bonding dielectric layer 560. Solder balls 593 may be attached to the metal bump structures 598.

Referring to FIG. 5L, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the molding compound matrix 497.

A dicing process may be performed to dice a reconstituted die including a two-dimensional array of TSV-containing semiconductor dies 300, a two-dimensional array of sets of device semiconductor dies 100, a two-dimensional array of underfill material portions 495, the molding compound matrix 497, and a bonding dielectric layer 560. Diced portions of the reconstituted die comprise composite dies 800. Each composite die 800 comprises a TSV-containing semiconductor die 300, device semiconductor dies 100, an underfill material portion 495, and a diced portion of the bonding dielectric layer 560.

The exemplary structure illustrated in FIG. 5L comprises a semiconductor package, which comprises: a through-substrate-via-containing (TSV-containing) semiconductor die 300 comprising a first semiconductor substrate 310 having through-substrate-via (TSV) structures 304 formed therein, first semiconductor devices 320 and front connection pads 378 located on a front side of the first semiconductor substrate 310, and backside bump structures 348 located on a backside of the first semiconductor substrate 310; device semiconductor dies 100 bonded to the backside bump structures 348; a molding compound matrix 497 laterally surrounding the device semiconductor dies 100; and a bonding dielectric layer 560 having bonding-level metal interconnect structures 580 formed therein and located on the front connection pads 378.

In one embodiment, each of the device semiconductor dies 100 is attached to the backside bump structures 348 via a respective array of solder material portions 493. In one embodiment, the package structure comprises an underfill material portion 495 laterally surrounding the arrays of solder material portions 493 and formed within the molding compound matrix 497. In one embodiment, the underfill material portion 495 is in contact with the backside bump structures 348.

In one embodiment, the bonding dielectric layer 560 is in contact with the molding compound matrix 497 and a backside insulating layer 316 of the TSV-containing semiconductor die 300. In one embodiment, the bonding dielectric layer 560 has a greater lateral extent than the TSV-containing semiconductor die 300.

In one embodiment, sidewalls of the bonding dielectric layer 560 are vertically coincident with outer sidewalls of the molding compound matrix 497. In one embodiment, all sidewalls of the TSV-containing semiconductor die 300 are in contact with inner sidewalls of the molding compound matrix 497. In one embodiment, the package structure comprises metal bump structures 598 located on the bonding-level metal interconnect structures 580 and the bonding dielectric layer 560.

In one embodiment, the first semiconductor devices 320 comprise first field effect transistors; and each of the device semiconductor dies 100 comprises a respective set of additional field effect transistors. In one embodiment, each of the device semiconductor dies 100 comprises a respective horizontal surface that is located entirely within a horizontal plane including a planar frame-shaped surface of the molding compound matrix 497. In one embodiment, the TSV-containing semiconductor die 300 comprises first metal interconnect structures 360 formed within first dielectric material layers 350 and interposed between the front connection pads 378 and the first semiconductor devices 320.

Referring to FIG. 5M, a fifth flow chart including a subset of processing steps for forming a semiconductor structure is illustrated.

Referring to step 1510 and FIGS. 5A-5E, a semiconductor assembly (300, 914, 924) is provided. The semiconductor assembly (300, 914, 924) comprises a through-substrate-via-containing (TSV-containing) semiconductor die 300, an adhesive layer 914, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and backside bump structures 348 located on a backside of the first semiconductor substrate 310;

Referring to step 1520 and FIG. 5F, the semiconductor assembly (300, 914, 924) is attached to a carrier wafer 902 using a die attachment film 932.

Referring to step 1530 and FIGS. 5G-5L, the semiconductor carrier substrate 924 and the adhesive layer 914 may be removed from the semiconductor assembly (300, 914, 924).

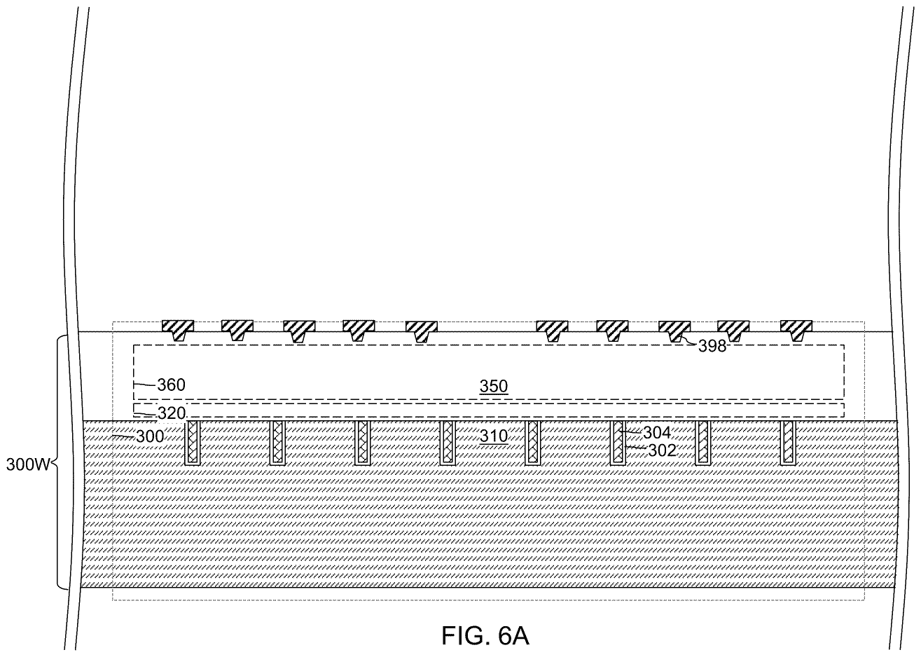

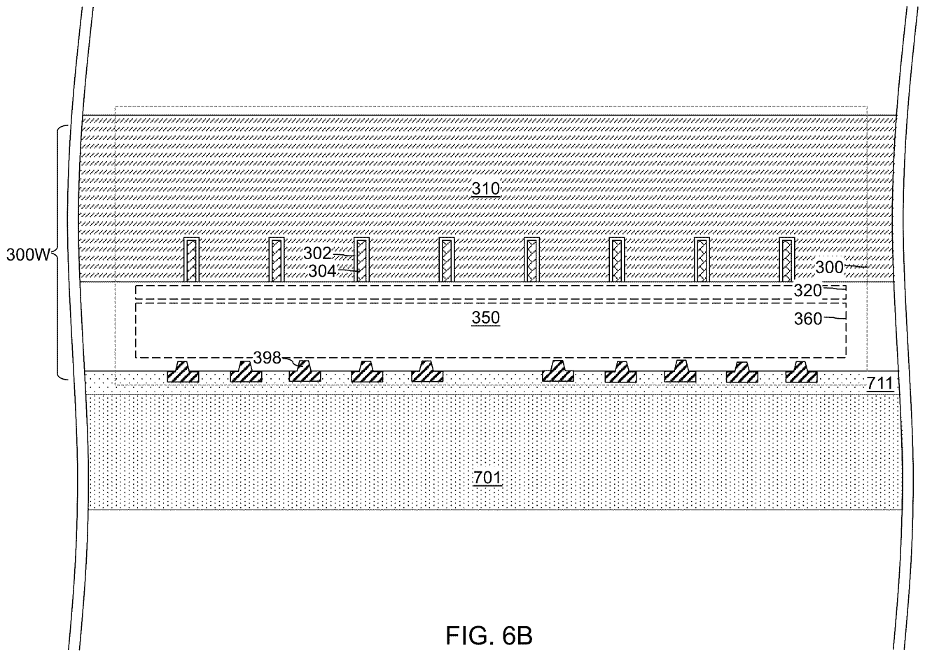

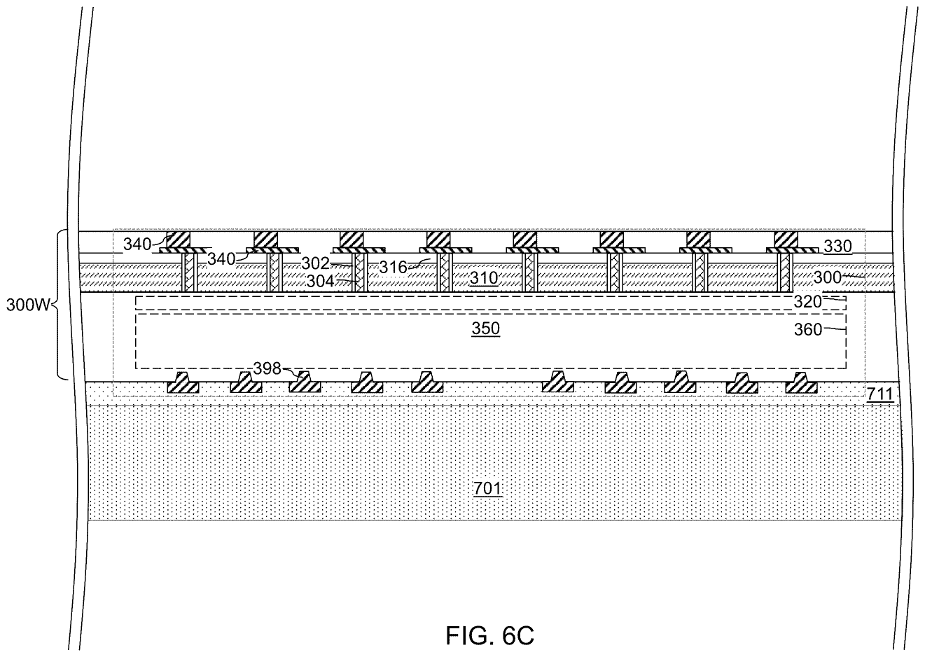

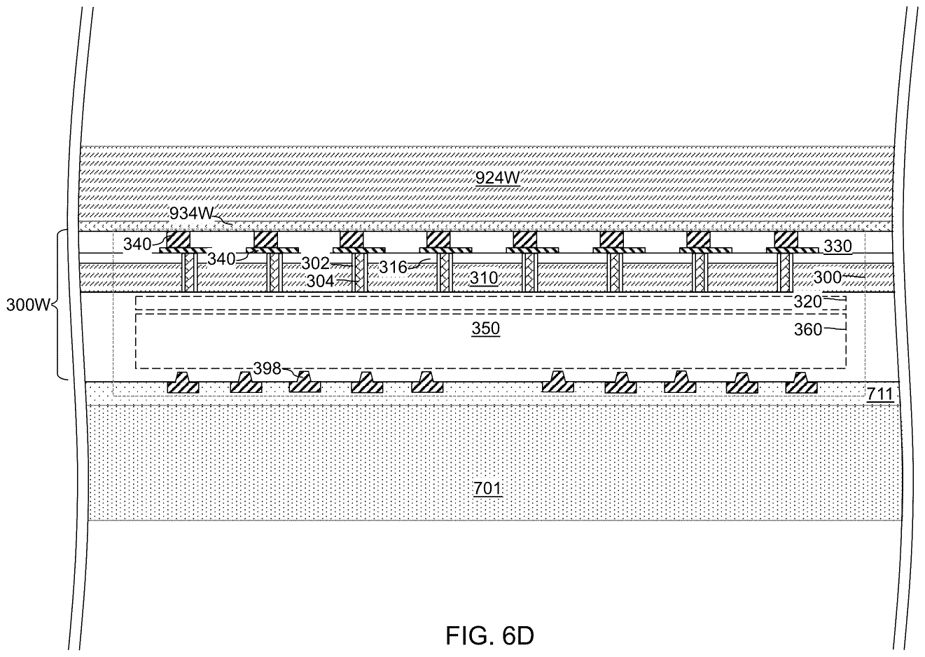

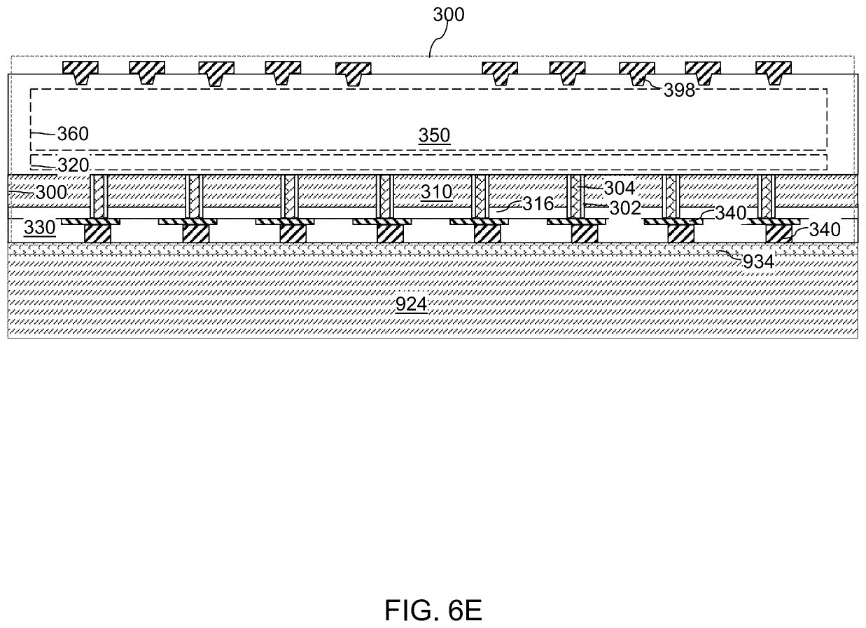

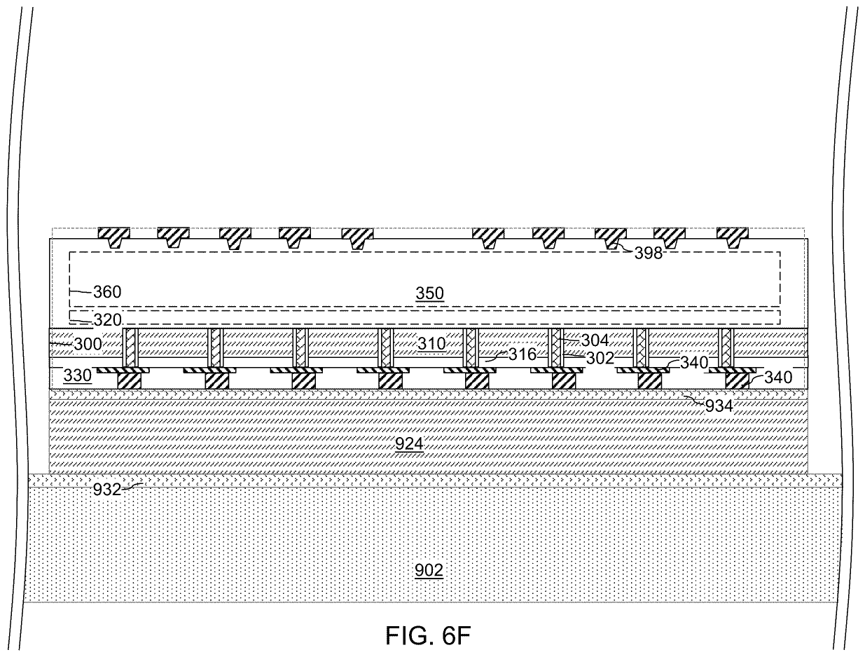

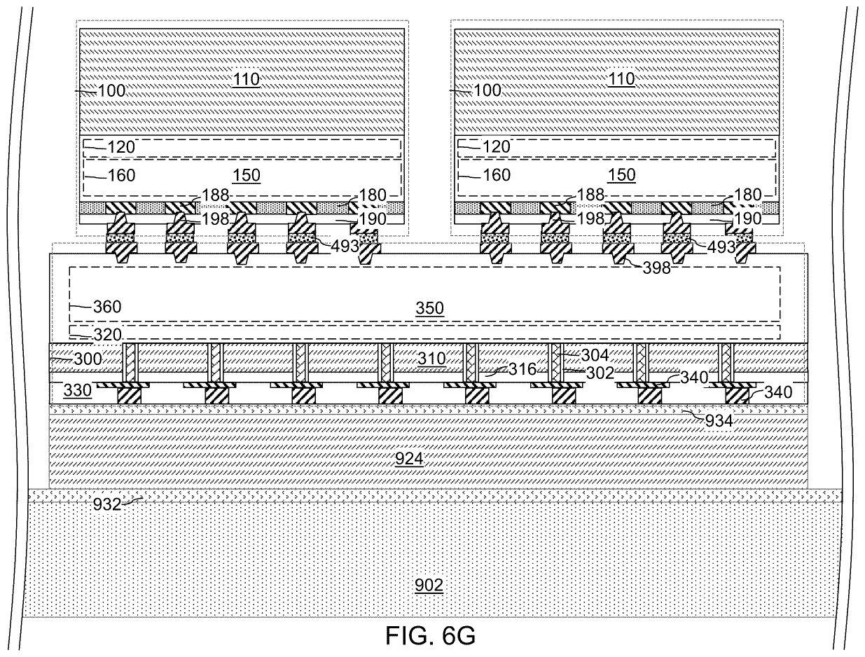

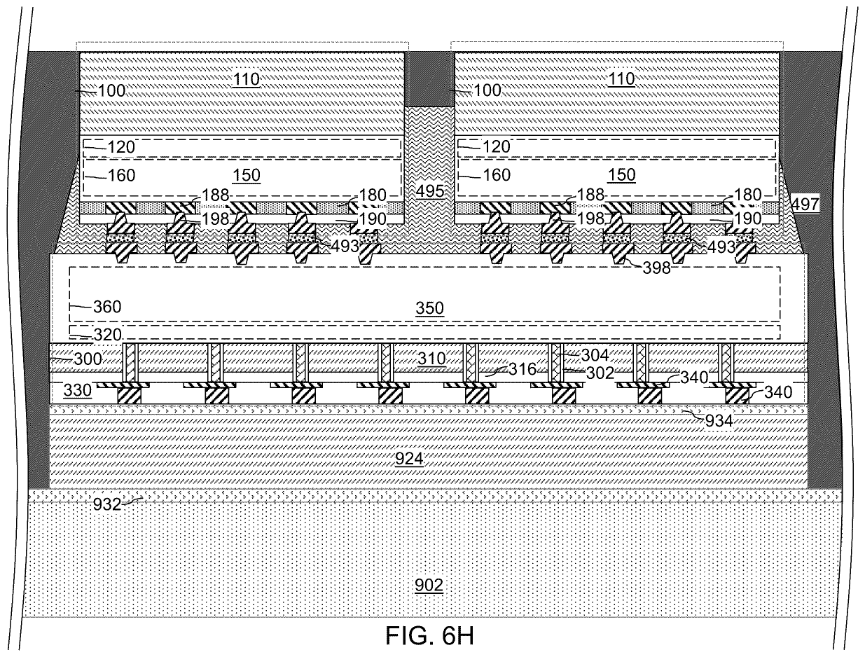

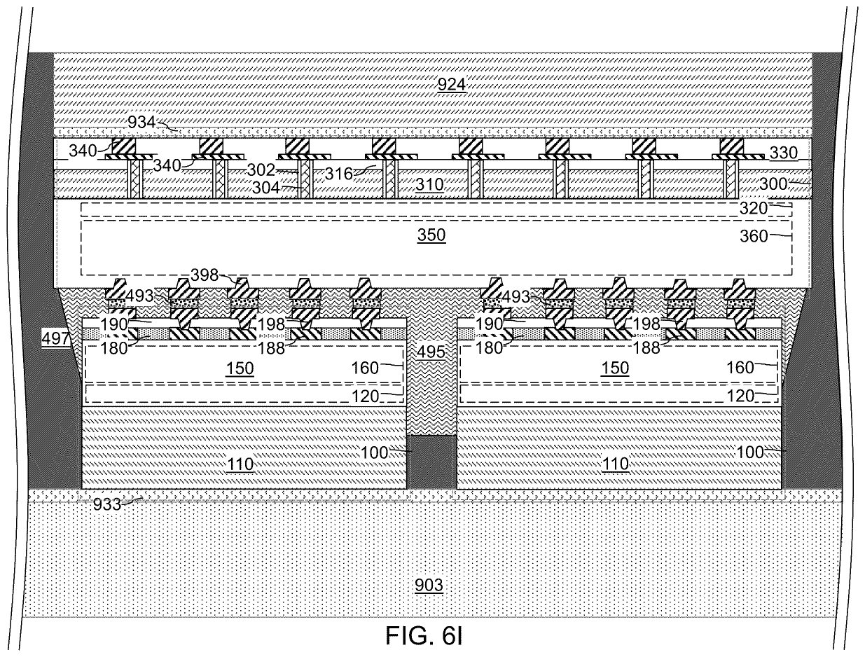

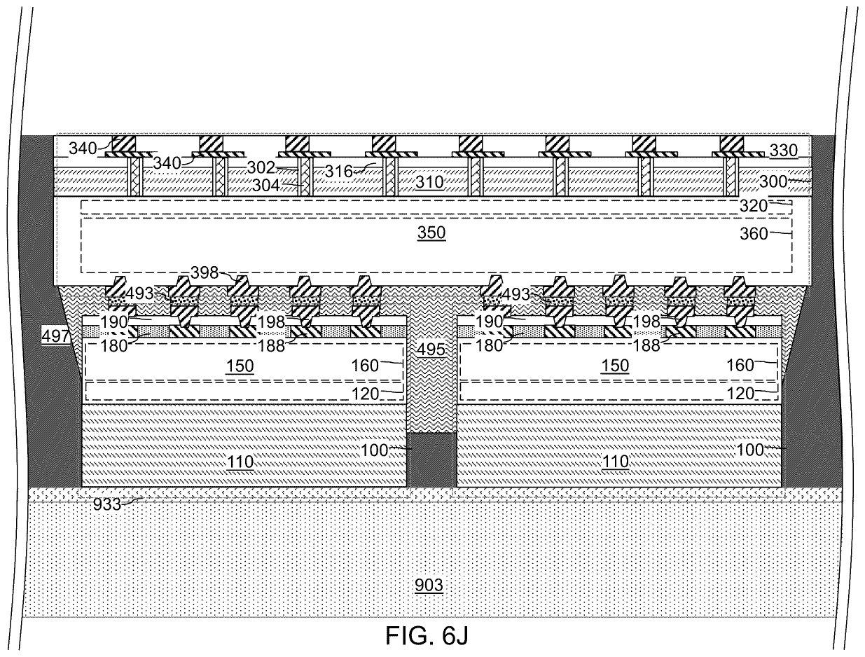

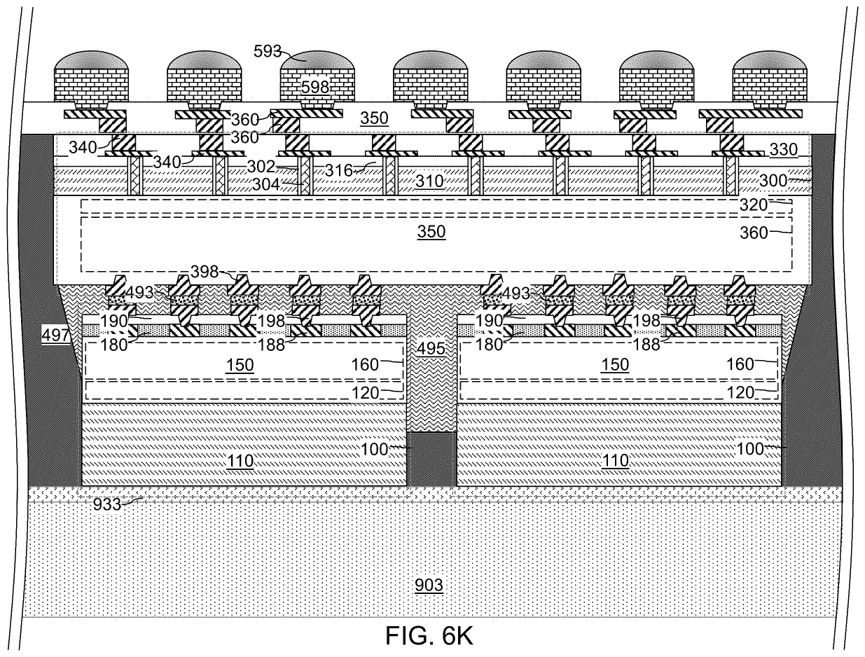

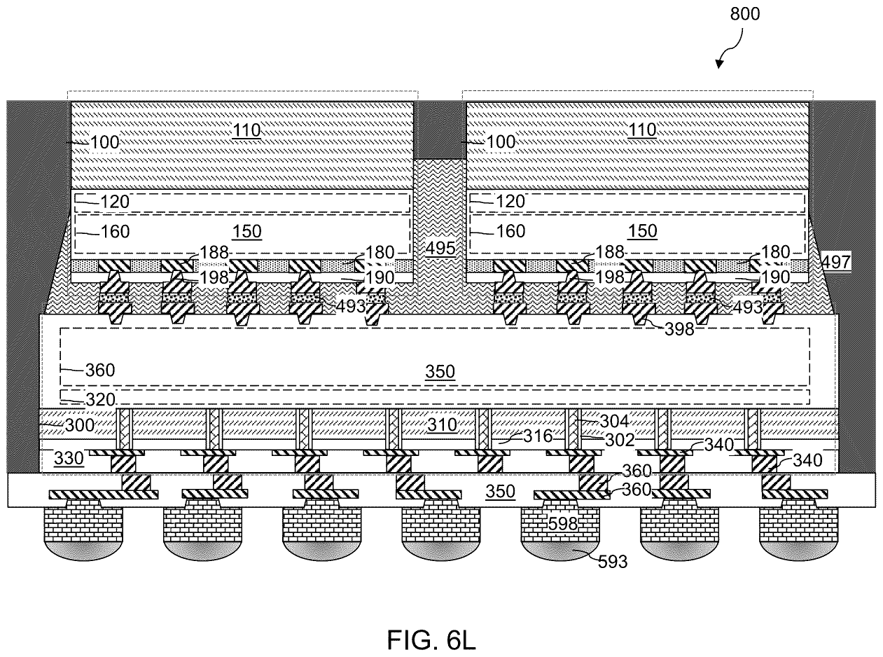

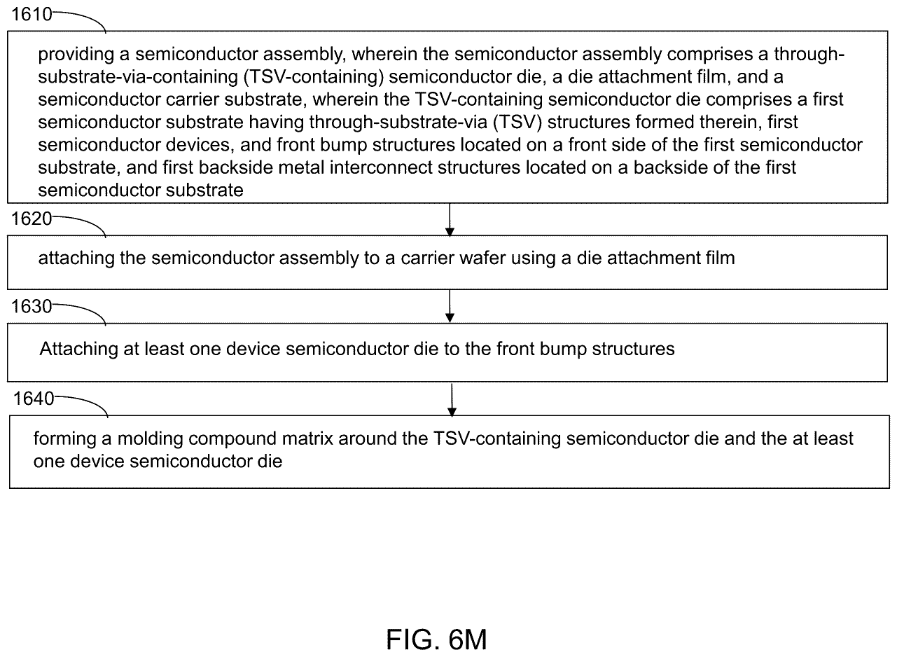

FIGS. 6A-6L are sequential vertical cross-sectional views of a sixth embodiment structure during a sequence of processing steps according to an embodiment of the present disclosure.

Referring to FIG. 6A, a device wafer 300W is illustrated, which includes a first semiconductor substrate 310 and structural elements formed therein and thereupon. The device wafer 300W illustrated in FIG. 5A may be derived from the device wafer 300W illustrated in FIG. 1A by omitting formation of the at least one front capping dielectric layer (370, 372) and the front connection pads 378. Front bump structures 398 may be formed front side of the first semiconductor substrate 310 on a subset of the first metal interconnect structures 360 formed within the first dielectric material layers 350. Each of the front bump structures 398 may be formed on a respective one of the first metal interconnect structures 360. In one embodiment, the front bump structures 398 may comprise via portions formed within, and laterally surrounded by, a topmost dielectric layer selected from the first dielectric material layers 350. Further, the front bump structures 398 may comprise pillar structures or pad structures overlying the topmost surface of the first dielectric material layers 350. In one embodiment, the front bump structures 398 may comprise chip connection (C2) bonding structures such as microbump structures.

Referring to FIG. 6B, the device wafer 300W may be attached to a handle wafer 701, for example, using an adhesive layer 711. The adhesive layer 711 may comprise a thermally decomposable material, a UV-decomposable material, or a combination thereof, depending on the process criteria. In semiconductor manufacturing, adhesive layers are commonly made from polymers such as polyimides, benzocyclobutene (BCB), epoxy-based adhesives, or other thermosetting resins. These materials are selected based on their ability to provide strong adhesion while allowing for subsequent easy detachment during debonding processes. For example, UV-decomposable adhesives may be preferred when the handle wafer 701 is a transparent substrate like glass, enabling UV exposure through the handle wafer to facilitate debonding. Thermally decomposable adhesives may be utilized when thermal processing may be used to degrade the adhesive and separate the wafers. The adhesive layer 711 ensures secure attachment during the handling and processing of the device wafer 300W. The handle wafer 701, in this embodiment, may comprise a glass carrier wafer with the same lateral dimensions as the device wafer 300W, providing mechanical support during subsequent steps in the manufacturing process.

Referring to FIG. 6C, the device wafer 300W may be thinned from the backside. The backside of the first semiconductor substrate 310 may be removed by grinding, polishing, an anisotropic etch process, and/or an isotropic etch process. Backside surfaces of the TSV structures 304 may be physically exposed upon thinning of the first semiconductor substrate 310. The TSV structures 304 vertically extend through the thinned first semiconductor substrate 310.

The backside surface of the first semiconductor substrate 310 may be further thinned by performing an etch process (which may comprise an anisotropic etch process or an isotropic etch process). An insulating material such as silicon oxide may be deposited over the recessed backside surface of the first semiconductor substrate 310. Excess portions of the insulating material may be removed from above a horizontal plane including the backside surfaces of the TSV structures 304 may be removed by performing a planarization process such as a chemical mechanical polishing (CMP) process. The remaining portion of the insulating material constitutes a backside insulating layer 316. Physically exposed backside surfaces of the TSV structures 304 may be coplanar with a physically exposed horizontal surface of the backside insulating layer 316.

A metal layer may be deposited over the backside surfaces of the TSV structures 304, and may be subsequently patterned to form first backside metal interconnect structures 340. The first backside metal interconnect structures 340 may comprise metal pad structures, metal line structures, and/or metal pillar structures. The device wafer 300W includes an array of TSV-containing semiconductor dies 300.

Referring to FIG. 6D, a semiconductor carrier wafer 924W may be attached to the device wafer 300W using a continuous die attachment film 934W. The semiconductor carrier wafer 924W may comprise a commercially available semiconductor wafer (such as a silicon wafer) having a same lateral extent as the device wafer 300W. The continuous die attachment film 934W may comprise a glue layer. For example, the continuous die attachment film 934W may comprise a thermosetting adhesive, such as benzocyclobutene (BCB) or an epoxy-based adhesive. Surfaces of the first backside metal interconnect structures 340 may contact the continuous die attachment film 934W. The continuous die attachment film 934W provide adhesion between the device wafer 300W and the semiconductor carrier wafer 924W. Optionally, the semiconductor carrier wafer 924W may be thinned to a desired target thickness prior to, or after, bonding to the device wafer 300W. The thickness of the semiconductor carrier wafer 924W may be in a range from 60 microns to 1 mm, such as from 150 microns to 600 microns, although lesser and greater thicknesses may also be used. A wafer-level bonded assembly (300W, 934W, 924W) of the device wafer 300W, the continuous die attachment film 934W, and the semiconductor carrier wafer 924W is formed.

Referring to FIG. 6E, the die attachment film 731 may be deactivated to facilitate the detachment of the handle wafer 701 from the wafer-level bonded assembly (300W, 934W, 924W). For instance, the die attachment film 731 may comprise an ultraviolet-decomposable material, and the handle wafer 701 may comprise a transparent wafer such as a glass substrate. In this embodiment, ultraviolet radiation may impinge on the die attachment film through the handle wafer 701 to break down the adhesive properties of the film, enabling easy detachment. Once the die attachment film 731 is deactivated, the handle wafer 701 is removed, leaving the device wafer 300W securely bonded to the semiconductor carrier wafer 924W via the continuous die attachment film 934W. To prepare the surface for subsequent processing, any residual die attachment film 731 may be eliminated through a cleaning process, such as solvent cleaning or plasma etching, ensuring a contaminant-free interface.

The wafer-level bonded assembly (300W, 934W, 924W) may be subsequently diced along dicing channels. The dicing channels extend along boundaries between neighboring pairs of TSV-containing semiconductor dies 300. Diced portions of the wafer-level bonded assembly (300W, 934W, 924W) comprise semiconductor assemblies (300, 934, 924). Each semiconductor assembly (300, 934, 924) comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front connection pads 378 located on a front side of the first semiconductor substrate 310, and backside metal interconnect structures 340 located on a backside of the first semiconductor substrate 310.

Referring to FIG. 6F, a plurality of semiconductor assemblies (300, 934, 924) provided through the processing steps described with reference to FIGS. 6A-6E may be attached to a carrier wafer 902 using a die attachment film 932. It is to be understood that a region around a single semiconductor assembly (300, 934, 924) is illustrated in FIG. 6F and subsequent drawings. The carrier wafer 902 may be any carrier wafer known in the art. For example, the carrier wafer 902 may comprise a glass substrate having a circular shape or a rectangular shape in a plan view. The die attachment film 932 may comprise an ultraviolet-decomposable adhesive material. The die attachment film 932 may be attached to a top surface of the carrier wafer 902, and a two-dimensional array of semiconductor assemblies (300, 934, 924) may be attached to the die attachment film 932. In one embodiment, the semiconductor carrier substrate 924 of each semiconductor assembly (300, 934, 924) may be attached to the carrier wafer 902. In one embodiment, the two-dimensional array of semiconductor assemblies (300, 934, 924) may be arranged as a two-dimensional rectangular array of semiconductor assemblies (300, 934, 924). A gap may be present between each neighboring pair of semiconductor assemblies (300, 934, 924).

Referring to FIG. 6G, device semiconductor dies 100 may be attached to the front bump structures 398 via the array of solder material portions 493. Each of the device semiconductor dies 100 may comprise active devices such as field effect transistors, and may optionally comprise passive devices such as capacitors, resistors, inductors, etc. Each of the device semiconductor dies 100 may comprise a central processing unit (CPU), a graphic processing unit (GPU), a neural process unit (NPU), a digital signal processor (DSP), an embedded volatile memory, and/or an embedded non-volatile memory. Each of the device semiconductor dies 100 may have a smaller area than an underlying TSV-containing semiconductor die 300 in a plan view along a vertical direction. Each of the device semiconductor dies 100 is attached to the backside bump structures 348 via a respective array of solder material portions 493.

In one embodiment, each of the device semiconductor dies 100 may comprise a semiconductor substrate 110, a respective set of second semiconductor devices 120 (which may be referred to as additional semiconductor devices), a respective set of second dielectric material layers 150 having second metal interconnect structures 160 formed therein. In one embodiment, each of the device semiconductor dies 100 may comprise a respective connection-level dielectric layer 180 having a respective set of connection metal pads 188 formed therein, and a respective bump-level dielectric layer 190 having a respective set of second bump structures 198 formed therein. The second bump structures 198 of the device semiconductor dies 100 may be bonded to the first bump structures 498 through the arrays of solder material portions 493.

Referring to FIG. 6H, an underfill material portion 495 may be formed around a respective set of solder material portions 493 that overlie a TSV-containing semiconductor die 300. In one embodiment, each underfill material portion 495 may laterally surround all solder material portions 493 having an areal overlap with a respective underlying TSV-containing semiconductor die 300.

An underfill material portion 495 may be formed around a respective set of solder material portions 493 that overlie a TSV-containing semiconductor die 300. In one embodiment, the underfill material portion 495 may laterally surround all solder material portions 493 having an areal overlap with a respective underlying TSV-containing semiconductor die 300. The underfill material provides structural support and reduces mechanical stress that may occur due to thermal cycling or mechanical shocks. The material absorbs stress between the device semiconductor dies 100 and the TSV-containing semiconductor die 300. The underfill material may be applied using capillary underfill, molded underfill, or printed underfill techniques.

Capillary underfill relies on capillary action to distribute the material between the solder bumps, while molded and printed underfill techniques involve direct application. The underfill material typically consists of an epoxy resin with silica or other fillers. The filler content may be up to 85% by weight, which improves thermal conductivity and mechanical strength and reduces shrinkage and warpage during the curing process. After application, the underfill material is cured at a temperature lower than the solder reflow temperature to solidify and protect the underlying structures. The underfill material reduces structural damage to the solder material portions 493 and the overall durability of the semiconductor package during subsequent processing steps.

A molding compound matrix 497 may be formed around the device semiconductor dies 100 and the underfill material portion 495 and directly on the sidewalls of the TSV-containing semiconductor dies 300. The molding compound matrix 497 may comprise an epoxy molding compound (EMC). The EMC may be cured at a temperature ranging from 125° C. to 150° C., thereby preserving the integrity of the assembly during the molding process. After curing, excess molding compound may be removed from above the device semiconductor dies 100 by performing a planarization process. Specifically, portions of the cured EMC material that overlie the horizontal plane including topmost surfaces of the device semiconductor dies 100 may be removed by performing a chemical mechanical polishing process. A remaining portion of the cured EMC material constitutes the molding compound matrix 497.

The molding compound matrix 497 may embed a two-dimensional array of sets of device semiconductor dies 100 and a two-dimensional array of TSV-containing semiconductor dies 300. The molding compound matrix 497 may have a top surface located within a horizontal plane including topmost surfaces of the device semiconductor dies 100, and may comprise a planar bottom surface contacting the top surface of the die attachment film 932. The molding compound matrix 497 provides mechanical support and environmental protection for the device semiconductor dies 100 and the TSV-containing semiconductor dies 300.

Referring to FIG. 6I, an additional carrier wafer 903 may be attached to the device semiconductor dies 100 using an additional die attachment film 933. The additional carrier wafer 903 may be any carrier wafer known in the art. For example, the additional carrier wafer 903 may comprise a glass substrate having a circular shape or a rectangular shape in a plan view. The additional die attachment film 933 may comprise an ultraviolet-decomposable adhesive material. The additional die attachment film 933 may be attached to the top surfaces of the device semiconductor dies 100 and to the additional carrier wafer 903.

Subsequently, the carrier wafer 902 and the die attachment film 932 may be removed. For example, an ultraviolet irradiation process may be performed to irradiate an ultraviolet beam through the carrier wafer 902 onto the die attachment film 932. The die attachment film 932 may be deactivated by the ultraviolet radiation. A suitable clean process may be performed to clean physically exposed surfaces of the front connection pads 378, the second front capping dielectric layer 372, and a horizontal surface of the molding compound matrix 497.

Referring to FIG. 6J, a chemical mechanical polishing (CMP) process may be performed to polish the semiconductor carrier substrates 924, the die attachment films 934, and portions of the molding compound matrix 497 that are more distal from the additional carrier wafer 903 than the horizontal plane including interfaces between the first backside metal interconnect structures 340 and the die attachment films 934. Distal horizontal surfaces of the first backside metal interconnect structures 340 and a backside horizontal surface of the first backside dielectric material layers 330 may be physically exposed. The distal horizontal surfaces of the first backside metal interconnect structures 340 and the backside horizontal surface of the first backside dielectric material layers 330 may be formed within the same horizontal plane as a polished horizontal surface of the molding compound matrix 497.

Referring to FIG. 6K, a bonding dielectric layer 560 having bonding-level metal interconnect structures 580 formed therein may be formed on the first backside metal interconnect structures 340. The bonding dielectric layer 560 may be formed directly on the molding compound matrix 497. The bonding dielectric layer 560 comprises at least one interlayer dielectric (ILD) layer, which may include at least one via-level dielectric layer and/or at least one line-level dielectric layer. The bonding dielectric layer 560 may comprise, and/or may consist essentially of, at least one inorganic dielectric material such as undoped silicate glass, a doped silicate glass, organosilicate glass, silicon nitride, silicon oxynitride, silicon carbide nitride, silicon oxycarbide, a dielectric metal oxide, etc. The bonding-level metal interconnect structures 580 may comprise metal via structures, metal line structures, metal pad structures, etc.

Metal bump structures 598 may be formed at the topmost level of the bonding dielectric layer 560. Each of the metal bump structures 598 may be formed on a respective one of the bonding-level metal interconnect structures 580, which overlies and contacts the molding compound matrix 497. In one embodiment, the metal bump structures 598 may comprise via portions formed within, and laterally surrounded by, the bonding dielectric layer 560. Further, the metal bump structures 598 may comprise pad structures overlying the topmost surface of the bonding dielectric layer 560. In one embodiment, the metal bump structures 598 may comprise controlled collapse chip connection (C4) pads. Each of the metal bump structures 598 may be formed directly on a respective one of the bonding-level metal interconnect structures 580 and over the bonding dielectric layer 560. Solder balls 593 may be attached to the metal bump structures 598.

Referring to FIG. 6L, the additional carrier wafer 903 and the additional die attachment film 933 may be removed. For example, an ultraviolet irradiation process may be performed to irradiate an ultraviolet beam through the additional carrier wafer 903 onto the additional die attachment film 933. The additional die attachment film 933 may be deactivated by the ultraviolet radiation. A suitable clean process may be performed to clean physically exposed surfaces of the device semiconductor dies 100 and a horizontal surface of the molding compound matrix 497.

A dicing process may be performed to dice (singulate) a reconstituted die including a two-dimensional array of TSV-containing semiconductor dies 300, a two-dimensional array of sets of device semiconductor dies 100, a two-dimensional array of underfill material portions 495, the molding compound matrix 497, and a bonding dielectric layer 560. Diced portions of the reconstituted die comprise composite dies 800. Each composite die 800 comprises a TSV-containing semiconductor die 300, device semiconductor dies 100, an underfill material portion 495, a diced portion of the molding compound matrix 497, and a diced portion of the bonding dielectric layer 560.

The exemplary structure illustrated in FIG. 6L comprises a semiconductor package, which comprises: a first semiconductor substrate 310 having through-substrate-via (TSV) structures 304 formed therein, first semiconductor devices 320 and front bump structures 398 located on a front side of the first semiconductor substrate 310, and first backside metal interconnect structures 340 located on a backside of the first semiconductor substrate 310; device semiconductor dies 100 bonded to the front bump structures 398; a molding compound matrix 497 laterally surrounding the device semiconductor dies 100; and a bonding dielectric layer 560 having bonding-level metal interconnect structures 580 formed therein and located on the first backside metal interconnect structures 340.

In one embodiment, each of the device semiconductor dies 100 is attached to the front bump structures 398 via a respective array of solder material portions 493. In one embodiment, the package structure comprises an underfill material portion 495 laterally surrounding the arrays of solder material portions 493 and formed within the molding compound matrix 497. In one embodiment, the underfill material portion 495 is in contact with the front bump structures 398 and first dielectric material layers 350 of the TSV-containing semiconductor die 300, wherein the first dielectric material layers 350 are interposed between the first semiconductor devices 320 and the front bump structures 398.

In one embodiment, the bonding dielectric layer 560 is in contact with the molding compound matrix 497. In one embodiment, the bonding dielectric layer 560 has a greater lateral extent than the TSV-containing semiconductor die 300. In one embodiment, sidewalls of the bonding dielectric layer 560 are vertically coincident with outer sidewalls of the molding compound matrix 497. In one embodiment, all sidewalls of the TSV-containing semiconductor die 300 are in contact with inner sidewalls of the molding compound matrix 497.

In one embodiment, the package structure comprises metal bump structures 598 located on the bonding-level metal interconnect structures 580 and the bonding dielectric layer 560. In one embodiment, the first semiconductor devices 320 comprise first field effect transistors; and each of the device semiconductor dies 100 comprises a respective set of additional field effect transistors. In one embodiment, each of the device semiconductor dies 100 comprises a respective horizontal surface that is located entirely within a horizontal plane including a planar frame-shaped surface of the molding compound matrix 497. In one embodiment, the TSV-containing semiconductor die 300 comprises first metal interconnect structures 360 formed within first dielectric material layers 350 and interposed between the front bump structures 398 and the first semiconductor devices 320.

Referring to FIG. 6M, a sixth flow chart including a subset of processing steps for forming a semiconductor structure is illustrated.

Referring to step 1610 and FIGS. 6A-6E, a semiconductor assembly (300, 934, 924) is provided, which comprises a through-substrate-via-containing (TSV-containing) semiconductor die 300, a die attachment film 934, and a semiconductor carrier substrate 924. The TSV-containing semiconductor die 300 comprises a first semiconductor substrate 310 having through-substrate-via (TSV) structures 304 formed therein, first semiconductor devices 320 and front bump structures 398 located on a front side of the first semiconductor substrate 310, and first backside metal interconnect structures 340 located on a backside of the first semiconductor substrate 310.

Referring to step 1620 and FIG. 6F, the semiconductor assembly (300, 934, 924) is attached to a carrier wafer 902 using a die attachment film 932.

Referring to step 1630 and FIGS. 6G-6M, device semiconductor dies 100 are attached to the front bump structures 398.

The disclosed embodiments address challenges related to yield reliability and manufacturing cost in semiconductor packaging, particularly during the handling and processing of large-area dies. The embodiments utilize a semiconductor carrier substrate 924, which provides temporary mechanical support during processing stages such as wafer thinning and backside interconnect formation. The semiconductor carrier substrate 924 helps maintain the structural stability of the TSV-containing semiconductor dies 300, minimizing the risk of warpage or mechanical deformation that may occur during processing. By offering this transient structural support, the dies retain proper alignment and integrity throughout the manufacturing process, contributing to a more efficient production of the semiconductor package.

After the necessary processing steps are completed, the semiconductor carrier substrate 924 is detached, allowing the TSV-containing semiconductor dies 300 to proceed through the remaining process without requiring permanent structural additions. The temporary use of the semiconductor carrier substrate 924 facilitates assembly and bonding operations while preserving the structural integrity of the semiconductor dies. This approach enhances stability during processing, resulting in improved manufacturing yields and reduced production costs.

In the first embodiment illustrated in FIGS. 1A-1O, the semiconductor carrier substrate 924 is introduced by attaching it to the device wafer 300W using a continuous adhesive layer 914W, providing mechanical support during the thinning of the first semiconductor substrate 310 and subsequent processing steps. After the processing is complete, the semiconductor carrier substrate 924 is removed by deactivating the adhesive layer 914, either thermally or chemically. A composite die 800 may comprise a first molding compound matrix 397 surrounding the TSV-containing semiconductor dies 300, which provides lateral support. The first backside metal interconnect structures 340 further enhance the electrical connectivity of the package, allowing for improved signal transmission. The combination of the molding compound and backside interconnects helps ensure stability during thermal and mechanical stresses encountered in later stages of processing.

In the second embodiment illustrated in FIGS. 2A-2O, the semiconductor carrier substrate 924 is attached to the device wafer 300W via the continuous adhesive layer 914W, providing necessary mechanical support throughout the processing. After the second molding compound matrix 497 is formed around the device semiconductor dies 100, the semiconductor carrier substrate 924 is removed by deactivating the adhesive layer 914. A composite die 800 may comprise a vertically spaced structure between the first molding compound matrix 397 and the second molding compound matrix 497, separated by the first bonding dielectric layer 460. This spacing helps maintain electrical isolation between layers, preventing short-circuiting, while also providing mechanical stability to the stacked layers. Additionally, the structure formed by stacking device semiconductor dies 100 on top of the TSV-containing semiconductor dies 300 creates a multi-layer package with enhanced density and electrical performance.

In the third embodiment, illustrated in FIGS. 3A-3O, the semiconductor carrier substrate 924 is bonded to the device wafer 300W using the continuous adhesive layer 914W, providing mechanical support during the formation of the backside metal interconnect structures 340 and the second bonding dielectric layer 560. After these structures are formed, the semiconductor carrier substrate 924 is removed by deactivating the adhesive layer. A composite die 800 may comprise a second bonding dielectric layer 560 having bonding-level metal interconnect structures 580 formed therein. These interconnects enhance electrical connectivity between the front connection pads 378 and external components, while the metal bump structures 598 provide bonding to other devices. The inclusion of first backside metal interconnect structures 340 helps optimize signal routing for high-performance applications.

In the fourth embodiment, illustrated in FIGS. 4A-4O, the semiconductor carrier substrate 924 is introduced by bonding it to the device wafer 300W using the continuous adhesive layer 914W, providing structural support during the attachment of an additional carrier wafer 903 and subsequent processing. After the second molding compound matrix 497 is formed, the semiconductor carrier substrate 924 is removed by deactivating the adhesive layer. A composite die 800 may comprise the stacked device semiconductor dies 100, supported by the additional carrier wafer 903 during processing. The removal of the original carrier wafer 902 and die attachment film 932 after the second molding compound matrix 497 is formed allows for better access to the underlying structures for further bonding or processing.

The fifth embodiment, illustrated in FIGS. 5A-5O, involves attaching the semiconductor carrier substrate 924 to the device wafer 300W via the continuous adhesive layer 914W, providing mechanical support during the simultaneous formation of multiple semiconductor assemblies. After the first molding compound matrix 397 and the second bonding dielectric layer 560 are formed around the assemblies, the semiconductor carrier substrate 924 is removed by deactivating the adhesive layer. A composite die 800 may comprise multiple semiconductor assemblies attached to a single carrier wafer 902, with the first molding compound matrix 397 providing lateral support and the second bonding dielectric layer 560 improving electrical connectivity across the assemblies. This embodiment allows for efficient high-volume manufacturing by processing multiple assemblies simultaneously.

In the sixth embodiment, illustrated in FIGS. 6A-6O, the semiconductor carrier substrate 924 is introduced by attaching it to the device wafer 300W using a continuous die attachment film 934W, allowing wafer-level processing. After the wafer-level bonded assembly is diced into individual semiconductor assemblies, the semiconductor carrier substrate 924 is removed by deactivating the adhesive layer. A composite die 800 may comprise a uniform bonding structure across the entire wafer. This wafer-level bonding approach simplifies the assembly process by reducing the number of individual die bonding steps, allowing for high-volume manufacturing with consistent structural integrity and electrical performance across the entire array of semiconductor assemblies.

The disclosed invention provides a consistent advantage across all embodiments by utilizing the semiconductor carrier substrate 924 as a temporary structural component that enhances mechanical support during critical stages of semiconductor manufacturing. The semiconductor carrier substrate 924 is introduced early in the process to stabilize the TSV-containing semiconductor dies 300 and the device wafer 300W during processes such as wafer thinning, backside interconnect formation, and molding compound application. By providing this transient support, the risk of structural warpage or deformation is minimized, leading to higher manufacturing yields. After processing, the semiconductor carrier substrate 924 is removed without leaving any permanent structural elements in the final product, allowing the TSV-containing semiconductor dies 300 and their associated components to remain free of excess material. This method improves the efficiency and the yield of semiconductor packaging by preserving the structural and electrical integrity of the dies while simplifying handling and assembly operations.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure comprising:
attaching semiconductor assemblies to a carrier wafer, wherein each of the semiconductor assemblies comprise a semiconductor die and a semiconductor carrier substrate, wherein the semiconductor die comprises a first semiconductor substrate having through-substrate-via structures formed therein, first semiconductor devices, and front connection pads located on a front side of the first semiconductor substrate, and backside metal interconnect structures located on a backside of the first semiconductor substrate;
removing the semiconductor carrier substrates from a combination of the carrier wafer and the semiconductor assemblies; and
forming a first molding compound matrix within gaps between the semiconductor dies after the semiconductor carrier substrates are removed.

2. The method of claim 1, wherein:
each of the semiconductor assemblies comprises an adhesive layer providing adhesion between the semiconductor die and the semiconductor carrier substrate; and
the method comprises removing the adhesive layer after removing the semiconductor carrier substrates.

3. The method of claim 2, further comprising forming a first bonding dielectric layer and first bump structures over the first molding compound matrix and the backside metal interconnect structures of the semiconductor dies.

4. The method of claim 3, further comprising attaching device semiconductor dies to the first bump structures using arrays of solder material portions.

5. The method of claim 4, further comprising:
forming an underfill material portion around the arrays of solder material portions; and
forming a second molding compound matrix around the device semiconductor dies and the underfill material portion and directly on the first bonding dielectric layer.

6. The method of claim 5, wherein the second molding compound matrix is vertically spaced from the first molding compound matrix by the first bonding dielectric layer and does not contact the first molding compound matrix.

7. The method of claim 4, further comprising:
attaching an additional carrier wafer to the device semiconductor dies using an additional die attachment film; and
removing the carrier wafer and the die attachment film.

8. The method of claim 7, further comprising forming a bonding dielectric layer embedding bonding-level metal interconnect structures on the front connection pads.

9. The method of claim 8, further comprising forming a second molding compound matrix around the device semiconductor dies directly on the first bonding dielectric layer, wherein the carrier wafer and the die attachment film are removed after formation of the second molding compound matrix, and the bonding dielectric layer is formed directly on the first molding compound matrix.

10. The method of claim 8, further comprising:
forming metal bump structures on the bonding-level metal interconnect structures and the bonding dielectric layer; and
dicing at least the bonding dielectric layer, the first molding compound matrix, and the first bonding dielectric layer, wherein a composite die comprising the semiconductor die, a diced portion of the bonding dielectric layer, a diced portion of the first molding compound matrix, and a diced portion of the first bonding dielectric layer is formed.

11. A semiconductor package comprising:
a semiconductor die comprising a first semiconductor substrate containing through-substrate-via structures, first semiconductor devices, and front connection pads located on a front side of the first semiconductor substrate and embedded within at least one front capping dielectric layer, and backside metal interconnect structures located on a backside of the first semiconductor substrate;
a first molding compound matrix laterally surrounding the semiconductor die;
a first bonding dielectric layer located on the backside metal interconnect structures;
first bump structures located on the first bonding dielectric layer;
a second bonding dielectric layer located on the front connection pads; and
second bump structures located on the second bonding dielectric layer,
wherein outer sidewalls of the at least one front capping dielectric layer are laterally offset inward relative to outer sidewalls of the first molding compound matrix, and outer sidewalls of the second bonding dielectric layer are vertically coincident with the outer sidewalls of the first molding compound matrix.

12. The semiconductor package of claim 11, further comprising device semiconductor dies attached to the first bump structures via arrays of solder material portions.

13. The semiconductor package of claim 12, further comprising:
an underfill material portion laterally surrounding the arrays of solder material portions; and
a second molding compound matrix laterally surrounding the device semiconductor dies and the underfill material portion.

14. The semiconductor package of claim 13, wherein outer sidewalls of the first bonding dielectric layer are vertically coincident with outer sidewalls of the second molding compound matrix.

15. The semiconductor package of claim 14, wherein the second molding compound matrix is vertically spaced from the first molding compound matrix by the first bonding dielectric layer.

16. A method of forming a semiconductor structure comprising:
providing a semiconductor assembly, wherein the semiconductor assembly comprises a semiconductor die and a semiconductor carrier substrate, wherein the semiconductor die comprises a first semiconductor substrate having through-substrate-via structures formed therein, first semiconductor devices, and front connection pads located on a front side of the first semiconductor substrate, and first backside metal interconnect structures located on a backside of the first semiconductor substrate;
attaching the semiconductor carrier substrate to a carrier wafer; and
forming a first molding compound matrix around the semiconductor assembly and in gaps between adjacent semiconductor assemblies.

17. The method of claim 16, further comprising forming a first bonding dielectric layer and first bump structures over the first molding compound matrix and the front connection pads.

18. The method of claim 17, further comprising attaching device semiconductor dies to the first bump structures using arrays of solder material portions.

19. The method of claim 18, further comprising:
forming an underfill material portion around the arrays of solder material portions; and
forming a second molding compound matrix around the device semiconductor dies and the underfill material portion and directly on the first bonding dielectric layer.

20. The method of claim 19, wherein the second molding compound matrix is vertically spaced from the first molding compound matrix by the first bonding dielectric layer and does not contact the first molding compound matrix.
